(19) United States
(12) Patent Application Publication
(10) Pub. No.: US 2026/0277790 A1
(43) Pub. Date: Sep. 17, 2026

(54) MEMORY SYSTEM

(71) Applicant: Kioxia Corporation, Tokyo (JP)

(72) Inventors: Naomi TAKEDA, Yokohama (JP); Masanobu SHIRAKAWA, Chigasaki (JP)

(73) Assignee: Kioxia Corporation, Tokyo (JP)

(21) Appl. No.: 19/266,275

(22) Filed: Jul. 11, 2025

(30) Foreign Application Priority Data
Mar. 17, 2025 (JP) 2025-042912

(51) Int. Cl. G06F 12/02; G11C 16/04; G11C 16/26

(52) U.S. Cl. CPC G06F 12/0246; G11C 16/26; G11C 16/0483

(57) ABSTRACT

According to one embodiment, a memory system includes a memory device and a memory controller. The memory device includes a first and a second memory cells, a word line coupled to the first and second memory cells, a first bit line coupled to the first memory cell, a second bit line coupled to the second memory cell, a sense amplifier module including a first and a second latch circuit, and a data register. In a first read operation, the first latch circuit stores first data corresponding to the first bit line, the second latch circuit stores second data corresponding to the second bit line, and the data register stores data of the first memory cell based on an operation result using the first data, and stores data of the second memory cell based on an operation result using the second data.

### CROSS-REFERENCE TO RELATED APPLICATIONS

This application is based upon and claims the benefit of priority from Japanese Patent Application No. 2025-042912, filed Mar. 17, 2025, the entire contents of which are incorporated herein by reference.

### FIELD

Embodiments described herein relate generally to a memory system.

### BACKGROUND

A memory system including a NAND flash memory capable of storing data in a nonvolatile manner and a memory controller that controls the NAND flash memory is known.

### BRIEF DESCRIPTION OF THE DRAWINGS

FIG. 1 is a block diagram illustrating an example of a configuration of an information processing system including a memory system according to a first embodiment.

FIG. 2 is a block diagram illustrating an example of a configuration of a memory device included in the memory system according to the first embodiment.

FIG. 3 is a circuit diagram illustrating an example of a circuit configuration of a memory cell array included in the memory system according to the first embodiment.

FIG. 4 is a perspective view illustrating an example of a structure of a memory cell array included in the memory system according to the first embodiment.

FIG. 5 is a plan view illustrating an example of a planar layout of a memory cell array included in the memory system according to the first embodiment.

FIG. 6 is a cross-sectional view taken along line VI-VI of FIG. 5.

FIG. 7 is a cross-sectional view taken along line VII-VII of FIG. 5.

FIG. 8 is a cross-sectional view taken along line VIII-VIII in FIG. 5.

FIG. 9 is a cross-sectional view along the X direction of a bit line coupling portion in a memory cell array included in the memory system according to the first embodiment.

FIG. 10 is a block diagram illustrating an example of a configuration of a sense amplifier module and a data register included in the memory system according to the first embodiment.

FIG. 11 is a circuit diagram illustrating an example of a circuit configuration of a sense amplifier unit included in the memory system according to the first embodiment.

FIG. 12 is a diagram illustrating a threshold voltage distribution and data allocation in a case where the memory cell transistor included in the memory system according to the first embodiment is a TLC capable of storing 3-bit data.

FIG. 13 is a table illustrating an example of a shift table included in the memory system according to the first embodiment.

FIG. 14 is a table illustrating an example of a read level management table included in the memory system according to the first embodiment.

FIG. 15 is a table illustrating an example of a group mode table included in the memory system according to the first embodiment.

FIG. 16 is a flowchart illustrating an example of a flow of a read operation in the memory system according to the first embodiment.

FIG. 17 is a flowchart illustrating an example of a flow of a read operation in the memory system according to the first embodiment.

FIG. 18 is a flowchart illustrating an example of a flow of a read operation in the memory system according to the first embodiment.

FIG. 19 is a flowchart illustrating an example of a flow of a read operation using a history value in the memory system according to the first embodiment.

FIG. 20 is a diagram illustrating an example of a command set of normal shift read of Lower page data in the memory system according to the first embodiment.

FIG. 21 is a diagram illustrating an example of a command set of group data read in a case where the number of groups of BL groups in the memory system according to the first embodiment is two.

FIG. 22 is a diagram illustrating an example of a command set of shift read of Lower page data in a case where the number of groups of BL groups in the memory system according to the first embodiment is two.

FIG. 23 is a timing chart illustrating an example of a voltage of a selected word line in normal shift read of Lower page data in the memory system according to the first embodiment.

FIG. 24 is a timing chart illustrating an example of a voltage of a selected word line WL in shift read of Lower page data in a case where the number of groups of BL groups is two in the memory system according to the first embodiment.

FIG. 25 is a diagram schematically illustrating an example of grouping of bit lines in the memory system according to the first embodiment.

FIG. 26 is a diagram illustrating an example of states of latch circuits at the time of a Lower page data read operation in the memory system according to the first embodiment.

FIG. 27 is a diagram illustrating an example of states of latch circuits at the time of a Lower page data read operation in the memory system according to the first embodiment.

FIG. 28 is a diagram illustrating an example of states of latch circuits at the time of a Lower page data read operation in the memory system according to the first embodiment.

FIG. 29 is a diagram illustrating an example of states of latch circuits at the time of a Lower page data read operation in the memory system according to the first embodiment.

FIG. 30 is a diagram illustrating an example of states of latch circuits at the time of a Lower page data read operation in the memory system according to the first embodiment.

FIG. 31 is a diagram illustrating an example of states of latch circuits at the time of a Lower page data read operation in the memory system according to the first embodiment.

FIG. 32 is a diagram illustrating an example of states of latch circuits at the time of a Lower page data read operation in the memory system according to the first embodiment.

FIG. 33 is a timing chart illustrating an example of a voltage of a selected word line in shift read of Lower page data in a case where the number of groups of BL groups is two in a memory system according to the first modification of the first embodiment.

FIG. 34 is a flowchart illustrating an example of a flow of the shift read for each BL group in the memory system according to the first modification of the first embodiment.

FIG. 35 is a diagram illustrating an example of a command set of group data read in a case where the number of groups of BL groups in a memory system according to the second modification of the first embodiment is two.

FIG. 36 is a diagram illustrating an example of a command set of shift read of Lower page data in a case where the number of groups of BL groups in the memory system according to the second modification of the first embodiment is two.

FIG. 37 is a timing chart illustrating an example of a voltage of a selected word line in shift read of Lower page data in a case where the number of groups of BL groups is two in the memory system according to the second modification of the first embodiment.

FIG. 38 is a diagram illustrating an example of states of latch circuits in group data read in a memory system according to the second modification of the first embodiment.

FIG. 39 is a flowchart illustrating an example of a flow of a read operation using a history value in a memory system according to a third modification of the first embodiment.

FIG. 40 is a graph illustrating a relationship between a voltage of a node SEN and a sense time in a read operation in a memory system according to a fourth modification of the first embodiment.

FIG. 41 is a timing chart showing voltages of a selected word line and a control signal STB in a read operation of Lower page data in the memory system according to the fourth modification of the first embodiment.

FIG. 42 is a block diagram illustrating an example of a configuration of an information processing system including a memory system according to a fifth modification of the first embodiment.

FIG. 43 is a flowchart illustrating an example of a flow of a read operation using a history value in the memory system according to the fifth modification of the first embodiment.

FIG. 44 is a diagram schematically illustrating an example of grouping of bit lines corresponding to read operations AR and ER in a memory system according to a second embodiment.

FIG. 45 is a diagram illustrating an example of a command set of group data read in the memory system according to the second embodiment.

FIG. 46 is a diagram illustrating an example of a command set of shift read of Lower page data in the memory system according to the second embodiment.

FIG. 47 is a diagram illustrating an example of states of latch circuits at the time of a Lower page data read operation in a case where grouping of BL groups is different for each state of threshold voltage distributions in the memory system according to the second embodiment.

FIG. 48 is a diagram illustrating an example of states of latch circuits at the time of a Lower page data read operation in a case where grouping of BL groups is different for each state of threshold voltage distributions in the memory system according to the second embodiment.

FIG. 49 is a diagram illustrating an example of states of latch circuits at the time of a Lower page data read operation in a case where grouping of BL groups is different for each state of threshold voltage distributions in the memory system according to the second embodiment.

FIG. 50 is a diagram illustrating an example of states of latch circuits at the time of a Lower page data read operation in a case where grouping of BL groups is different for each state of threshold voltage distributions in the memory system according to the second embodiment.

FIG. 51 is a diagram illustrating an example of states of latch circuits at the time of a Lower page data read operation in a case where grouping of BL groups is different for each state of threshold voltage distributions in the memory system according to the second embodiment.

FIG. 52 is a diagram illustrating an example of states of latch circuits at the time of a Lower page data read operation in a case where grouping of BL groups is different for each state of threshold voltage distributions in the memory system according to the second embodiment.

FIG. 53 is a diagram illustrating an example of states of latch circuits at the time of a Lower page data read operation in a case where grouping of BL groups is different for each state of threshold voltage distributions in the memory system according to the second embodiment.

FIG. 54 is a diagram schematically illustrating an example of bit line grouping in a memory system according to a third embodiment.

FIG. 55 is a diagram illustrating an example of a command set of group data read in the memory system according to the third embodiment.

FIG. 56 is a diagram illustrating an example of a command set of shift read of Lower page data in the memory system according to the third embodiment.

FIG. 57 is a timing chart illustrating an example of a voltage of a selected word line in shift read of Lower page data in a case where the number of groups of BL groups is four in the memory system according to the third embodiment.

FIG. 58 is a diagram illustrating an example of states of latch circuits at the time of a Lower page data read operation in the memory system according to the third embodiment.

FIG. 59 is a diagram illustrating an example of states of latch circuits at the time of a Lower page data read operation in the memory system according to the third embodiment.

FIG. 60 is a diagram illustrating an example of states of latch circuits at the time of a Lower page data read operation in the memory system according to the third embodiment.

FIG. 61 is a diagram illustrating an example of states of latch circuits at the time of a Lower page data read operation in the memory system according to the third embodiment.

FIG. 62 is a diagram illustrating an example of states of latch circuits at the time of a Lower page data read operation in the memory system according to the third embodiment.

FIG. 63 is a diagram illustrating an example of states of latch circuits at the time of a Lower page data read operation in the memory system according to the third embodiment.

FIG. 64 is a diagram illustrating an example of states of latch circuits at the time of a Lower page data read operation in the memory system according to the third embodiment.

FIG. 65 is a diagram illustrating an example of states of latch circuits at the time of a Lower page data read operation in the memory system according to the third embodiment.

FIG. 66 is a diagram illustrating an example of states of latch circuits at the time of a Lower page data read operation in the memory system according to the third embodiment.

FIG. 67 is a diagram illustrating an example of states of latch circuits at the time of a Lower page data read operation in the memory system according to the third embodiment.

FIG. 68 is a flowchart illustrating an example of a flow of a read operation using a history value in a memory system according to a fourth embodiment.

FIG. 69 is a diagram illustrating an example of allocation of group data for each BL group in a shift read of a first phase and a second phase in the memory system according to the fourth embodiment.

FIG. 70 is a diagram illustrating an example of a command set of group data read in the memory system according to the fourth embodiment.

FIG. 71 is a diagram illustrating an example of a command set of shift read in a first phase of Lower page data in the memory system according to the fourth embodiment.

FIG. 72 is a diagram illustrating an example of a command set of shift read in a second phase of Lower page data in the memory system according to the fourth embodiment.

FIG. 73 is a timing chart illustrating an example of a voltage of a selected word line in shift read in a first phase of Lower page data in the memory system according to the fourth embodiment.

FIG. 74 is a timing chart illustrating an example of a voltage of a selected word line in shift read in a second phase of Lower page data in the memory system according to the fourth embodiment.

FIG. 75 is a flowchart illustrating an example of a flow of a Vth tracking operation in a memory system according to a fifth embodiment.

FIG. 76 is a diagram illustrating an example of state separation of Lower page data in the memory system according to the fifth embodiment.

FIG. 77 is a diagram illustrating an example of a command set of tracking read of Lower page data in the memory system according to the fifth embodiment.

FIG. 78 is a timing chart illustrating an example of a voltage of a selected word line in tracking read of Lower page data in the memory system according to the fifth embodiment.

FIG. 79 is a diagram illustrating an example of states of latch circuits in tracking read of Lower page data in the memory system according to the fifth embodiment.

FIG. 80 is a diagram illustrating an example of states of latch circuits in tracking read of Lower page data in the memory system according to the fifth embodiment.

FIG. 81 is a diagram illustrating an example of states of latch circuits in tracking read of Lower page data in the memory system according to the fifth embodiment.

FIG. 82 is a flowchart illustrating an example of a flow of a Vth tracking operation in a memory system according to a modification of the fifth embodiment.

### DETAILED DESCRIPTION

In general, according to one embodiment, a memory system includes a memory device and a memory controller. The memory device includes a memory cell array including a first memory cell and a second memory cell stacked apart from each other above a substrate, a word line coupled to a gate of the first memory cell and a gate of the second memory cell, a first bit line coupled to the first memory cell, a second bit line coupled to the second memory cell, a sense amplifier module including a first sense circuit to which the first bit line is coupled, a second sense circuit to which the second bit line is coupled, a first latch circuit coupled to the first sense circuit, and a second latch circuit coupled to the second sense circuit, and a data register coupled to the sense amplifier module. The memory controller configured to control a read operation in the memory device. In a first read operation of the first memory cell and the second memory cell, the first latch circuit is configured to store first data corresponding to a first group to which the first bit line belongs, the second latch circuit is configured to store second data corresponding to a second group to which the second bit line belongs, and the data register is configured to store data of the first memory cell read by the first sense circuit under a first read condition based on an operation result using the first data, and stores data of the second memory cell read by the second sense circuit under a second read condition based on an operation result using the second data.

Hereinafter, embodiments will be described with reference to the drawings. In the following description, components having the same function and configuration are denoted by the same reference numerals. In addition, in a case where a plurality of components having a common reference sign is distinguished, the common reference sign is added with a suffix to be distinguished. Note that, in a case where a plurality of components does not need to be particularly distinguished, only common reference numerals are attached to the plurality of components, and no suffixes are attached thereto. Here, the suffix is not limited to a subscript or a superscript, and includes, for example, a lower case alphabet added to the end of the reference sign, an index meaning an array, and the like.

### 1. FIRST EMBODIMENT

Hereinafter, a memory system according to an embodiment will be described.

### 1.1 Configuration of Memory System

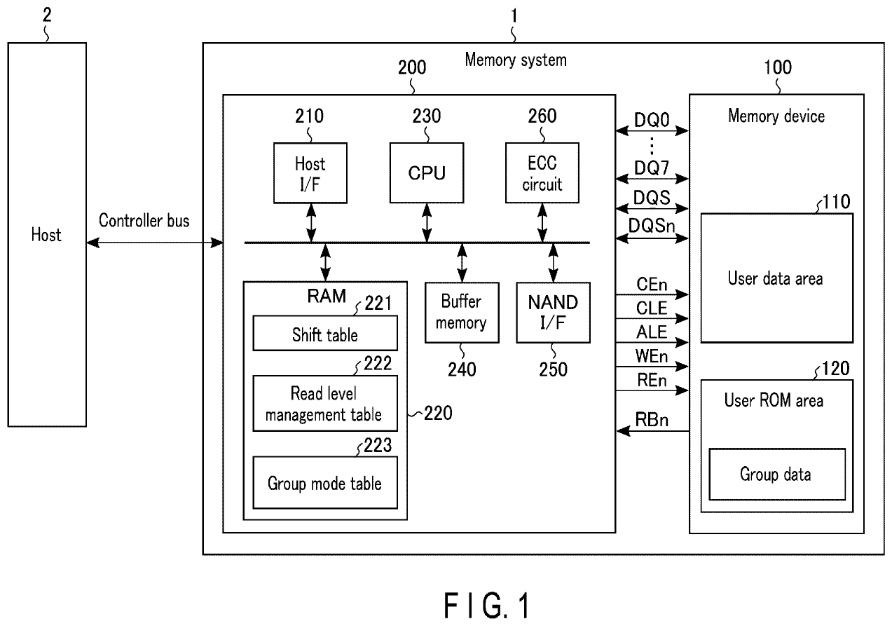

First, an example of a configuration of a memory system 1 will be described with reference to FIG. 1. FIG. 1 is a block diagram illustrating an example of a configuration of an information processing system including a memory system 1.

As illustrated in FIG. 1, the information processing system includes the memory system 1 and a host 2.

The memory system 1 is, for example, a solid state drive (SSD). The memory system 1 is coupled to the host 2 via a controller bus. The memory system 1 executes processing based on a request signal received from the host 2 or a voluntary processing request.

The host 2 is an information processing apparatus (computing device) that accesses the memory system 1. The host 2 controls the memory system 1. More specifically, for example, the host 2 requests (instructs) the memory system 1 to perform a write operation or a read operation of data (hereinafter, referred to as “user data”).

The memory system 1 includes a memory device 100 and a memory controller 200. A combination of the memory device 100 and the memory controller 200 may form one semiconductor memory device. Examples of such a semiconductor memory device include a memory card such as an SD™ card, an SSD, and the like.

The memory device 100 includes a plurality of memory cell transistors and stores data in a nonvolatile manner. The memory device 100 is, for example, a three-dimensional stacked NAND flash memory in which a plurality of memory cell transistors is three-dimensionally stacked above a semiconductor substrate. The memory device 100 includes a user data area 110 and a user ROM area 120 as memory areas. The user data area 110 is an area used for writing user data received from the host 2. The user ROM area 120 is an area in which various system data and various management data are stored. The user ROM area 120 is an area that cannot be accessed by the host 2. Each block BLK to be described later is allocated to either the user data area 110 or the user ROM area 120. The user ROM area 120 stores group data. The group data will be described later.

The memory device 100 is coupled to the memory controller 200 via a NAND bus. The memory device 100 operates based on an instruction from the memory controller 200. The 8-bit signals DQ0 to DQ7 and the clock signals DQS and DQSn are transmitted and received between the memory device 100 and the memory controller 200. Hereinafter, in a case where any of the signals DQ0 to DQ7 is not limited, it is referred to as a signal DQ. The signal DQ is, for example, data, an address, and a command. The clock signals DQS and DQSn are clock signals used at the time of inputting and outputting data. The clock signal DQSn is an inverted signal of the clock signal DQS.

In addition, the memory device 100 receives, for example, a chip enable signal CEn, a command latch enable signal CLE, an address latch enable signal ALE, a write enable signal WEn, and a read enable signal REn from the memory controller 200.

The chip enable signal CEn is a signal for enabling the memory device 100. The chip enable signal CEn is asserted at, for example, the Low (“L”) level.

The command latch enable signal CLE is a signal indicating that the signal DQ is a command. The command latch enable signal CLE is asserted at a high (“H”) level, for example.

The address latch enable signal ALE is a signal indicating that the signal DQ is an address. The address latch enable signal ALE is asserted, for example, at the “H” level.

The write enable signal WEn is a signal for taking the received signal into the memory device 100. The write enable signal WEn is asserted at the “L” level, for example, every time a command and an address are received from the memory controller 200. That is, every time the write enable signal WEn is toggled, a command or an address is taken into the memory device 100. The read enable signal REn is a signal for the memory controller 200 to read data from the memory device 100. The read enable signal REn is asserted at the “L” level, for example.

In addition, the memory device 100 transmits a ready/busy signal RBn to the memory controller 200. The ready/busy signal RBn is a signal indicating whether the memory device 100 is in a ready state or a busy state. The ready state is a state in which the memory device 100 can receive a command from the memory controller 200. The busy state is a state in which the memory device 100 cannot receive a command from the memory controller 200. For example, the “H” level of the ready/busy signal RBn indicates that the memory device 100 is in a ready state. The “L” level of the ready/busy signal RBn indicates that the memory device 100 is in a busy state.

### 1.1.1 Configuration of Memory Controller

Next, an example of a configuration of the memory controller 200 will be described with reference to FIG. 1. In response to a request (instruct) from the host 2, the memory controller 200 instructs the memory device 100 to perform a read operation, a write operation, an erase operation, and the like. In addition, the memory controller 200 manages a memory area of the memory device 100. The memory controller 200 includes, for example, a host interface circuit (host I/F) 210, an embedded memory (random access memory (RAM)) 220, a processor (central processing unit (CPU)) 230, a buffer memory 240, a NAND interface circuit (NAND I/F) 250, and an error check and correction (ECC) circuit 260.

The host interface circuit 210 is coupled to the host 2 via a controller bus and manages communication with the host 2. The host interface circuit 210 transfers the request and the data received from the host 2 to the CPU 230 and the buffer memory 240. In addition, the host interface circuit 210 transfers the data in the buffer memory 240 to the host 2 in response to an instruction from the CPU 230.

The RAM 220 is used as, for example, a work area of the CPU 230. The RAM 220 stores firmware for managing the memory device 100, various management tables, and the like. The RAM 220 stores, for example, a shift table 221, a read level management table 222, and a group mode table 223. Details of the shift table 221, the read level management table 222, and the group mode table 223 will be described later. As the RAM 220, for example, a semiconductor memory such as a static random access memory (SRAM) or a dynamic random access memory (DRAM) is used.

The CPU 230 controls the entire operation of the memory controller 200. For example, Upon receiving a read request including a command and a logical address from the host 2, the CPU 230 issues a command set including a command and a physical address in response to the received read request. Then, the issued command set is transferred to the memory device 100, and the memory device 100 executes the read operation based on the command set. The CPU 230 can execute the write operation and the erase operation as in the read operation. In addition, the CPU 230 can execute various processes for managing the memory device 100, such as wear leveling. Furthermore, the CPU 230 can execute various arithmetic processing such as data encryption processing and randomization processing.

The buffer memory 240 temporarily stores read data received by the memory controller 200 from the memory device 100. In addition, the buffer memory 240 temporarily stores user data and the like received by the memory controller 200 from the host 2. As the buffer memory 240, for example, a semiconductor memory such as a DRAM is used. The buffer memory 240 may be externally coupled to the memory controller 200 or may be integrated with the RAM 220.

The NAND interface circuit 250 is coupled to the memory device 100 via the NAND bus, and manages communication between the memory device 100 and the memory controller 200. The NAND interface circuit 250 transfers the command set issued by the CPU 230 to the memory device 100. At the time of the read operation, the NAND interface circuit 250 transfers read data received from the memory device 100 to the buffer memory 240. At the time of the write operation, the NAND interface circuit 250 transfers write data stored in the buffer memory 240 to the memory device 100.

The ECC circuit 260 is a circuit that executes the ECC process. The ECC process includes encoding and decoding of data. The encoding is an operation of generating a code word based on data. For example, the ECC circuit 260 generates an error correction code (hereinafter, referred to as “parity”) based on the user data. Then, the ECC circuit 260 imparts parity to the user data to generate a code word, that is, write data. Decoding is an operation of performing error correction of data. The ECC circuit 260 decodes data read from the memory device 100. In a case where the number of fail bits exceeds the number of error correctable bits of the ECC circuit 260, the read data cannot be decoded. Hereinafter, a case where the ECC circuit can decode the data is referred to as “the ECC process passed”, and a case where the ECC circuit 260 cannot decode the data is referred to as “the ECC process failed”.

### 1.1.2 Configuration of Memory Device

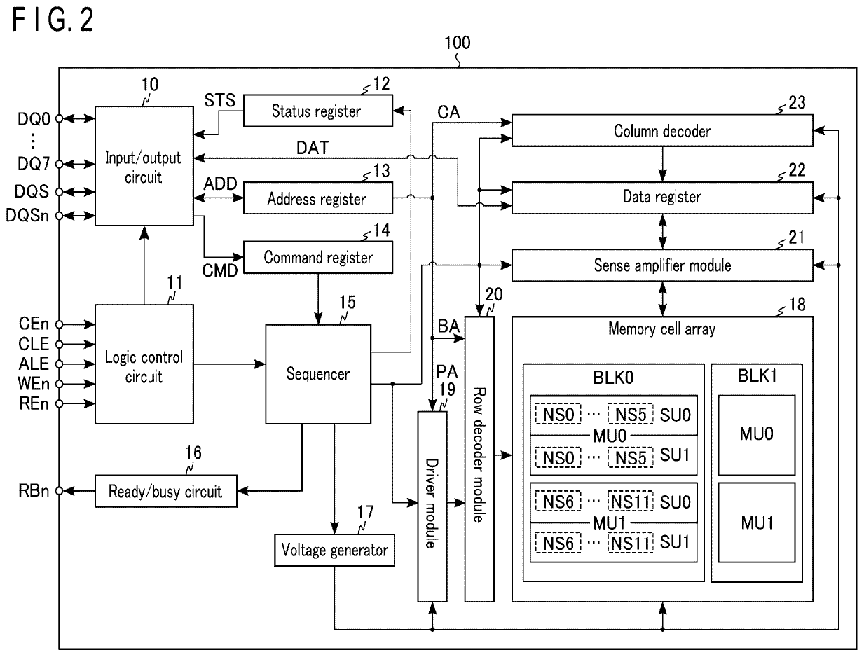

Next, an example of a configuration of the memory device 100 will be described with reference to FIG. 2. FIG. 2 is a block diagram illustrating an example of a configuration of the memory device 100. In FIG. 2, the coupling between the components is indicated by an arrow line, but the coupling between the components is not limited to the illustrated coupling.

As illustrated in FIG. 2, the memory device 100 includes, for example, an input/output circuit 10, a logic control circuit 11, a status register 12, an address register 13, a command register 14, a sequencer 15, a ready/busy circuit 16, a voltage generator 17, a memory cell array 18, a driver module 19, a row decoder module 20, a sense amplifier module 21, a data register 22, and a column decoder 23. Some elements of the input/output circuit 10, the logic control circuit 11, the status register 12, the address register 13, the command register 14, the sequencer 15, the ready/busy circuit 16, the voltage generator 17, the driver module 19, the row decoder module 20, the sense amplifier module 21, and the column decoder 23 may be referred to as a control circuit or a controller.

The input/output circuit 10 is a circuit that inputs and outputs the signal DQ and the clock signals DQS and DQSn. The input/output circuit 10 is coupled to the memory controller 200 via a NAND bus. In addition, the input/output circuit 10 is coupled to the logic control circuit 11, the status register 12, the address register 13, the command register 14, and the data register 22.

The input/output circuit 10 transmits data DAT (write data) to the data register 22. The input/output circuit 10 transmits an address ADD to the address register 13. The input/output circuit 10 transmits a command CMD to the command register 14.

The input/output circuit 10 receives data DAT (read data) from the data register 22. The input/output circuit 10 receives the address ADD from the address register 13. The input/output circuit 10 receives status information STS from the status register 12.

The logic control circuit 11 is a circuit that performs logic control of the memory device 100. The logic control circuit 11 is coupled to the memory controller 200 via a NAND bus. In addition, the logic control circuit 11 is coupled to the input/output circuit 10 and the sequencer 15. The logic control circuit 11 receives, for example, a chip enable signal CEn, a command latch enable signal CLE, an address latch enable signal ALE, a write enable signal WEn, and a read enable signal REn from the memory controller 200. The logic control circuit 11 controls the input/output circuit 10 and the sequencer 15 based on a signal received from the memory controller 200.

The status register 12 is a register that temporarily stores the status information STS. The status information STS includes, for example, information for notifying the memory controller 200 whether the write operation, the read operation, the erase operation, and the like are normally ended. The status register 12 is coupled to the input/output circuit 10 and the sequencer 15. The status register 12 receives the status information STS from the sequencer 15.

The address register 13 is a register that temporarily stores the address ADD. The address ADD may include the page address PA, a block address BA, a column address CA, and the like. The address register 13 is coupled to the input/output circuit 10, the driver module 19, the row decoder module 20, and the column decoder 23. The address register 13 transmits the page address PA to the driver module 19. The address register 13 transmits the block address BA to the row decoder module 20. The address register 13 transmits the column address CA to the column decoder 23.

The command register 14 is a register that temporarily stores the command CMD. The command register 14 is coupled to the input/output circuit 10 and the sequencer 15. The command register 14 transmits the command CMD to the sequencer 15.

The sequencer 15 controls the entire operation of the memory device 100. The sequencer 15 is coupled to the input/output circuit 10, the logic control circuit 11, the status register 12, the command register 14, the ready/busy circuit 16, the voltage generator 17, the driver module 19, the row decoder module 20, the sense amplifier module 21, the data register 22, and the column decoder 23. For example, the sequencer 15 controls the status register 12, the ready/busy circuit 16, the voltage generator 17, the driver module 19, the row decoder module 20, the sense amplifier module 21, the data register 22, and the column decoder 23. The sequencer 15 executes a write operation, a read operation, an erase operation, and the like in response to the command CMD. In some embodiments, a sequencer 15 is a circuit or a component that controls timing of operations of various components of the memory device 100. In some embodiments, the sequencer 15 may operate as a control circuit or a controller. In some embodiments, the sequencer 15 is implemented as a logic circuit, ASIC, FPGA, or any combination of them. In some embodiments, the sequencer 15 may apply various voltages, pulses, or signals to various components of the memory device 100 to control timing of operations of the components of the memory device 100 as described herein.

The ready/busy circuit 16 is a circuit that transmits the ready/busy signal RBn. The ready/busy circuit 16 generates a ready/busy signal RBn based on the operation state of the sequencer 15. The ready/busy circuit 16 transmits the generated ready/busy signal RBn to the memory controller 200.

The voltage generator 17 generates various voltages used for the write operation, the read operation, the erase operation, and the like under the control of the sequencer 15. The voltage generator 17 is coupled to the sequencer 15, the memory cell array 18, the driver module 19, the sense amplifier module 21, the data register 22, the column decoder 23, and the like. The voltage generator 17 supplies the generated voltages to the memory cell array 18, the driver module 19, the sense amplifier module 21, the data register 22, the column decoder 23, and the like.

The memory cell array 18 includes a plurality of blocks BLK. In the example illustrated in FIG. 2, the memory cell array 18 includes two blocks BLK0 and BLK1. The block BLK is, for example, a set of a plurality of memory cell transistors from which data is collectively erased. The block BLK can be used, for example, as a data erasing unit.

Each block BLK includes a plurality of string units SU. The string unit SU is a set of a plurality of NAND strings NS collectively selected in the write operation or the read operation. The NAND string NS includes a plurality of memory cell transistors coupled in series. In the example illustrated in FIG. 2, each block BLK includes two string units SU0 and SU1. Each string unit SU includes the NAND strings NS0 to NS11.

Each block BLK includes a plurality of memory units MU. In the example illustrated in FIG. 2, each block BLK includes two memory units MU0 and MU1. The memory unit MU is a structure including a semiconductor layers (a channel layer of the NAND string NS) stacked above and away from the semiconductor substrate. Details of the structure of the memory unit MU will be described later.

Each memory unit MU includes part of each string unit SU. In the example illustrated in FIG. 2, the memory unit MU0 includes the NAND strings NS0 to NS5 of the string units SU0 and SU1. The memory unit MU1 includes the NAND strings NS6 to NS11 of the string units SU0 and SU1.

Note that the number of blocks BLK, string units SU, NAND strings NS, and memory units MU included in the memory cell array 18 are arbitrary.

The driver module 19 is a driver that supplies voltages to the row decoder module 20. The driver module 19 is coupled to the sequencer 15, the voltage generator 17, and the row decoder module 20. The driver module 19 and the row decoder module 20 are coupled by a plurality of signal lines. The driver module 19 receives the page address PA from the address register 13. The driver module 19 applies a plurality of voltages used for the read operation, the write operation, the erase operation, and the like to the plurality of signal lines based on the page address PA.

The row decoder module 20 is a circuit that decodes the block address BA. The row decoder module 20 is coupled to the address register 13, the sequencer 15, the memory cell array 18, and the driver module 19. The row decoder module 20 receives the block address BA from the address register 13. The row decoder module 20 selects one block BLK in the memory cell array 18 based on the decoding result of the block address BA.

The sense amplifier module 21 is a circuit that writes and reads data. The sense amplifier module 21 is coupled to the address register 13, the sequencer 15, the voltage generator 17, the memory cell array 18, and the data register 22. The sense amplifier module 21 reads data from the memory cell array 18 at the time of the read operation. The sense amplifier module 21 transfers the read data to the data register 22. In addition, the sense amplifier module 21 supplies voltages corresponding to the write data received from the data register 22 to the memory cell array 18 at the time of the write operation.

The data register 22 is a register that temporarily stores write data or read data. The data register 22 is coupled to the input/output circuit 10, the sequencer 15, the voltage generator 17, the sense amplifier module 21, and the column decoder 23. The data register 22 includes a plurality of latch circuits. Each latch circuit temporarily stores write data or read data.

The column decoder 23 is a circuit that decodes the column address CA. The column decoder 23 is coupled to the address register 13, the sequencer 15, the voltage generator 17, and the data register 22. The column decoder 23 receives the column address CA from the address register 13. The column decoder 23 selects the latch circuit in the data register 22 based on the decoding result of the column address CA.

### 1.2 Circuit Configuration of Memory Cell Array

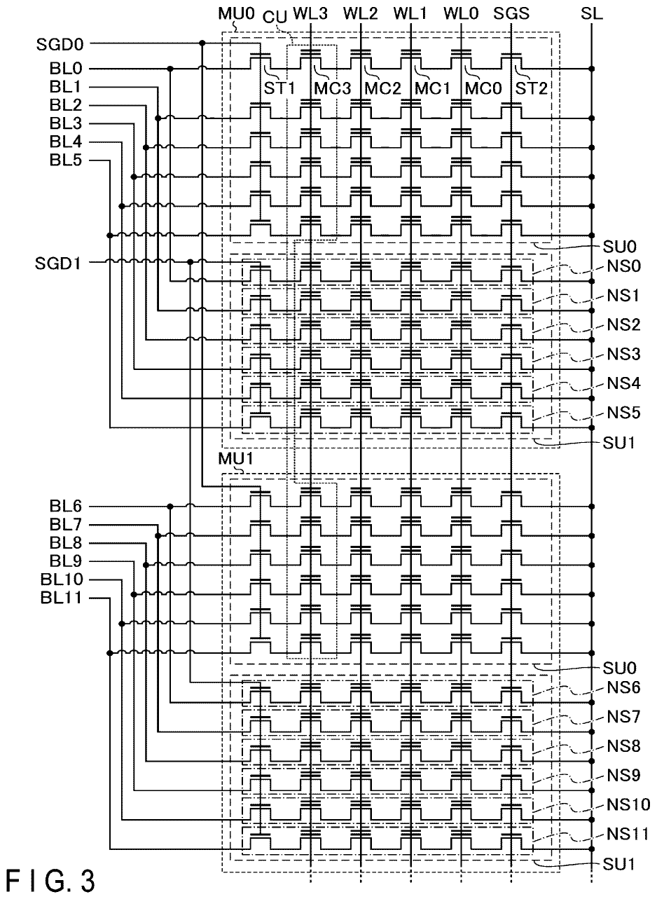

Next, an example of a circuit configuration of the memory cell array 18 will be described with reference to FIG. 3. FIG. 3 is a circuit diagram illustrating an example of a circuit configuration of the memory cell array 18. FIG. 3 illustrates an example of a circuit configuration of one block BLK in the memory cell array 18.

As shown in FIG. 3, each block BLK includes two string units SU and two memory units MU. Each string unit SU includes 12 NAND strings NS0 to NS11. The memory unit MU0 includes the NAND strings NS0 to NS5 of the string unit SU0 and the NAND strings NS0 to NS5 of the string unit SU1. The memory unit MU1 includes the NAND strings NS6 to NS11 of the string unit SU0 and the NAND strings NS6 to NS11 of the string unit SU1.

The NAND strings NS of the same number in each string unit SU are coupled to a common bit line BL. Each bit line BL is coupled to the sense amplifier module 21. For example, the NAND strings NS0 to NS11 of each string unit SU are coupled to the bit lines BL0 to BL11, respectively. More specifically, the NAND strings NS0 to NS5 included in the string units SU0 and SU1 of the memory unit MU0 are coupled to the bit lines BL0 to BL5, respectively. Further, the NAND strings NS6 to NS11 included in the string units SU0 and SU1 of the memory unit MU1 are coupled to the bit lines BL6 to BL11, respectively.

Each NAND string NS includes, for example, four memory cell transistors MC0 to MC3 and selection transistors ST1 and ST2. The number of memory cell transistors MC in the NAND string NS is not limited to four. In addition, the number of selection transistors ST1 and ST2 in the NAND string NS may be one or more.

The memory cell transistor MC includes a control gate and a charge storage layer, and stores data in a nonvolatile manner. The memory cell transistor MC may be a metal-oxide-nitride-oxide-silicon (MONOS) type in which an insulator is used for the charge storage layer, or may be a floating gate (FG) type in which a conductor is used for the charge storage layer. Hereinafter, a case where the memory cell transistor MC is of the MONOS type will be described.

The selection transistors ST1 and ST2 are switching elements. The selection transistors ST1 and ST2 are used to select the string unit SU in the write operation, the read operation, or the like.

In each NAND string NS, the current paths of the selection transistor ST2, the memory cell transistors MC0 to MC3, and the selection transistor ST1 are coupled in series in this order. The drain of the selection transistor ST1 is coupled to the corresponding bit line BL. The source of the selection transistor ST2 is coupled to a source line SL.

The control gates of the memory cell transistors MC0 to MC3 in the block BLK are commonly coupled to the word lines WL0 to WL3, respectively. More specifically, the control gate of each of the plurality of memory cell transistors MC0 included in the block BLK is coupled to the word line WL0. The control gate of each of the plurality of memory cell transistors MC1 included in the block BLK is coupled to the word line WL1. The control gate of each of the plurality of memory cell transistors MC2 included in the block BLK is coupled to the word line WL2. The control gate of each of the plurality of memory cell transistors MC3 included in the block BLK is coupled to the word line WL3.

In the block BLK, the gates of the plurality of selection transistors ST1 in each string unit SU are commonly coupled to one select gate line SGD. More specifically, the gates of the plurality of selection transistors ST1 included in the string unit SU0 are coupled to the select gate line SGD0. The gates of the plurality of selection transistors ST1 included in the string unit SU1 are coupled to the select gate line SGD1.

The gates of the plurality of selection transistors ST2 in the block BLK are coupled to the select gate line SGS. Note that the gates of the plurality of selection transistors ST2 in the block BLK may be coupled to different select gate lines SGS for each string unit SU, as in the select gate line SGD.

The word lines WL0 to WL3, the select gate lines SGD0 and SGD1, and the select gate line SGS are coupled to the row decoder module 20. The word lines WL0 to WL3, the select gate lines SGD0 and SGD1, and the select gate line SGS can be independently controlled by the row decoder module 20.

The bit line BL is commonly coupled to one NAND string NS of each of the plurality of string units SU of each block BLK. A plurality of bit lines BL is allocated for each memory unit MU. Each bit line BL is coupled to the sense amplifier module 21.

The source line SL is shared among the plurality of blocks BLK, for example. Note that the source line SL may be provided for each block BLK.

Hereinafter, a set of the plurality of memory cell transistors MC coupled to the common word line WL in one string unit SU will be referred to as a “cell unit CU”. In the example illustrated in FIG. 3, the memory cell transistor MC3 of each of the NAND strings NS0 to NS11 included in the string units SU0 of the memory units MU0 and MU1 is included in one cell unit CU. The page is a unit of data that is collectively written (or collectively read) to the cell unit CU. For example, in a case where the memory cell transistor MC stores 1-bit data, the storage capacity of the cell unit CU is one page. That is, the cell unit CU stores one page data. The cell unit CU may have a storage capacity of two or more pages based on the number of bits of data stored in the memory cell transistor MC. The memory cell transistor MC may be a single level cell (SLC) that stores 1-bit data or a multi level cell (MLC) that stores 2-bit data. The memory cell transistor MC may be a triple level cell (TLC) that stores 3-bit data, a quad level cell (QLC) that stores 4-bit data, or a penta level cell (PLC) that stores 5-bit data.

Hereinafter, a case where the memory cell transistor MC in the user data area 110 is a TLC and the memory cell transistor MC in the user ROM area 120 is an SLC will be described. For example, the block BLK0 is included in the user data area 110, and the block BLK1 is included in the user ROM area 120. In this case, the memory cell transistor MC of the block BLK0 is the TLC, and the memory cell transistor MC of the block BLK1 is the SLC.

Note that the number of the NAND strings NS included in each memory unit MU can be appropriately changed according to the number of stacked semiconductor layers 33 to be described later.

### 1.3 Structure of Memory Cell Array

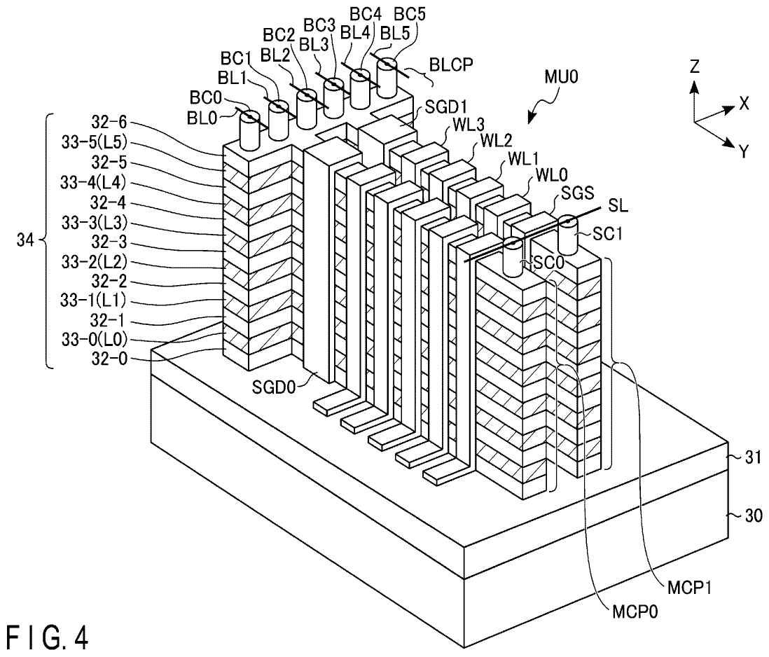

Next, an example of a structure of the memory cell array 18 will be described with reference to FIG. 4. FIG. 4 is a perspective view illustrating an example of a structure of the memory cell array 18. FIG. 4 illustrates a region including a structure corresponding to one memory unit MU0.

The X direction, the Y direction, and the Z direction used in the following description are directions crossing each other. The X direction is substantially parallel to the surface of the semiconductor substrate 30 used for forming the memory device 100 and corresponds to the direction in which the word line WL extends. The Y direction is substantially parallel to the surface of the semiconductor substrate 30 and corresponds to the direction in which the bit line BL extends. The Z direction corresponds to a vertical direction with respect to the surface of the semiconductor substrate 30. In the drawings referred to below, illustration of the configuration of the insulator layer and the like is omitted as appropriate for easy viewing of the drawings.

As illustrated in FIG. 4, the memory device 100 includes, for example, a semiconductor substrate 30, an insulator layer 31, a plurality of insulator layers 32, a plurality of semiconductor layers 33, contact plugs BC0 to BC5, and contact plugs SC0 and SC1.

The insulator layer 31 is provided on the semiconductor substrate 30. The insulator layer 31 includes, for example, silicon oxide (SiO). A structure corresponding to the memory unit MU0 is provided on the insulator layer 31. Specifically, the insulator layers 32 and the semiconductor layers 33 are alternately stacked one by one on the insulator layer 31. The insulator layer 32 includes, for example, silicon oxide (SiO). The semiconductor layer 33 is, for example, silicon doped with impurities. Hereinafter, the alternately stacked insulator layers 32 and semiconductor layers 33 are referred to as a “stacked body 34”.

In the present example, the stacked body 34 includes seven insulator layers 32 and six semiconductor layers 33. Hereinafter, the seven insulator layers 32 will be referred to as insulator layers 32-0 to 32-6 in order from the semiconductor substrate 30 side. The six semiconductor layers 33 are referred to as semiconductor layers 33-0 to 33-5 in order from the semiconductor substrate 30 side.

An interconnect layer including the semiconductor layer 33-0 is referred to as a “layer L0”. Similarly, an interconnect layer including the semiconductor layer 33-1 is referred to as a “layer L1”. An interconnect layer including the semiconductor layer 33-2 is referred to as a “layer L2”. An interconnect layer including the semiconductor layer 33-3 is referred to as a “layer L3”. An interconnect layer including the semiconductor layer 33-4 is referred to as a “layer L4”. An interconnect layer including the semiconductor layer 33-5 is referred to as a “layer L5”.

One stacked body 34 corresponds to one memory unit MU. The stacked body 34 includes a bit line coupling portion BLCP and memory cell units MCP0 and MCP1. The bit line coupling portion BLCP has a portion extending in the X direction. Each of the memory cell units MCP0 and MCP1 has a portion extending in the Y direction. One end of each of the memory cell units MCP0 and MCP1 is coupled to the bit line coupling portion BLCP. In other words, the insulator layers 32 and the semiconductor layers 33 stacked in each memory cell unit MCP are coupled to the insulator layers 32 and the semiconductor layers 33 stacked in the bit line coupling portion BLCP, respectively.

One memory cell unit MCP corresponds to one string unit SU in the memory unit MU. Specifically, the memory cell units MCP0 and MCP1 correspond to the string units SU0 and SU1, respectively. The semiconductor layers 33-0 to 33-5 of each memory cell unit MCP are provided corresponding to the NAND strings NS0 to NS5, respectively. That is, the number of NAND strings NS included in one string unit SU corresponds to the number of stacked semiconductor layers 33. In addition, the semiconductor layer 33 included in the memory cell unit MCP functions as an active area including the channel layers of the memory cell transistors MC and the selection transistors ST1 and ST2. That is, the channel layer of each NAND string NS is provided to extend in a direction (Y direction) parallel to the surface of the semiconductor substrate 30.

The bit lines BL are provided above the stacked body 34. Each bit line BL has a portion extending in the Y direction. The bit line BL is electrically coupled to the NAND string NS (the semiconductor layer 33 of the memory cell unit MCP) via the contact plug BC and the semiconductor layer 33 of the bit line coupling portion BLCP. More specifically, the bit lines BL0 to BL5 are electrically coupled to the upper faces of the contact plugs BC0 to BC5, respectively. Bottom portions of the contact plugs BC0 to BC5 are electrically coupled to the semiconductor layers 33-0 to 33-5, respectively. Each contact plug BC is electrically coupled to any one of the semiconductor layers 33 and is electrically insulated from the other semiconductor layers 33. For example, the contact plug BC0 is electrically coupled to the semiconductor layer 33-0 and is electrically insulated from the semiconductor layers 33-1 to 33-5.

The source line SL is provided above stacked body 34. Source line SL has, for example, a portion extending in the X direction. The source line SL is electrically coupled to each NAND string NS (each semiconductor layer 33 of the memory cell unit MCP) via the contact plug SC. More specifically, the source line SL is electrically coupled to the upper faces of the contact plugs SC0 and SC1. The contact plug SC0 is electrically coupled to each of the semiconductor layers 33-0 to 33-5 on the other end side of the memory cell unit MCP0. The contact plug SC1 is electrically coupled to each of the semiconductor layers 33-0 to 33-5 on the other end side of the memory cell unit MCP1.

A tunnel insulating film, a charge storage layer, and a block insulating film (hereinafter, referred to as a stacked film) not illustrated are stacked on the side face and the upper face of the stacked body 34. In addition, in the Y direction, the select gate line SGS, the word lines WL0 to WL3, and the select gate line SGD are disposed in this order from the contact plug SC side toward the contact plug BC side between the contact plug SC and the contact plug BC (bit line coupling portion BLCP). Each of the select gate line SGS and the word lines WL0 to WL3 has a portion provided to extend in the X direction so as to cover (straddle) the side face and the upper face of the stacked film provided in the memory cell unit MCP of the stacked body 34. The select gate line SGD0 has a portion provided so as to cover the side face and the upper face of the stacked film provided in the memory cell unit MCP0 of the stacked body 34. The select gate line SGD1 has a portion provided so as to cover the side face and the upper face of the stacked film provided in the memory cell unit MCP1 of the stacked body 34.

### 1.3.1 Planar Layout of Memory Cell Array

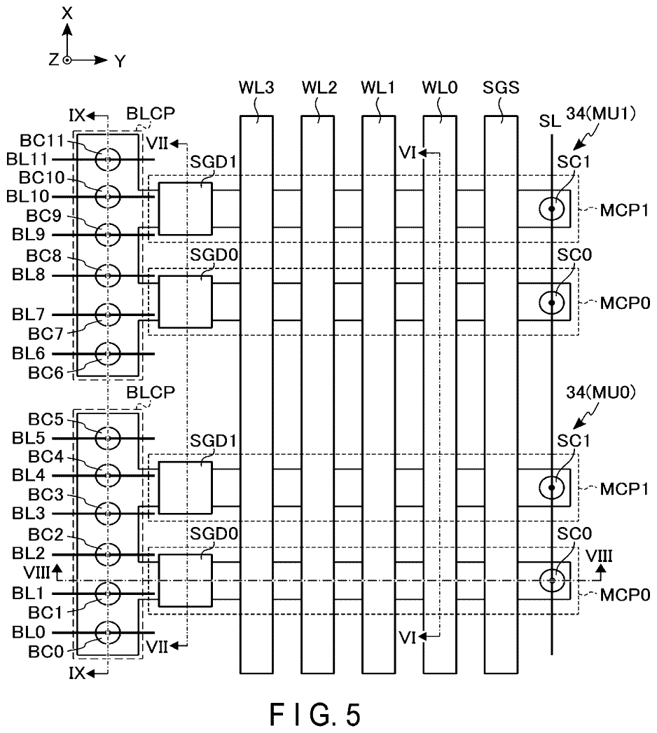

Referring now to FIG. 5, an example of a planar layout of the memory cell array 18 will be described. FIG. 5 is a plan view illustrating an example of a planar layout of the memory cell array 18. FIG. 5 illustrates a region including two adjacent memory units MU0 and MU1.

As illustrated in FIG. 5, the two stacked bodies 34 are disposed side by side in the X direction while being separated from each other.

The bit line coupling portion BLCP of the stacked body 34 corresponding to the memory unit MU0 is provided with the contact plugs BC0 to BC5 respectively coupled to the bit lines BL0 to BL5. The bit line coupling portion BLCP of the stacked body 34 corresponding to the memory unit MU1 is provided with the contact plugs BC6 to BC11 respectively coupled to the bit lines BL6 to BL11. As described above, in the present example, the bit line coupling portion BLCP of the stacked body 34 of one memory unit MU is provided with the six contact plugs BC coupled to the six bit lines BL.

The stacked body 34 corresponding to the memory unit MU0 is provided with contact plugs SC0 and SC1 coupled to the memory cell units MCP0 and MCP1, respectively. Similarly, the stacked body 34 corresponding to the memory unit MU1 is provided with contact plugs SC0 and SC1 coupled to the memory cell units MCP0 and MCP1, respectively. In this manner, each memory cell unit MCP of the stacked body 34 of one memory unit MU is provided with at least one contact plug SC coupled to the source line SL.

The select gate line SGS and the word lines WL0 to WL3 are provided in a region where a plurality of stacked bodies 34 corresponding to one block BLK are formed. Each of the select gate line SGS and the word lines WL0 to WL3 has a portion extending in the X direction and is disposed so as to overlap the plurality of stacked bodies 34. As a result, each of the select gate line SGS and the word lines WL0 to WL3 is shared among the plurality of memory units MU in the same block BLK.

The memory cell units MCP0 and MCP1 of the stacked body 34 corresponding to the memory units MU0 are provided with the select gate lines SGD0 and SGD1, respectively. Similarly, the memory cell units MCP0 and MCP1 of the stacked body 34 corresponding to the memory unit MU1 are provided with the select gate lines SGD0 and SGD1, respectively. As described above, the memory cell units MCP0 and MCP1 of one stacked body 34 are provided with the select gate lines SGD0 and SGD1, respectively. In the same block BLK, the plurality of select gate lines SGD0 are electrically coupled via contacts and interconnects (not illustrated), and the plurality of select gate lines SGD1 are electrically coupled via contacts and interconnects (not illustrated).

### 1.3.2 Cross-Sectional Structure of Memory Cell Array

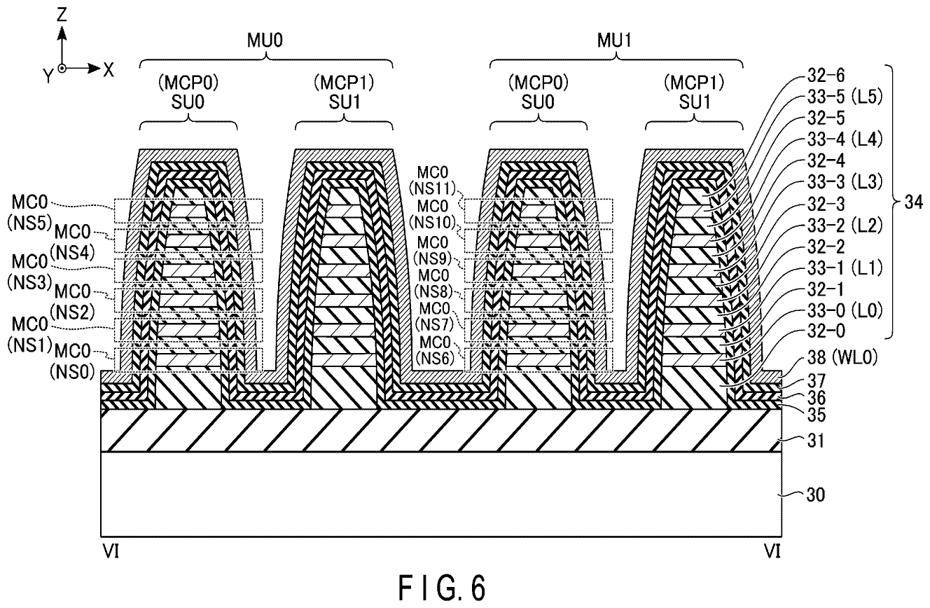

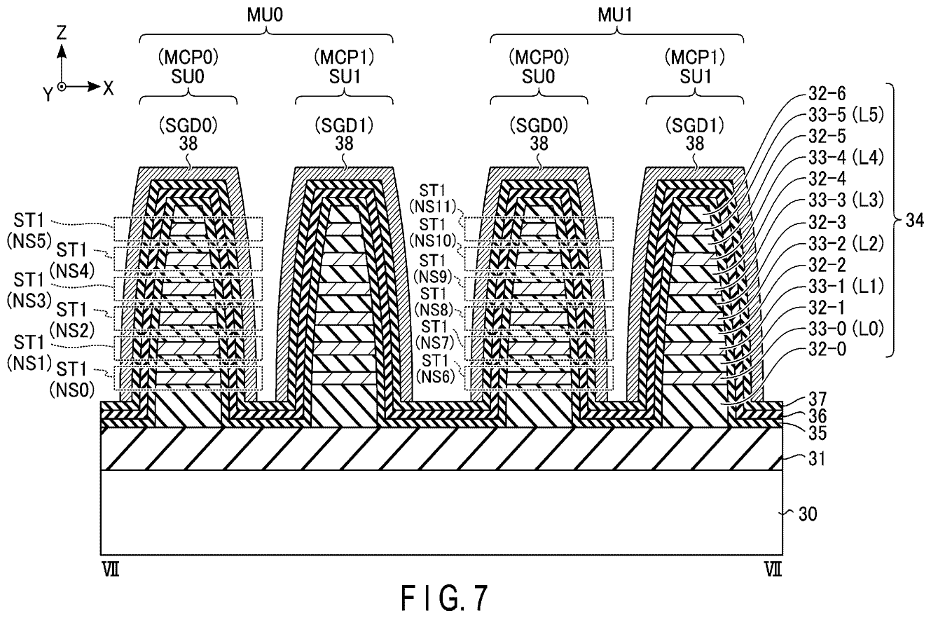

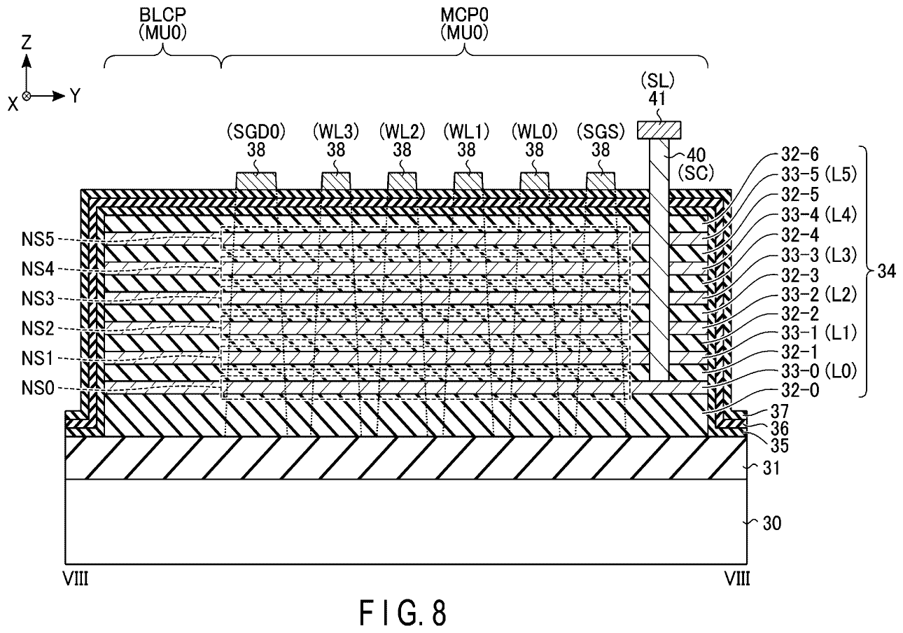

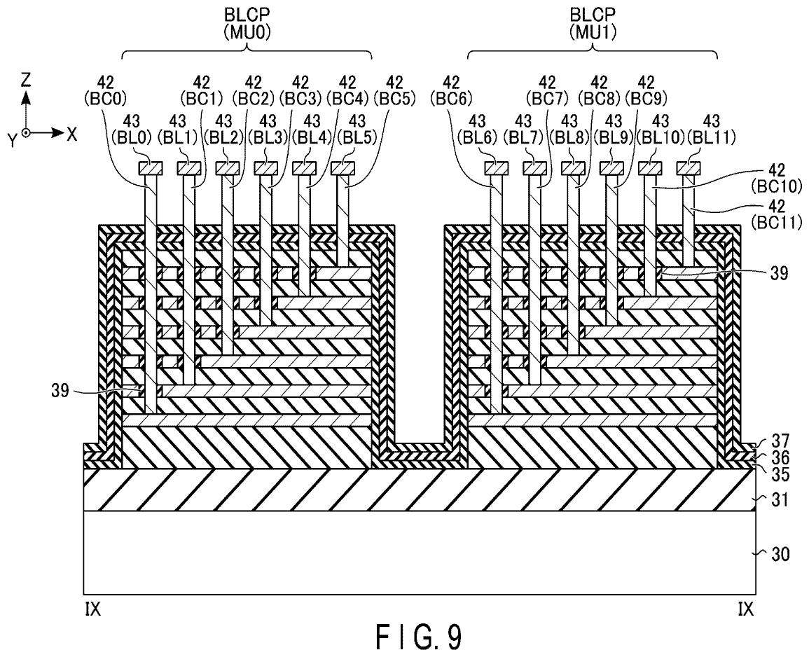

Next, an example of a cross-sectional structure of the memory cell array 18 will be described with reference to FIGS. 6 to 9. FIGS. 6 to 9 are cross-sectional views illustrating an example of a cross-sectional structure of the memory cell array 18. FIG. 6 is a cross-sectional view taken along line VI-VI in FIG. 5. FIG. 6 illustrates a cross section including the word line WL0 and along the X direction. FIG. 7 is a cross-sectional view taken along line VII-VII in FIG. 5. FIG. 7 illustrates a cross section including the select gate lines SGD0 and SGD1 and taken along the X direction. FIG. 8 is a cross-sectional view taken along line VIII-VIII in FIG. 5. FIG. 8 illustrates a cross section of the memory cell unit MCP0 of the memory unit MU0 along the Y direction. FIG. 9 is a cross-sectional view taken along line IX-IX in FIG. 5. FIG. 9 illustrates a cross section of the bit line coupling portion BLCP along the X direction.

As illustrated in FIG. 6, the memory device 100 further includes a tunnel insulating film 35, a charge storage layer 36, a block insulating film 37, and a conductive layer 38.

The tunnel insulating film 35 is continuously provided so as to cover the upper face and the side face of the stacked body 34 of each memory unit MU. In other words, the tunnel insulating film 35 is provided above the insulator layer 31 so as to straddle the stacked body 34 of each memory unit MU. The charge storage layer 36, the block insulating film 37, and the conductive layer 38 are stacked in this order on the tunnel insulating film 35.

Each of the tunnel insulating film 35 and the block insulating film 37 includes, for example, silicon oxide (SiO). The charge storage layer 36 includes, for example, silicon nitride (SiN). The conductive layer 38 contains, for example, tungsten (W). The conductive layer 38 included in the cross section shown in FIG. 6 is used as the word line WL0.

In the memory unit MU0, a portion where the semiconductor layer 33-0 and the word line WL0 in the memory cell units MCP0 and MCP1 are close to each other functions as the memory cell transistor MC0 of the NAND string NS0 included in the string units SU0 and SU1. Similarly, in the memory unit MU1, a portion where the semiconductor layer 33-0 and the word line WL0 in the memory cell units MCP0 and MCP1 are close to each other functions as the memory cell transistor MC0 of the NAND string NS6 included in the string units SU0 and SU1. That is, the memory cell transistors MC0 of the NAND strings NS0 and NS6 are included in the layer L0.

In the memory unit MU0, a portion where the semiconductor layer 33-1 in the memory cell units MCP0 and MCP1 and the word line WL0 are close to each other functions as the memory cell transistor MC0 of the NAND string NS1 included in each of the string units SU0 and SU1. Similarly, in the memory unit MU1, a portion where the semiconductor layer 33-1 in the memory cell units MCP0 and MCP1 and the word line WL0 are close to each other functions as the memory cell transistor MC0 of the NAND string NS7 included in each of the string units SU0 and SU1. That is, the memory cell transistors MC0 of the NAND strings NS1 and NS7 are included in the layer L1.

In the memory unit MU0, a portion where the semiconductor layer 33-2 in the memory cell units MCP0 and MCP1 and the word line WL0 are close to each other functions as the memory cell transistor MC0 of the NAND string NS2 included in each of the string units SU0 and SU1. Similarly, in the memory unit MU1, a portion where the semiconductor layer 33-2 in the memory cell units MCP0 and MCP1 and the word line WL0 are close to each other functions as the memory cell transistor MC0 of the NAND string NS8 included in each of the string units SU0 and SU1. That is, the memory cell transistors MC0 of the NAND strings NS2 and NS8 are included in the layer L2.

In the memory unit MU0, a portion where the semiconductor layer 33-3 in the memory cell units MCP0 and MCP1 and the word line WL0 are close to each other functions as the memory cell transistor MC0 of the NAND string NS3 included in each of the string units SU0 and SU1. Similarly, in the memory unit MU1, a portion where the semiconductor layer 33-3 in the memory cell units MCP0 and MCP1 and the word line WL0 are close to each other functions as the memory cell transistor MC0 of the NAND string NS9 included in each of the string units SU0 and SU1. That is, the memory cell transistors MC0 of the NAND strings NS3 and NS9 are included in the layer L3.

In the memory unit MU0, a portion where the semiconductor layer 33-4 in the memory cell units MCP0 and MCP1 and the word line WL0 are close to each other functions as the memory cell transistor MC0 of the NAND string NS4 included in each of the string units SU0 and SU1. Similarly, in the memory unit MU1, a portion where the semiconductor layer 33-4 in the memory cell units MCP0 and MCP1 and the word line WL0 are close to each other functions as the memory cell transistor MC0 of the NAND string NS10 included in each of the string units SU0 and SU1. That is, the memory cell transistors MC0 of the NAND strings NS4 and NS10 are included in the layer L4.

In the memory unit MU0, a portion where the semiconductor layer 33-5 in the memory cell units MCP0 and MCP1 and the word line WL0 are close to each other functions as the memory cell transistor MC0 of the NAND string NS5 included in each of the string units SU0 and SU1. Similarly, in the memory unit MU1, a portion where the semiconductor layer 33-5 in the memory cell units MCP0 and MCP1 and the word line WL0 are close to each other functions as the memory cell transistor MC0 of the NAND string NS11 included in each of the string units SU0 and SU1. That is, the memory cell transistors MC0 of the NAND strings NS5 and NS11 are included in the layer L5.

Note that the cross-sectional structure along the X direction is similar between the cross-sectional structure including the word line WL0 and the cross-sectional structure including the other word lines WL. In addition, the cross-sectional structure along the X direction is similar between the cross-sectional structure including the word line WL0 and the cross-sectional structure including the select gate line SGS. That is, the plurality of memory cell transistors MC1 to MC3 and the plurality of selection transistors ST2 allocated to the NAND strings NS0 and NS6 are included in the layer L0. The plurality of memory cell transistors MC1 to MC3 and the plurality of selection transistors ST2 allocated to the NAND strings NS1 and NS7 are included in the layer L1. The plurality of memory cell transistors MC1 to MC3 and the plurality of selection transistors ST2 allocated to the NAND strings NS2 and NS8 are included in the layer L2. The plurality of memory cell transistors MC1 to MC3 and the plurality of selection transistors ST2 allocated to the NAND strings NS3 and NS9 are included in the layer L3. The plurality of memory cell transistors MC1 to MC3 and the plurality of selection transistors ST2 allocated to the NAND strings NS4 and NS10 are included in the layer L4. The plurality of memory cell transistors MC1 to MC3 and the plurality of selection transistors ST2 allocated to the NAND strings NS5 and NS11 are included in the layer L5.

As shown in FIG. 7, the cross-sectional structure including the select gate lines SGD0 and SGD1 and along the X direction includes the conductive layer 38 with a different shape than the cross-sectional structure including the word line WL0 and along the X direction.

Specifically, the conductive layer 38 is separated for each memory cell unit MCP in the cross section including the select gate lines SGD0 and SGD1 and along the X direction. In other words, the conductive layer 38 is provided independently for each string unit SU in the cross section along the X direction including the plurality of select gate lines SGD.

Other structures of the cross section including the select gate lines SGD0 and SGD1 and along the X direction are similar to the structures of the cross section including the word line WL0 and along the X direction. That is, the plurality of selection transistors ST1 allocated to the NAND strings NS0 and NS6 are included in the layer L0. The plurality of selection transistors ST1 allocated to the NAND strings NS1 and NS7 are included in the layer L1. The plurality of selection transistors ST1 allocated to the NAND strings NS2 and NS8 are included in the layer L2. The plurality of selection transistors ST1 allocated to the NAND strings NS3 and NS9 are included in the layer L3. The plurality of selection transistors ST1 allocated to the NAND strings NS4 and NS10 are included in the layer L4. The plurality of selection transistors ST1 allocated to the NAND strings NS5 and NS11 are included in the layer L5.

In addition, as illustrated in FIGS. 6 and 7, the cross-sectional shape of the stacked body 34 along the X direction has a tapered shape. As described above, in the memory device 100, the cross-sectional shape of the stacked body 34 along the X direction can change based on processing characteristics of dry etching or the like in the process of forming the stacked body 34. For this reason, the cross-sectional shape of the stacked body 34 along the X direction may be a reverse tapered shape, a bowing shape, or the like.

In the present example, the width of each of the semiconductor layers 33-0 to 33-5 in the X direction included in the stacked body 34 and the length of the side face of each of the semiconductor layers 33-0 to 33-5 included in the stacked body 34 along the Z direction are different for each layer. As a result, the gate widths of the memory cell transistors MC included in the NAND strings NS0 to NS5 are different for each layer.

Specifically, the gate width of the memory cell transistor MC provided in the layer L0, that is, the length of the word line WL adjacent to the memory cell transistor MC and in the Z direction is shorter than the gate width of the memory cell transistor MC provided in the layer L1. The gate width of the memory cell transistor MC provided in the layer L1 is shorter than the gate width of the memory cell transistor MC provided in the layer L2. The gate width of the memory cell transistor MC provided in the layer L2 is shorter than the gate width of the memory cell transistor MC provided in the layer L3. The gate width of the memory cell transistor MC provided in the layer L3 is shorter than the gate width of the memory cell transistor MC provided in the layer L4. Further, the gate width of the memory cell transistor MC provided in the layer L4 is shorter than the gate width of the memory cell transistor MC provided in the layer L5. That is, in the present example, the gate width of the memory cell transistor MC is longer as the distance from the semiconductor substrate 30 increases.

In addition, the length (width) of the semiconductor layer 33-0 provided in the layer L0 in the X direction is longer than the length of the semiconductor layer 33-1 provided in the layer L1 in the X direction. The length of the semiconductor layer 33-1 provided in the layer L1 in the X direction is longer than the length of the semiconductor layer 33-2 provided in the layer L2 in the X direction. The length of the semiconductor layer 33-2 provided in the layer L2 in the X direction is longer than the length of the semiconductor layer 33-3 provided in the layer L3 in the X direction. The length of the semiconductor layer 33-3 provided in the layer L3 in the X direction is longer than the length of the semiconductor layer 33-4 provided in the layer L4 in the X direction. Further, the length of the semiconductor layer 33-4 provided in the layer L4 in the X direction is longer than the length of the semiconductor layer 33-5 provided in the layer L5 in the X direction. That is, in the present example, the length in the X direction of the semiconductor layer 33 used as part of the memory cell transistor MC is shorter as the distance from the semiconductor substrate 30 increases. As shown in FIG. 8, the memory device 100 further includes a conductive member 40 and a conductive layer 41.

The conductive member 40 has a columnar shape extending along the Z direction, for example, and is used as the contact plug SC. The conductive member 40 penetrates the block insulating film 37, the charge storage layer 36, the tunnel insulating film 35, the insulator layers 32-6 to 32-1, and the semiconductor layers 33-5 and 33-1 in the vicinity of an end of the memory cell unit MCP, that is, the end being away from the bit line coupling portion BLCP. The bottom portion of the conductive member 40 reaches the semiconductor layer 33-0. Thus, the conductive member 40 is electrically coupled to the semiconductor layers 33-0 to 33-5. The conductive member 40 contains, for example, tungsten (W).

The conductive layer 41 is provided on the conductive member 40. The conductive layer 41 has, for example, a portion extending along the X direction, and is used as the source line SL. That is, the conductive layer 41 is electrically coupled to each of the semiconductor layers 33-0 to 33-5 via the conductive member 40 (contact plug SC). The conductive layer 41 contains, for example, copper (Cu).

As illustrated in FIG. 8, the width of the conductive layer 38 separated for each interconnect in the Y direction varies according to the height. As described above, in the memory device 100, the width of the conductive layer 38 separated for each interconnect in the Y direction can be changed based on processing characteristics of dry etching or the like in the process of separating the conductive layer 38 for each interconnect. In the present example, the width of the conductive layer 38 separated for each interconnect in the Y direction is shorter as the distance from the semiconductor substrate 30 increases. In such a case, the gate length of the memory cell transistor MC is different for each NAND string NS.

Specifically, the gate length of the memory cell transistor MC provided in the layer L0 is longer than the gate length of the memory cell transistor MC provided in the layer L1. The gate length of the memory cell transistor MC provided in the layer L1 is longer than the gate length of the memory cell transistor MC provided in the layer L2. The gate length of the memory cell transistor MC provided in the layer L2 is longer than the gate length of the memory cell transistor MC provided in the layer L3. The gate length of the memory cell transistor MC provided in the layer L3 is longer than the gate length of the memory cell transistor MC provided in the layer L4. Further, the gate length of the memory cell transistor MC provided in the layer L4 is longer than the gate length of the memory cell transistor MC provided in the layer L5. That is, in the present example, the gate length of the memory cell transistor MC is shorter as the distance from the semiconductor substrate 30 increases.

As shown in FIG. 9, the memory device 100 further includes a plurality of conductive members 42, a plurality of conductive layers 43, and a plurality of insulator layers 39.

Each conductive member 42 has a columnar shape extending in the Z direction, for example, and is used as a contact plug BC. Specifically, in the bit line coupling portion BLCP of the memory unit MU0, six conductive members 42 (contact plugs BC0 to BC5) are provided on the semiconductor layers 33-0 to 33-5, respectively. In the bit line coupling portion BLCP of the memory unit MU1, six conductive members 42 (contact plugs BC6 to BC11) are provided with on the semiconductor layers 33-0 to 33-5, respectively. In addition, each conductive member 42 penetrates the block insulating film 37, the charge storage layer 36, and the tunnel insulating film 35.

The conductive member 42 coupled to the semiconductor layer 33-0 included in the layer L0 further penetrates the semiconductor layers 33-1 to 33-5 included in the layers L1 to L5. The conductive member 42 coupled to the semiconductor layer 33-0 and each of the semiconductor layers 33-1 to 33-5 are separated and insulated by the insulator layer 39.

The conductive member 42 coupled to the semiconductor layer 33-1 included in the layer L1 further penetrates the semiconductor layers 33-2 to 33-5 included in the layers L2 to L5. The conductive member 42 coupled to the semiconductor layer 33-1 and each of the semiconductor layers 33-2 to 33-5 are separated and insulated by the insulator layer 39.

The conductive member 42 coupled to the semiconductor layer 33-2 included in the layer L2 further penetrates the semiconductor layers 33-3 to 33-5 included in the layers L3 to L5. The conductive member 42 coupled to the semiconductor layer 33-2 and each of the semiconductor layers 33-3 to 33-5 are separated and insulated by the insulator layer 39.

The conductive member 42 coupled to the semiconductor layer 33-3 included in the layer L3 further penetrates the semiconductor layers 33-4 and 33-5 included in the layers L4 and L5. The conductive member 42 coupled to the semiconductor layer 33-3 and each of the semiconductor layers 33-4 and 33-5 are separated and insulated by the insulator layer 39.

The conductive member 42 coupled to the semiconductor layer 33-4 included in the layer L4 further penetrates the semiconductor layer 33-5 included in the layer L5. The conductive member 42 coupled to the semiconductor layer 33-4 and the semiconductor layer 33-5 are separated and insulated by the insulator layer 39. The insulator layer 39 includes, for example, silicon oxide (SiO).

A plurality of conductive layers 43 is provided on the plurality of conductive members 42. The conductive layer 43 has, for example, a portion extending in the Y direction, and is used as the bit line BL. Specifically, the conductive layer 43 provided on the conductive member 42 corresponding to the contact plug BC0 is used as the bit line BL0. The conductive layer 43 provided on the conductive member 42 corresponding to the contact plug BC1 is used as the bit line BL1. The conductive layer 43 provided on the conductive member 42 corresponding to the contact plug BC2 is used as the bit line BL2. Similarly, each conductive layer 43 is used as the bit line BL associated with the semiconductor layer 33 coupled via the contact plug BC. The conductive layer 43 contains, for example, copper (Cu).

### 1.4 Configuration of Sense Amplifier Module and Data Register

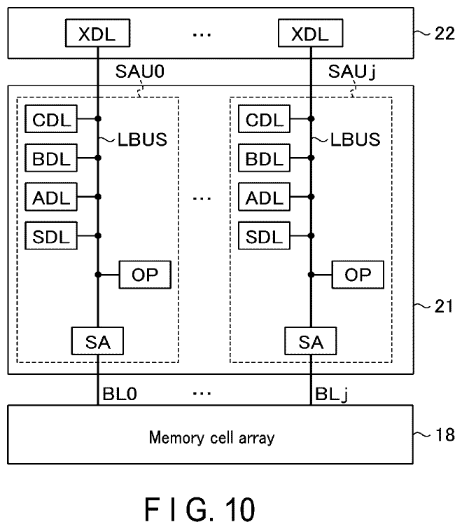

Next, an example of a configuration of the sense amplifier module 21 and the data register 22 will be described with reference to FIG. 10. FIG. 10 is a block diagram illustrating an example of a configuration of the sense amplifier module 21 and the data register 22.

As illustrated in FIG. 10, the sense amplifier module 21 includes a plurality of sense amplifier units SAU provided for each bit line BL. In the example illustrated in FIG. 10, the sense amplifier module 21 includes sense amplifier units SAU0 to SAUj (j is an integer of one or more). The sense amplifier units SAU0 to SAUj are coupled to the bit lines BL0 to BLj, respectively. The data register 22 includes, for example, a plurality of latch circuits XDL each of which is provided for each sense amplifier unit SAU. The read operation in the memory device 100 roughly includes a cell read operation and a cache read operation. The cell read operation is an operation of reading data from the memory cell array 18 to the data register 22, that is, to the plurality of latch circuits XDL, and the cache read operation is an operation of reading (externally outputting) data from the data register 22 to the memory controller 200 via the input/output circuit 10.

For example, the sense amplifier unit SAU includes a sense circuit SA, an operation unit OP, and latch circuits SDL, ADL, BDL, and CDL. The sense circuit SA, the operation unit OP, and the latch circuits SDL, ADL, BDL, and CDL are commonly coupled to the corresponding latch circuit XDL via a bus LBUS. In other words, the latch circuit XDL, the sense circuit SA, the operation unit OP, and the latch circuits SDL, ADL, BDL, CDL, and XDL are coupled so as to be able to transmit and receive data to and from each other via the bus LBUS. The number of latch circuits included in the sense amplifier unit SAU can be designed based on the number of bits of data that can be stored in one memory cell transistor MC.

The sense circuit SA senses the data read to the corresponding bit line BL at the time of the read operation, and determines whether the read data is “0” or “1”. The sense circuit SA applies a voltage to the bit line BL based on the write data at the time of the write operation.

The operation unit OP performs various logical operations using data stored in the sense circuit SA and the latch circuits XDL, SDL, ADL, BDL, and CDL.

The latch circuits SDL, ADL, BDL, CDL, and XDL temporarily store data. For example, at the time of the read operation, the read data determined by the sense circuit SA is transferred to any of the latch circuits SDL, ADL, BDL, CDL, and XDL via the operation unit OP. For example, at the time of the write operation, the write data transferred from the input/output circuit 10 to the latch circuit XDL is transferred to any of the latch circuits SDL, ADL, BDL, and CDL.

### 1.4.1 Circuit Configuration of Sense Amplifier Unit SAU

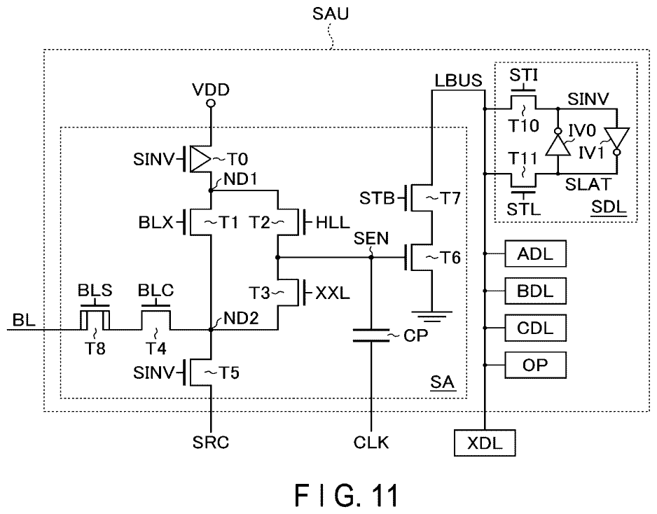

Next, an example of a circuit configuration of the sense amplifier unit SAU will be described with reference to FIG. 11. FIG. 11 is a circuit diagram illustrating an example of a circuit configuration of the sense amplifier unit SAU. Note that, in the example illustrated in FIG. 11, in order to simplify the description, the circuit configurations of the latch circuits ADL, BDL, and CDL and the operation unit OP are omitted.

As illustrated in FIG. 11, the sense circuit SA includes transistors T0 to T8 and a capacitance element CP. The latch circuit SDL includes inverters IV0 and IV1 and transistors T10 and T11. The transistor T0 is a P-type metal-oxide-semiconductor (MOS) transistor. Each of the transistors T1 to T7, T10, and T11 is an N-type MOS transistor. The transistor T8 is an N-type MOS transistor having a higher withstand voltage than each of the transistors T0 to T7.

The source of the transistor TO is coupled to the power supply line. The drain of the transistor TO is coupled to a node ND1. The gate of the transistor TO is coupled to a node SINV in the latch circuit SDL.

The drain of the transistor T1 is coupled to the node ND1. The source of the transistor T1 is coupled to a node ND2. A control signal BLX is input to the gate of the transistor T1.

The drain of the transistor T2 is coupled to the node ND1. The source of the transistor T2 is coupled to a node SEN. A control signal HLL is input to the gate of the transistor T2.

The drain of the transistor T3 is coupled to the node SEN. The source of the transistor T3 is coupled to the node ND2. A control signal XXL is input to the gate of the transistor T3.

The drain of the transistor T4 is coupled to the node ND2. A control signal BLC is input to the gate of the transistor T4.

The drain of the transistor T5 is coupled to the node ND2. The source of the transistor T5 is coupled to a node SRC. The gate of the transistor T5 is coupled to, for example, the node SINV in the latch circuit SDL.

The source of the transistor T6 is grounded. The gate of the transistor T6 is coupled to the node SEN.

The drain of the transistor T7 is coupled to the bus LBUS. The source of the transistor T7 is coupled to the drain of the transistor T6. The control signal STB is input to the gate of the transistor T7.

One electrode of the capacitance element CP is coupled to the node SEN. A clock signal CLK is input to the other electrode of the capacitance element CP.

The drain of the transistor T8 is coupled to the source of the transistor T4. The source of the transistor T8 is coupled to the associated bit line BL. A control signal BLS is input to the gate of the transistor T8.

The input node of the inverter IV0 is coupled to a node SLAT. The output node of the inverter IV0 is coupled to the node SINV.

The input node of the inverter IV1 is coupled to the node SINV. The output node of the inverter IV1 is coupled to the node SLAT.

One end of a current path of the transistor T10 is coupled to the node SINV. The other end of the current path of the transistor T10 is coupled to the bus LBUS. A control signal STI is input to the gate of the transistor T10.

One end of a current path of the transistor T11 is coupled to the node SLAT. The other end of the current path of the transistor T11 is coupled to the bus LBUS. A control signal STL is input to the gate of the transistor T11.

For example, the data stored in the node SLAT corresponds to the data stored in the latch circuit SDL. On the other hand, the data stored in the node SINV corresponds to inverted data of the data stored in the node SLAT.

The circuit configuration of each of the latch circuits ADL, BDL, and CDL are similar to, for example, that of the latch circuit SDL.

In the circuit configuration of the sense amplifier unit SAU described above, for example, a power supply voltage VDD is applied to the power supply line coupled to the source of the transistor TO. For example, a ground voltage VSS is applied to the node SRC. Each of the control signals BLX, HLL, XXL, BLC, STB, BLS, STI, and STL and the clock signal CLK is generated by, for example, the sequencer 15. The node SEN may be referred to as a sense node of the sense circuit SA.

The sense circuit SA determines the data read to the bit line BL based on the timing at which the control signal STB is asserted at the “H” level.

Next, the operation of the sense circuit SA at the time of the read operation will be briefly described. At the time of reading, first, the node SINV is set to the “L” level, and the transistor T0 is turned on. Furthermore, in a case where the transistors T1 and T8 are turned on and a signal BLC (clamp voltage) is applied to the transistor T4, the bit line BL is precharged (charged) to a voltage corresponding to the signal BLC via the transistors T0, T1, T4, and T8. In a case where the transistor T2 is turned on, the node SEN is precharged to a voltage VDD.

After the transistor T2 is turned off, the transistor T3 is turned on. In a case where the threshold voltage of the memory cell transistor MC (hereinafter, referred to as a “selected memory cell transistor MC”) to be read is lower than the read voltage, the selected memory cell transistor MC is turned on (hereinafter, referred to as an “ON-cell”). In this case, since the current flows from the bit line BL to the source line SL, the potential of the node SEN decreases. In a case where the potential of the node SEN is lower than the threshold voltage of the transistor T6, the transistor T6 is turned off. On the other hand, in a case where the threshold voltage of the selected memory cell transistor MC is equal to or higher than the read voltage, the selected memory cell transistor MC is turned off (hereinafter, referred to as an “Off-cell”). In this case, since almost no current flows from the bit line BL to the source line SL, the potential of the node SEN is almost maintained. As a result, the transistor T6 is turned on.

Then, in a case where the control signal STB is set to the “H” level and the transistor T7 is turned on (hereinafter, referred to as a “strobe operation”), a potential according to the determination of on/off of the transistor T6 is read to the bus LBUS. In a case where the transistor T6 is turned off, that is, in a case of the ON-cell, the bus LBUS is set to the “H” level by the strobe operation. In a case where the transistor T6 is turned on, that is, in a case of the Off-cell, the bus LBUS is set to the “L” level by the strobe operation. In a case where the bus LBUS is at the “H” level, for example, “1” data is stored in the latch circuit SDL. On the other hand, in a case where the bus LBUS is at the “L” level, for example, “0” data is stored in the latch circuit SDL.

In a case where the latch circuit SDL stores “1” data, the node SINV is at the “L” level. On the other hand, in a case where the latch circuit SDL stores “0” data, the node SINV is at the “H” level.

### 1.5 Threshold Voltage Distribution of Memory Cell Transistor

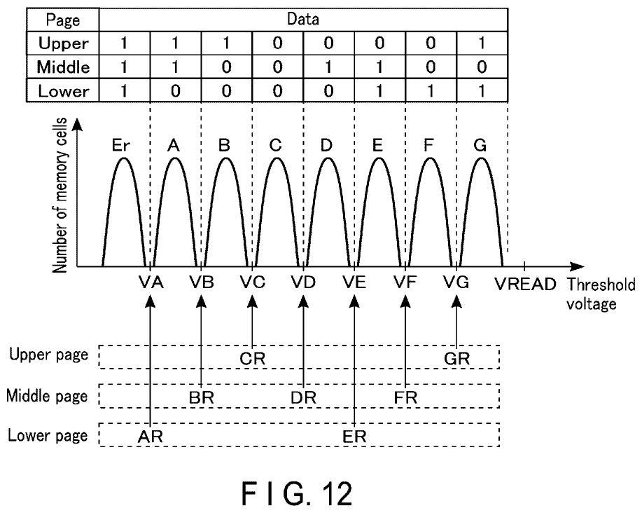

Next, an example of the threshold voltage distribution of the memory cell transistor MC will be described with reference to FIG. 12. FIG. 12 is a diagram illustrating a threshold voltage distribution and data allocation in a case where the memory cell transistor MC is a TLC capable of storing 3-bit data.

As illustrated in FIG. 12, in a case where the memory cell transistor MC stores 3-bit data, the distribution of the threshold voltage is divided into eight. These eight threshold voltage distributions (threshold voltage ranges) are referred to as an Er state, an A state, a B state, a C state, a D state, an E state, an F state, and a G state in order from the lowest threshold voltage.

The voltages VA to VG are verification voltages used in the program verification operation of each of the A state to the G state at the time of the write operation. The voltages VA to VG are voltages applied to the selected word line WL at the time of the program verification operation. The voltage VREAD is a voltage applied to the non-selected word line WL at the time of the read operation (and at the time of the program verification operation). In a case where the voltage VREAD is applied to the gate of the memory cell transistor MC, the memory cell transistor MC is turned on regardless of stored data. The relationship between the voltages VA to VG and the voltage VREAD is VA<VB<VC<VD<VE<VF<VG<VREAD.

The Er state corresponds to an erase state of the memory cell transistor MC. The A state to G state correspond to a state in which charges are injected into the charge storage layer of the memory cell transistor MC and data is written. The threshold voltage of the memory cell transistor MC included in the Er state is less than the voltage VA. The threshold voltages of the memory cell transistors MC included in the A state to the F state are equal to or more than the voltage VA and less than the voltage VB to the voltage VF or more and less than the voltage VG. The threshold voltage of the memory cell transistor MC included in the G state is equal to or more than the voltage VG and less than the voltage VREAD.

The set value of the verification voltage and the set value of the read voltage corresponding to each state may be the same or different. Hereinafter, in order to simplify the description, a case where the verification voltage and the read voltage have the same set value will be described.

Hereinafter, the read operation using the voltages VA to VG will be referred to as read operations AR to GR, respectively. The read operation AR determines whether the threshold voltage of the memory cell transistor MC is less than the voltage VA. The read operation BR determines whether the threshold voltage of the memory cell transistor MC is less than the voltage VB. The read operation CR determines whether the threshold voltage of the memory cell transistor MC is less than the voltage VC. The same applies hereinafter.

As described above, the threshold voltage of each memory cell transistor MC belongs to any of the eight threshold voltage distributions. As a result, each of the memory cell transistors MC can take eight types of states. By allocating these states to the data “000” to “111” in binary numeral, each memory cell transistor MC can store 3-bit data. Hereinafter, the 3-bit data is referred to as a “Lower bit”, a “Middle bit”, and an “Upper bit” in order from the Lower bit. A set of Lower bits stored in the memory cell transistors MC included in the same cell unit CU is referred to as “Lower page data”, a set of Middle bits is referred to as “Middle page data”, and a set of Upper bits is referred to as “Upper page data”.

In the example shown in FIG. 12, data of “Upper bit/Middle bit/Lower bit” is allocated to the memory cell transistor MC included in each state as shown below.
Er state: “111” data
A state: “110” data
B state: “100” data
C state: “000” data
D state: “010” data
E state: “011” data
F state: “001” data
G state: “101” data

In a case where the data allocated in this manner is read, the Lower bit is determined by the read operations AR and ER. The Middle bit is determined by the read operations BR, DR, and FR. The Upper bit is determined by the read operations CR and GR. The values of the Lower bit, the Middle bit, and the Upper bit are determined by two, three, and two read operations, respectively. Hereinafter, this data allocation is referred to as a “2-3-2 code”. Note that the allocation of data to Er to G states is not limited to the 2-3-2 code.

### 1.6 Read Operation

Next, the read operation will be described. As described with reference to FIGS. 7 and 8, the size (gate length, gate width, and the like) of the memory cell transistor MC of each layer L differs depending on the processing characteristics of the stacked body 34 and the conductive layer 38 (word line WL). Therefore, even in a case where the same write condition is applied, the threshold voltage distribution can be shifted according to the layer L. In addition, the variation amount of the threshold voltage due to disturbance or the like may also be different for each layer L. Therefore, in the present embodiment, the bit lines BL can be grouped for each layer L, and shift values of different read voltages can be set for each group (hereinafter, referred to as a “BL group”) of the bit lines BL. That is, different read conditions can be set for each BL group. Hereinafter, the read operation in which the read voltage is shifted is referred to as “shift read”.

### 1.6.1 Shift Table

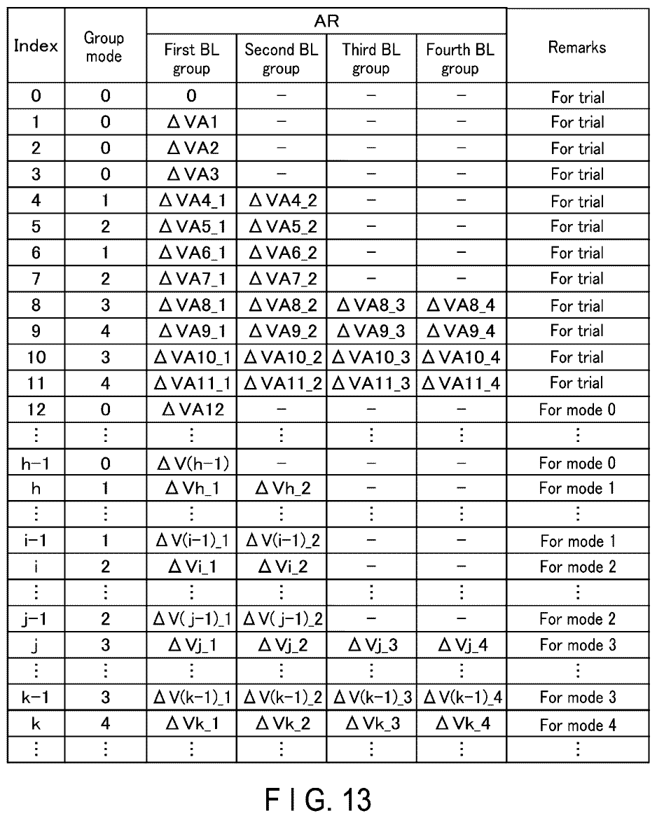

Next, an example of the shift table 221 will be described with reference to FIG. 13. FIG. 13 is a table illustrating an example of the shift table 221. In the example illustrated in FIG. 13, in order to simplify the description, the shift values for each BL group in the read operations BR to GR are omitted.

As illustrated in FIG. 13, the shift table 221 is a table indicating correction values (shift values) of the read voltage. The shift table 221 includes a plurality of entries. Each entry includes an index, a group mode of the BL group, and a shift value for each BL group in each of the read operations AR to GR.

An index number is sequentially allocated to each entry. For example, index 0 indicates a case where a read voltage of an initial value is used. That is, index 0 indicates a case where the shift value of the read voltage is 0. For example, the read voltage of the read operation AR at index 0 is the voltage VA described with reference to FIG. 12.

For example, index 0 to index 11 are used for trial of the shift read using a preset shift value. In a case where the ECC process of the read data fails in the read operation, the CPU 230 counts up the index number and executes the shift read again (hereinafter, referred to as “retry read”). For example, as the index number is counted up, the degree of correction of the shift value increases. For example, the shift value ΔVA1 of index 1, the shift value ΔVA2 of index 2, and the shift value ΔVA3 of index 3 have a relationship of ΔVA1<ΔVA2<ΔVA3. Note that the shift value may not increase with the count up of the index number. For example, a shift value used for a different countermeasure such as a data retention countermeasure, a read disturb countermeasure, or a temperature crossing countermeasure may be set for each index.

For example, the twelfth and subsequent indexes are indexes selected based on the result of the Vth tracking operation. The Vth tracking operation is an operation of searching for an optimum read voltage, that is, a threshold voltage (Vth) by repeating a plurality of read operations (referred to as “tracking read”) while shifting the read voltage. For example, in a case where the ECC process fails in the shift read using index 11, the CPU 230 executes the Vth tracking operation. For example, an index at a least-square distance from the shift value calculated by the Vth tracking operation is set as the history value in the read level management table 222. The history value is a value of the index used in the previous read operation.

More specifically, for index 12 to index (h−1) (h is an integer greater than 12), shift values corresponding to the group mode 0 are registered. For example, in a case where the Vth tracking operation corresponding to the group mode 0 is executed, the CPU 230 sets, as the history value, an index closest to the shift value calculated by tracking among index 12 to index (h−1).

For index (h) to index (i−1) (i is an integer greater than h), shift values corresponding to group mode 1 are registered. For example, in a case where executing the Vth tracking operation corresponding to the group mode 1, the CPU 230 sets, as the history value, an index closest to the shift value calculated by tracking among index (h) to index (i−1).

For index (i) to index (j−1) (i is an integer greater than i), shift values corresponding to group mode 2 are registered. For example, in a case where the Vth tracking operation corresponding to the group mode 2 is executed, the CPU 230 sets, as the history value, an index closest to the shift value calculated by tracking among index (i) to index (j−1).

For index (j) to index (k−1) (k is an integer greater than j), shift values corresponding to the group mode 3 are registered. For example, in a case where executing the Vth tracking operation corresponding to the group mode 3, the CPU 230 sets, as the history value, an index closest to the shift value calculated by tracking among index (j) to index (k−1).

For index (k), index (k+1), . . . , shift values corresponding to the group mode 4 are registered. For example, in a case where the Vth tracking operation corresponding to the group mode 4 is executed, the CPU 230 sets, as the history value, an index closest to the shift value calculated by tracking from among index (k), index (k+1), . . . .

The group mode (also simply referred to as a “mode”) indicates grouping of the bit lines BL. The mode 0 indicates a case where the number of groups is one, that is, a case where the bit line BL is not divided into a plurality of groups. In the entry (index 0 to index 3 and the like) in which the mode 0 is set, a common shift value is set to each bit line BL. In this case, the shift value of the first BL group is diverted.

For example, the mode 1 and the mode 2 show a case where the bit line BL (layer L) is divided into two groups. The grouping of the bit line BL (layer L) is different between the mode 1 and the mode 2. For example, in the mode 1, the bit lines BL corresponding to the layers L0 to L2 belong to the first BL group, and the bit lines BL corresponding to the layers L3 to L5 belong to the second BL group. On the other hand, for example, in the mode 2, the bit lines BL corresponding to the layers L0 and L1 belong to the first BL group, and the bit lines BL corresponding to the layers L2 to L5 belong to the second BL group.

For example, the mode 3 and the mode 4 show a case where the bit line BL (layer L) is divided into four groups. The grouping of the bit line BL (layer L) is different between the mode 3 and the mode 4. Note that the example illustrated in FIG. 13 illustrates a case where the number of groups of the BL group is one, two, or four, but the number of groups is not limited thereto.

One or more shift values of the read operations AR to GR are set for each index according to the group mode. For example, in the case of the mode 0 (in a case where the number of groups is 1), the shift value of the first BL group is used. In the case of mode 1 or mode 2 (in a case where the number of groups is 2), the shift values of the first and second BL groups are used. The shift values of the first and second BL groups are different from each other. For example, index 4 is the mode 1. The shift value of the first BL group of the read operation AR of index 4 is ΔV4_1, and the shift value of the second BL group is ΔV4_2. The shift values ΔV4_1 and ΔV4_2 are different from each other. For example, index 5 is the mode 2. The shift value of the first BL group of the read operation AR of index 5 is ΔV5_1, and the shift value of the second BL group is ΔV5_2. The shift values ΔV5_1 and ΔV5_2 are different from each other.

In the case of the mode 3 or the mode 4 (in a case where the number of groups is 4), the shift values of the first to fourth BL groups are used. The shift values of the first to fourth BL groups are different from each other. For example, index 8 is the mode 3. The shift value of the first BL group of the read operation AR of index 8 is ΔV8_1, and the shift value of the second BL group is ΔV8_2. Further, the shift value of the third BL group of the read operation AR of index 8 is ΔV8_3, and the shift value of the fourth BL group is ΔV8_4. The shift values ΔV8_1, ΔV8_2, ΔV8_3, and ΔV8_4 are different from each other. For example, index 9 is the mode 4. The shift value of the first BL group of the read operation AR of index 9 is ΔV9_1, and the shift value of the second BL group is ΔV9_2. Further, the shift value of the third BL group of the read operation AR of index 9 is ΔV9_3, and the shift value of the fourth BL group is ΔV9_4. The shift values ΔV9_1, ΔV9_2, ΔV9_3, and ΔV9_4 are different from each other.

Note that, in the example illustrated in FIG. 13, a shift value is set for each index, but a shifted read voltage (initial voltage+shift value) may be set. For example, at index 0, the voltage VA is set as the first BL group of the read operation AR. Furthermore, for example, at index 1, the voltage VA+ΔVA1 is set as the first BL group of the read operation AR.

### 1.6.2 Read Level Management Table

Next, an example of the read level management table 222 will be described with reference to FIG. 14. FIG. 14 is a table illustrating an example of the read level management table 222.

As illustrated in FIG. 14, the read level management table 222 is a table that manages the history of the read level (shift value of the read voltage) of each word line WL. The read level management table 222 includes a plurality of entries. Each entry includes a block BLK number, a word line WL number, and a history value (index) of the Lower page, the Middle page, and the Upper page. The history value is a value of the index used in the previous read operation.

Each entry corresponds to one word line WL. Each entry may correspond to a plurality of word lines. As an initial value of the history value, index 0 is set. For example, index 0 is set as the history values of the Lower page, the Middle page, and the Upper page of the word line WL0 of the block BLK0. Further, index 2, index 3, and index 2 are set as the history values of the Lower page, the Middle page, and the Upper page of the word line WL0 of the block BLK1, respectively. For example, in a case where the index number is counted up in the read operation, the history value of the read level management table 222 is updated.

### 1.6.3 Group Mode Table

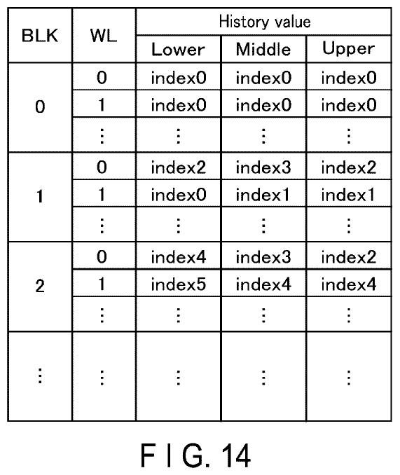

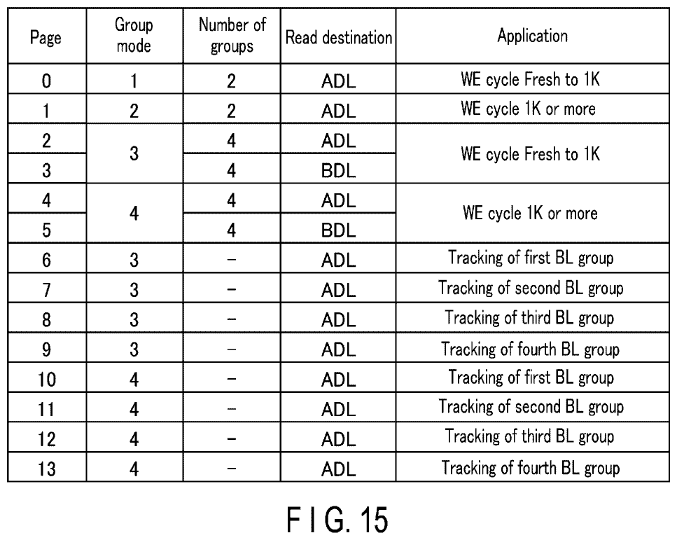

Next, an example of the group mode table 223 will be described with reference to FIG. 15. FIG. 15 is a table illustrating an example of the group mode table 223.

As illustrated in FIG. 15, the group mode table 223 is a table indicating which page address in the user ROM area 120 the group information (hereinafter, it is referred to as “bit-by-bit group information”) of each bit at the time of setting the group mode is registered. The group data is data indicating bit-by-bit group information. The memory cell transistor MC in the user ROM area 120 is an SLC. Therefore, the page number corresponds to any cell unit CU in the user ROM area 120.

The group mode table 223 includes a plurality of entries. Each entry includes the page number of the group data, the group mode, the number of groups of the BL group, and information about the latch circuit of group data read destination.

In the read operation in which the group mode (that is, a plurality of BL groups) is set, the group data read operation (referred to as “group data read”) is executed before the shift read is executed. The group data read by the group data read is stored in any latch circuit of each sense amplifier unit SAU. For example, in the read operation in which the group mode is set, the operation with the data read from the user data area 110 and the group data stored in the latch circuit is executed. Thus, the data of the latch circuit XDL can be updated at different timings for each BL group. That is, the shift read can be executed for each BL group.

Each entry indicates in which page address of the user ROM area 120 the bit-by-bit group information (group data) is registered. For example, the page 0 to 5 corresponds to a page address of group data used at the time of shift read.

In page 0, group information of each bit in the group mode 1 is registered. The number of groups in the mode 1 is two. The BL group to which each bit line BL belongs can be represented by 1-bit data. For example, the “0” data indicates the first BL group. The “1” data indicates the second BL group. Therefore, the group data of mode 1 is one page data. The read destination of page 0 is the latch circuit ADL. For example, the mode 1 is used in a case where the repetition of writing/erasing (referred to as a “WE cycle”) in the target memory cell transistor MC is less than 1000 times (fresh to 1 K).

In page 1, group information of each bit in the group mode 2 is registered. The number of groups in the mode 2 is two. Therefore, as in the mode 1, the group data of the mode 2 is one page data. The read destination of page 1 is the latch circuit ADL. For example, the mode 2 is used in a case where WE cycles are greater than or equal to 1000 (1 K or more).

In pages 2 and 3, group information about each bit in the group mode 3 is registered. The number of groups in the mode 3 is four. The BL group to which each bit line BL belongs can be represented by 2-bit data. For example, lower page data is stored in page 2, and upper page data is stored in page 3. In this case, 2-bit data of “data of page 3, data of page 2” is allocated to the first to fourth BL groups as shown below. For example, the “0, 0” data indicates the first BL group. The “0, 1” data indicates the second BL group. The “1, 0” data indicates the third BL group. The “1, 1” data indicates the fourth BL group. Therefore, the group data of the mode 3 is 2-page data. For example, page 2 corresponds to the Lower bit of 2-bit data of the mode 3. The read destination of page 2 is the latch circuit ADL. For example, page 3 corresponds to the Upper bit of 2-bit data of the mode 3. The read destination of page 3 is the latch circuit BDL. For example, the mode 3 is used in a case where the WE cycles are less than 1000 times.

In pages 4 and 5, group information of each bit in the group mode 4 is registered. The number of groups in mode 4 is four. Therefore, as in the mode 3, the group data of the mode 4 is two page data. For example, page 4 corresponds to the Lower bit of 2-bit data of mode 4. The read destination of page 4 is the latch circuit ADL. For example, page 5 corresponds to the Upper bit of 2-bit data of mode 4. The read destination of page 5 is the latch circuit BDL. For example, mode 4 is used in a case where the WE cycles are greater than or equal to 1000 times.

Pages 6 to 13 corresponds to the page address of the group data used at the time of tracking read. For example, the tracking read is executed for each BL group. Therefore, a page address is allocated to each BL group. For example, “O” data indicates a non-tracking target. The “1” data indicates a tracking target. Since one page corresponds to one BL group, the number of groups is not set. The read destination of each page is the latch circuit ADL.

Pages 6 to 9 corresponds to the first to fourth BL groups in the mode 3, respectively. Pages 10 to 13 corresponds to the first to fourth BL groups in the mode 4, respectively.

### 1.6.4 Flow of Read Operation

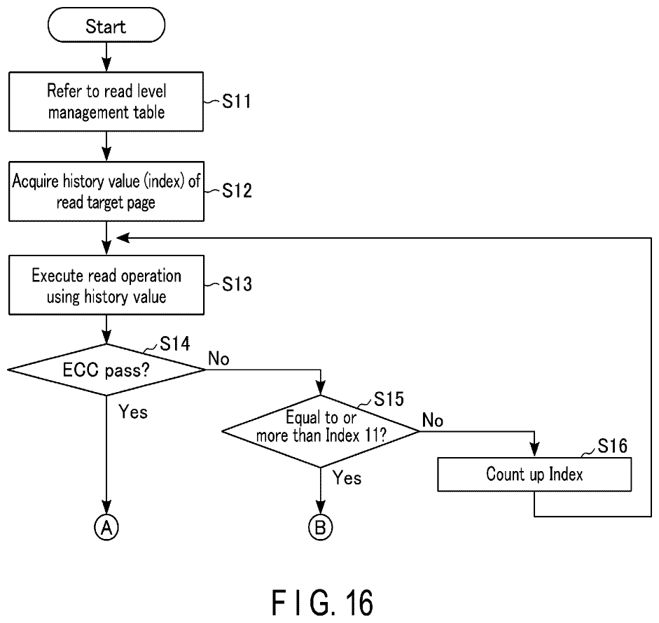

Next, an example of a flow of the read operation will be described with reference to FIGS. 16 to 18. FIGS. 16 to 18 are flowcharts illustrating an example of a flow of the read operation. Hereinafter, the word line WL coupled to the memory cell transistor MC (cell unit CU) to be read is referred to as a “selected word line WL”. Each of the other word lines WL is referred to as a “non-selected word line WL”.

As illustrated in FIG. 16, the CPU 230 first refers to the read level management table 222 (S11).

The CPU 230 acquires the history value (index) of the selected word line WL corresponding to the read target page (S12).

The CPU 230 executes the read operation using the history value, that is, the shift read (S13). The flow of the read operation using the history value will be described later.

The ECC circuit 260 executes the ECC process of read data. In a case where the ECC process fails (S14_No), the CPU 230 checks whether the index of the history value is index 11. For example, the CPU 230 checks whether the index of the history value is the last index 11 for the shift read trial described with reference to FIG. 13 or the index (index 12 or more) registered by the Vth tracking operation.

In a case where the history value is not index 11 or more (S15_No), the CPU 230 counts up the number of the index (S16), and then advances the process to step S13. The CPU 230 executes the read operation using the counted up index as the history value.

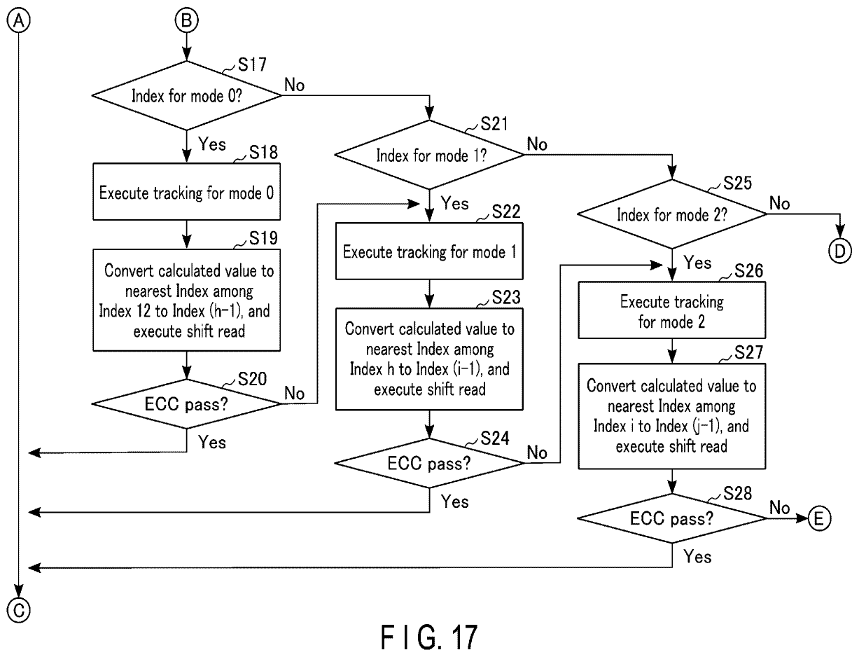

In a case where the history value is index 11 or more (S15_Yes), as illustrated in FIG. 17, the CPU 230 executes the Vth tracking operation in consideration of the BL group. That is, the tracking read is executed for each BL group. More specifically, first, the CPU 230 checks whether the history value is index 11 or an index number (index 11 to index (h−1)) for the group mode 0.

In a case where the history value is the index 11 or the index number for the group mode 0 (S17_Yes), the CPU 230 executes tracking read for the group mode 0 (S18). The CPU 230 calculates the shift value of the read voltage for the group mode 0 based on the result of the tracking read.

The CPU 230 refers to the shift table 221 and converts the shift value of the read voltage calculated by the tracking read for the group mode 0 into an index having the closest shift value among the indexes 12 to index (h−1) for the group mode 0. The CPU 230 executes shift read using the shift value of the converted index (S19).

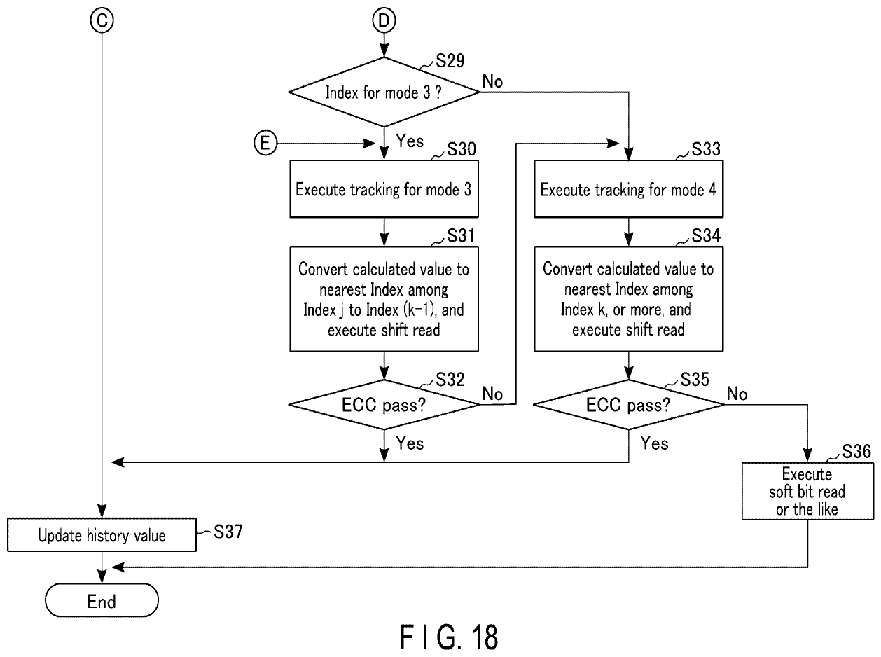

The ECC circuit 260 executes the ECC process of read data. In a case where the ECC process was passed (S20_Yes), the CPU 230 advances the process to step S37 illustrated in FIG. 18 and updates the history value of the read level management table 222.

In a case where the history value is not the index 11 or the index number for the group mode 0 (S17_No), the CPU 230 checks whether the history value is the index number (index (h) to index (i−1)) for the group mode 1.

In a case where the history value is the index number for the group mode 1 (S21_Yes) or in a case where the ECC process fails in step S20 (S20_No), the CPU 230 executes tracking read for the group mode 1 (S22). The CPU 230 calculates the shift value of the read voltage for the group mode 1 based on the result of the tracking read.

The CPU 230 refers to the shift table 221 and converts the shift value of the read voltage calculated by the tracking read for the group mode 1 into an index having the closest shift value among index (h) to index (i−1) for the group mode 1. The CPU 230 executes shift read using the shift value of the converted index (S23).

The ECC circuit 260 executes the ECC process of read data. In a case where the ECC process was passed (S24_Yes), the CPU 230 advances the process to step S37 illustrated in FIG. 18 and updates the history value of the read level management table 222.

In a case where the history value is not the index number for the group mode 1 (S21_No), the CPU 230 checks whether the history value is the index number for the group mode 2 (index (i) to index (j−1)).

In a case where the history value is the index number for the group mode 2 (S25_Yes) or in a case where the ECC process fails in step S24 (S24_No), the CPU 230 executes tracking read for the group mode 2 (S26). The CPU 230 calculates the shift value of the read voltage for the group mode 2 based on the result of the tracking read.

The CPU 230 refers to the shift table 221 and converts the shift value of the read voltage calculated by the tracking read for the group mode 2 into an index having the closest shift value among index (i) to index (j−1) for the group mode 2. The CPU 230 executes shift read using the shift value of the converted index (S27).

The ECC circuit 260 executes the ECC process of read data. In a case where the ECC process was passed (S28_Yes), the CPU 230 advances the process to step S37 illustrated in FIG. 18 and updates the history value of the read level management table 222.

In a case where the history value is not the index number for the group mode 2 (S25_No), the CPU 230 checks whether the history value is the index number for the group mode 3 (index (j) to index (k−1)) as illustrated in FIG. 18.

In a case where the history value is the index number for the group mode 3 (S29 Yes) or in a case where the ECC process fails in step S28 (S29_No), the CPU 230 executes tracking read for the group mode 3 (S30). The CPU 230 calculates the shift value of the read voltage for the group mode 3 based on the result of the tracking read.

The CPU 230 refers to the shift table 221 and converts the shift value of the read voltage calculated by the tracking read for the group mode 3 into an index having the closest shift value among index (j) to index (k−1) for the group mode 3. The CPU 230 executes shift read using the shift value of the converted index (S31).

The ECC circuit 260 executes the ECC process of read data. In a case where the ECC process was passed (S32_Yes), the CPU 230 advances the process to step S37 and updates the history value of the read level management table 222.

In a case where the history value is not the index number for the group mode 3 (S29_No) or in a case where the ECC process fails in step S32 (S32_No), the CPU 230 executes tracking read for the group mode 4 (S33). The CPU 230 calculates the shift value of the read voltage for the group mode 4 based on the result of the tracking read.

The CPU 230 refers to the shift table 221 and converts the shift value of the read voltage calculated by the tracking read for the group mode 4 into an index having the closest shift value among index (k), index (k+1), . . . for the group mode 4. The CPU 230 executes shift read using the shift value of the converted index (S34).

The ECC circuit 260 executes the ECC process of read data. In a case where the ECC process was passed (S35_Yes), the CPU 230 advances the process to step S37 and updates the history value of the read level management table 222.

In a case where the ECC process fails in step S35 (S35_No), the CPU 230 executes another read operation such as soft bit read (S36). The soft bit read is a read operation by soft bit decoding processing using a soft bit.

### 1.6.5 Flow of Read Operation Using History Value

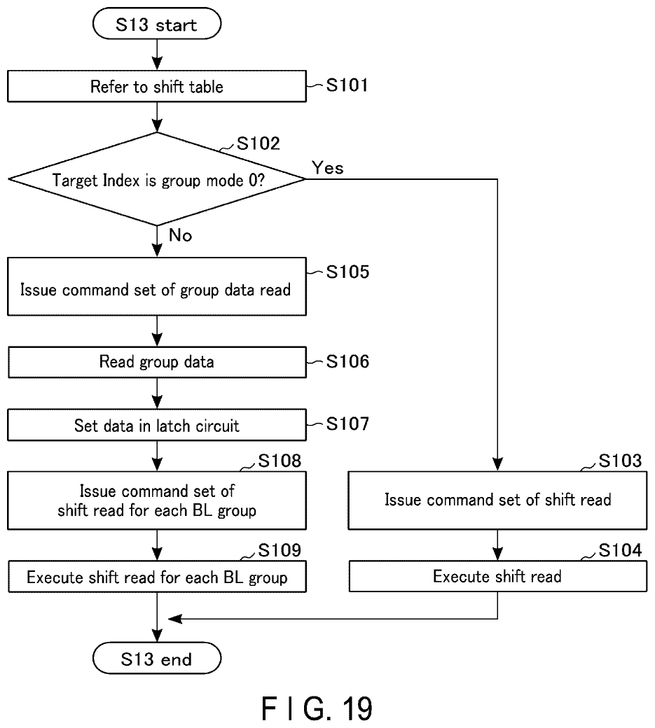

Next, an example of a flow of the read operation using the history value will be described with reference to FIG. 19. FIG. 19 is a flowchart illustrating an example of a flow of the read operation using the history value. Note that FIG. 19 corresponds to step S13 in FIG. 16.

As illustrated in FIG. 19, the CPU 230 refers to the shift table 221 and checks the information about the target index corresponding to the history value of the selected word line WL acquired in step S12 of FIG. 16 (S101).

In a case where the group mode of the target index is 0 (S102_Yes), the CPU 230 issues a command set of shift read (S103). Hereinafter, the shift read in the case of the group mode 0 is referred to as “normal shift read”. The CPU 230 transmits the issued command set to the memory device 100.

Upon receiving the command set of normal shift read, the sequencer 15 executes the normal shift read (S104).

On the other hand, in a case where the group mode of the target index is not 0 (S102_No), the CPU 230 refers to the group mode table 223 and checks the page number (page address) of the corresponding group mode. The CPU 230 issues a command set of group data read in order to read the group data of the target page number (page address) (S105). The command set of group data read includes a command CMD of the group data read and an address ADD designating a target page of the group data. The CPU 230 transmits the command set of group data read to the memory device 100.

Upon receiving the command set of group data read, the sequencer 15 reads the group data of the target page (S106).

The group data is set in the latch circuit of the sense amplifier module 21 designated as the read destination (S107).

The CPU 230 issues a command set corresponding to the shift read for each BL group (S108). The CPU 230 transmits the issued command set to the memory device 100.

Upon receiving the command set corresponding to the shift read for each BL group, the sequencer 15 executes the shift read for each BL group (S109).

In a case where the shift read ends in step S104 or S109, the read operation using the history value ends.

### 1.6.6 Command Sequence of Lower Page Data Read Operation

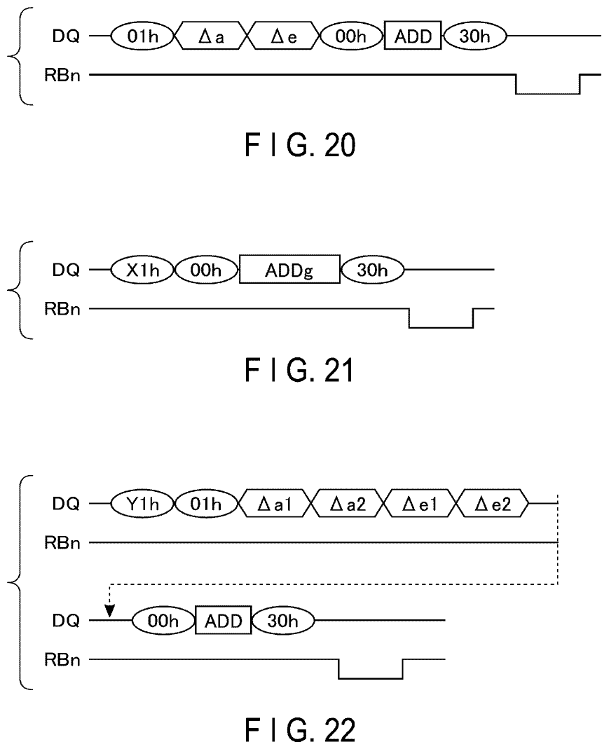

Next, an example of a command sequence of the read operation of the Lower page data will be described with reference to FIGS. 20 to 22. FIG. 20 is a diagram illustrating an example of a command set of normal shift read of Lower page data. FIG. 21 is a diagram illustrating an example of a command set of group data read in a case where the number of groups of the BL group is two. FIG. 22 is a diagram illustrating an example of a command set of shift read for each BL group of Lower page data in a case where the number of groups of BL groups is two. In the command sequence described below, a round frame indicates a command, a square frame indicates an address, and a hexagonal frame indicates data.

First, a command set of normal shift read will be described.

As illustrated in FIG. 20, first, the memory controller 200 transmits a command “01h” to the memory device 100. The command “01h” is a prefix command designating the Lower page. For example, in a case where the Middle page is designated, the command “02h” is transmitted, and in a case where the Upper page is designated, the command “03h” is transmitted.

Next, the memory controller 200 transmits a shift value Aa corresponding to the read operation AR and a shift value Ae corresponding to the read operation ER to the memory device 100. For example, in the case of the read operation of the Middle page data, the memory controller 200 transmits a shift value Δb corresponding to the read operation BR, a shift value Δd corresponding to the read operation DR, and a shift value Δf corresponding to the read operation FR to the memory device 100. In addition, for example, in the case of the read operation of the Upper page data, the memory controller 200 transmits a shift value Ac corresponding to the read operation CR and a shift value Ag corresponding to the read operation GR to the memory device 100.

In the case of index 0, the transmission of the shift values Δa and Δe is omitted.

Next, the memory controller 200 transmits a command “00h” to the memory device 100. The command “00h” is a command making a notification of execution of the read operation. Next, the memory controller 200 transmits, to the memory device 100, an address “ADD” that identifies the target cell unit CU in the user data area 110. The number of cycles of the address ADD are arbitrary. Further, information designating the Lower page may be included in the address ADD. In this case, the command “01h” may be omitted. Next, the memory controller 200 transmits a command “30h” instructing the memory device 100 to execute the read operation.

Upon receiving the command “30h”, the sequencer 15 sets the ready/busy signal RBn to the “L” level. Then, the sequencer 15 executes the read operation of the Lower page data based on the command “01h”. More specifically, for example, the AR read operation and the ER read operation are executed. In a case where the Lower page data is transferred to the latch circuit XDL, the sequencer 15 sets the ready/busy signal RBn to the “H” level.

Next, a command set of group data read will be described. In a case where the group mode is set, the group data read is executed before the shift read for each BL group is executed.

As illustrated in FIG. 21, first, the memory controller 200 transmits a command “X1h” to the memory device 100. The command “X1h” is a prefix command indicating access to the user ROM area 120, reading the SLC data, and that the read destination is the latch circuit ADL. In the case of the command “X1h”, the group data is stored in the latch circuit ADL. Next, the memory controller 200 transmits a command “00h”, an address “ADDg”, and a command “30h” to the memory device 100. The address “ADDg” is an address designating the cell unit CU of the target page of the group data.

Upon receiving the command “30h”, the sequencer 15 sets the ready/busy signal RBn to the “L” level. Then, based on the command “X1h”, the sequencer 15 executes the SLC read operation. In a case where the read data is transferred to the latch circuit ADL, the sequencer 15 sets the ready/busy signal RBn to the “H” level.

Next, a command set corresponding to shift read for each BL group will be described.

As shown in FIG. 22, first, the memory controller 200 transmits a command “Y1h” to the memory device 100. The command “Y1h” is a prefix command indicating shift read for each BL group in a case where the number of groups is two. Next, the memory controller 200 transmits a command “01h” to the memory device 100.

For example, in the case of the command “Y1h”, the shift value of the first BL group and the shift value of the second BL group are sequentially transmitted with respect to the read operation of each state, and the shift value of the first BL group is smaller than the shift value of the second BL group. More specifically, the memory controller 200 sequentially transmits the shift values Δa1, Δa2, Δe1, and Δe1 to the memory device 100. The shift value Δa1 corresponds to the first BL group of the read operation AR. The shift value Δa2 corresponds to the second BL group of the read operation AR. The shift value Δe1 corresponds to the first BL group of the read operation ER. The shift value Δe2 corresponds to the second BL group of the read operation ER. The shift values Δa1 and Δa2 have a relationship of Δa1<Δa2. The shift values Δe1 and Δe2 have a relationship of Δe1<Δe2.

Next, the memory controller 200 transmits a command “00h”, an address “ADD”, and a command “30h” to the memory device 100.

Upon receiving the command “30h”, the sequencer 15 sets the ready/busy signal RBn to the “L” level. Then, the sequencer 15 executes the shift read for each BL group in a case where the number of groups is two based on the command “Y1h”. In a case where the shift read operation is ended, the sequencer 15 sets the ready/busy signal RBn to the “H” level.

### 1.6.7 Voltage of Selected Word Line at Time of Lower Page Data Read Operation

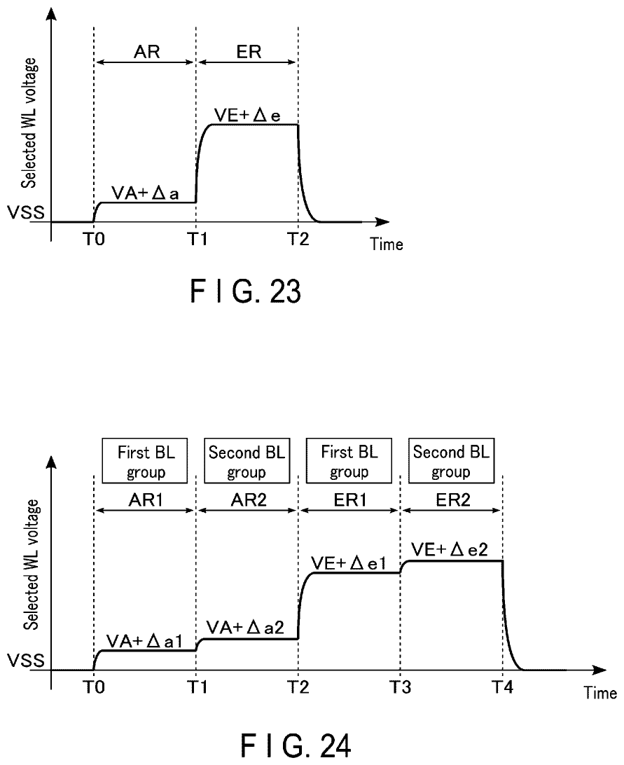

Next, an example of the voltage of the selected word line WL at the time of the Lower page data read operation will be described with reference to FIGS. 23 and 24. FIG. 23 is a timing chart illustrating an example of the voltage of the selected word line WL in the normal shift read of the Lower page data. FIG. 24 is a timing chart illustrating an example of the voltage of the selected word line WL in the shift read of the Lower page data in a case where the number of groups of the BL groups is two.

First, the normal shift read of the Lower page data will be described.

As illustrated in FIG. 23, during the period from the time T0 to the time T1, the read voltage (VA+Δa) corresponding to the read operation AR of the A state is applied to the selected word line WL.

During the period from the time T1 to the time T2, the read voltage (VE+Δe) corresponding to the read operation ER of the E state is applied to the selected word line WL.

As described above, in a case where the read operation of the plurality of states is continuously executed, the read voltage corresponding to each state is continuously applied to the selected word line. For example, after the read voltage (VA+Δa) is applied to the selected word line WL, the voltage VSS is once applied, and thereafter, the read voltage (VE+Δe) is not applied. Furthermore, in the read operation of the plurality of states, the lower read voltage is applied in order, but the higher read voltage may be applied in order. For example, the read voltage (VA+Δa) may be applied after the read voltage (VE+Δe) is applied to the selected word line WL.

Next, shift read of the Lower page data in a case where the number of groups is two will be described.

As shown in FIG. 24, for example, in each state, the read voltages are applied to the selected word line WL in ascending order.

During the period from the time T0 to the time T1, first, the read voltage (VA+Δa1) corresponding to the read operation AR1 of the A state of the first BL group is applied to the selected word line WL.

During the period from the time T1 to the time T2, the read voltage (VA+Δa2) corresponding to the read operation AR2 of the A state of the second BL group is applied to the selected word line WL.

During the period from the time T2 to the time T3, the read voltage (VE+Δe1) corresponding to the read operation ER1 of the E state of the first BL group is applied to the selected word line WL.

During the period from the time T3 to the time T4, the read voltage (VE+Δe2) corresponding to the read operation ER2 of the E state of the second BL group is applied to the selected word line WL.

### 1.6.8 Specific Example of Lower Page Data Read Operation In a Case where the Number of Groups is Two

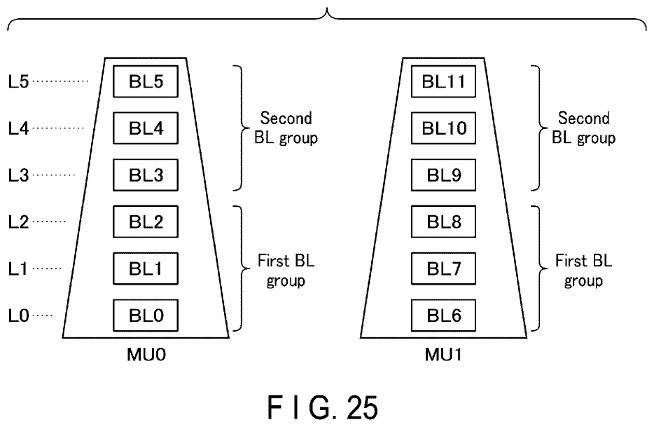

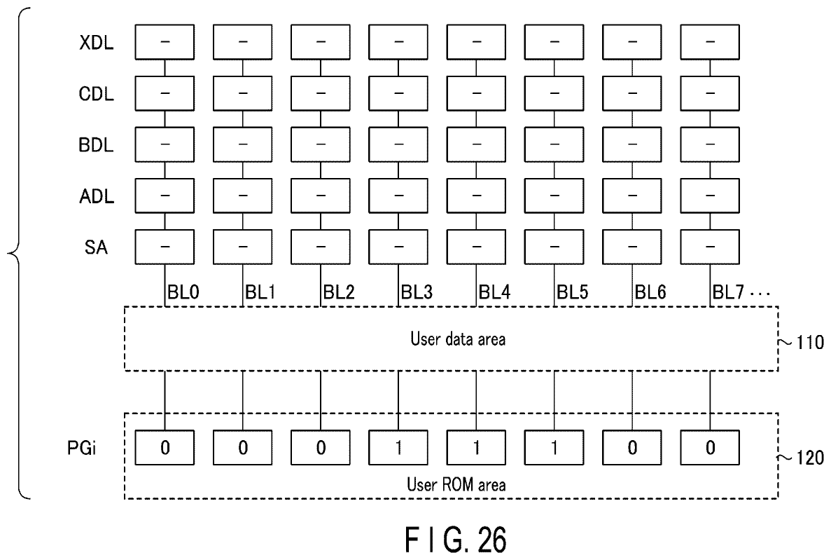

Next, a specific example of the read operation of the Lower page data in a case where the number of groups is two will be described with reference to FIGS. 25 to 32. FIG. 25 is a diagram schematically illustrating an example of grouping of the bit lines BL. FIGS. 26 to 32 are diagrams illustrating an example of the states of the latch circuits at the time of the Lower page data read operation. In the examples illustrated in FIGS. 26 to 32, the operation unit OP is omitted. In FIGS. 26 to 32, a square frame in the user ROM area 120 corresponds to one memory cell transistor MC (SCL).

In the following arithmetic expressions, “~” represents inverted data, “|” represents an OR operation, and “&” represents an AND operation. Further, 1-bit data stored in the sense circuit SA, the latch circuit ADL, the latch circuit BDL, the latch circuit CDL, and the latch circuit XDL is simply referred to as “SA”, “ADL”, “BDL”, “CDL”, and “XDL”, respectively.

First, the BL group in the specific example will be described.

As shown in FIG. 25, in the specific example, the bit lines BL0 to BL2 and BL6 to BL8 corresponding to the layers L0 to L2 belong to the first BL group, and the bit lines BL3 to BL5 and BL9 to BL11 corresponding to the layers L3 to L5 belong to the second BL group.

Next, the state of the latch circuit at the time of the read operation will be described.

As illustrated in FIG. 26, the group data is stored in a page PGi (i is any integer) of the user ROM area 120. For example, the data “0” indicates a first BL group, and the data “1” indicates a second BL group. The bit lines BL0, BL1, BL2, BL6, and BL7 belong to the first BL group, and the bit lines BL3, BL4, and BL5 belong to the second BL group.

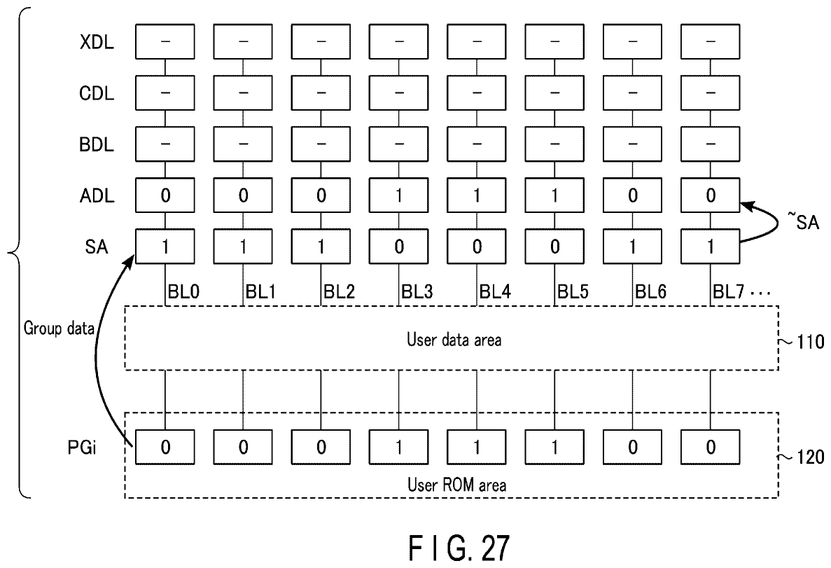

As illustrated in FIG. 27, the group data read of the page PGi is executed based on the command set of group data read described with reference to FIG. 21. First, the sense circuit SA reads the group data stored in the page PGi. At this time, the group data is inverted in the sense circuit SA. The operation unit OP transfers inverted data (~SA) of data stored in the sense circuit SA to the latch circuit ADL.

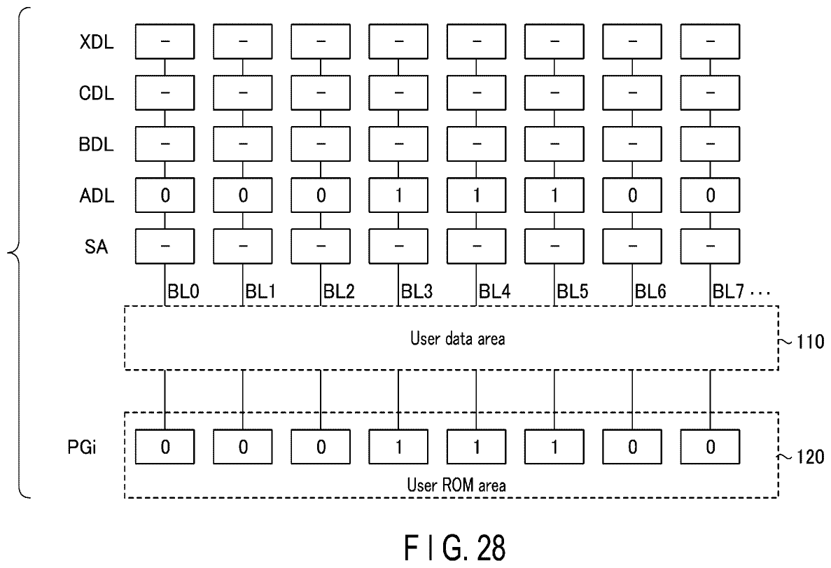

As illustrated in FIG. 28, the latch circuit ADL stores the same data as the page PGi. More specifically, “0” data is stored in the latch circuits ADL corresponding to the bit lines BL0, BL1, BL2, BL6, and BL7. “1” data is stored in the latch circuits ADL corresponding to the bit lines BL3, BL4, and BL5. In other words, “0” data is stored in the latch circuit ADL corresponding to the first BL group, and “1” data is stored in the latch circuit ADL corresponding to the second BL group.

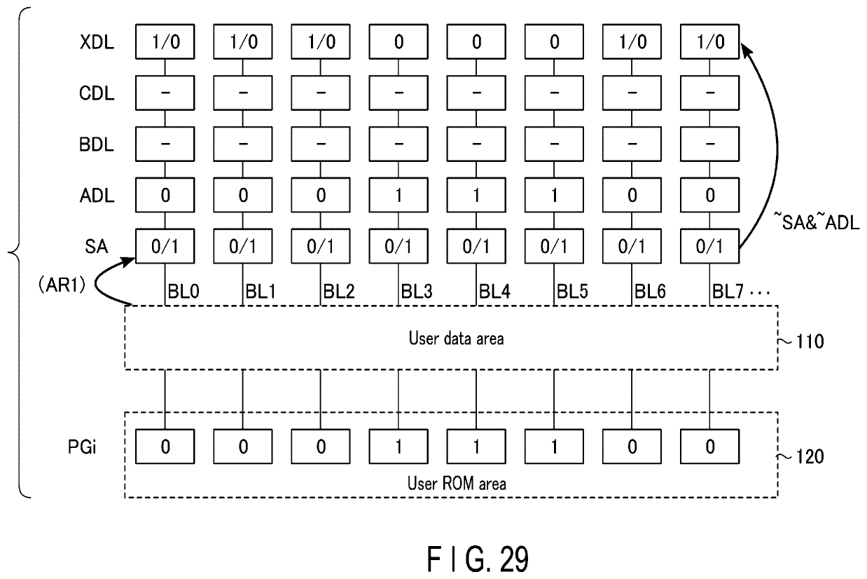

As illustrated in FIG. 29, the shift read of the Lower page is executed based on the command set of shift read for each BL group described with reference to FIG. 22. First, the read operation AR1 of the A state of the first BL group is executed. In other words, the read operation AR1 using the read voltage (VA+Δa1) is executed. The sense circuit SA stores the data (0/1) read by the read operation AR1. The operation unit OP executes the operation of Expression (1) using the read data of the sense circuit SA and the group data of the latch circuit ADL, and transfers the result to the latch circuit XDL.

XDL=~SA&~ADL (1)

As a result, the inverted data (1/0) of the sense circuit SA is stored in the latch circuits XDL corresponding to the bit lines BL0, BL1, BL2, BL6, and BL7. “0” data is stored in the latch circuits XDL corresponding to the bit lines BL3, BL4, and BL5. In other words, inverted data (1/0) of the sense circuit SA is stored in the latch circuit XDL corresponding to the first BL group (ADL=0), and “O” data is stored in the latch circuit XDL corresponding to the second BL group (ADL=1).

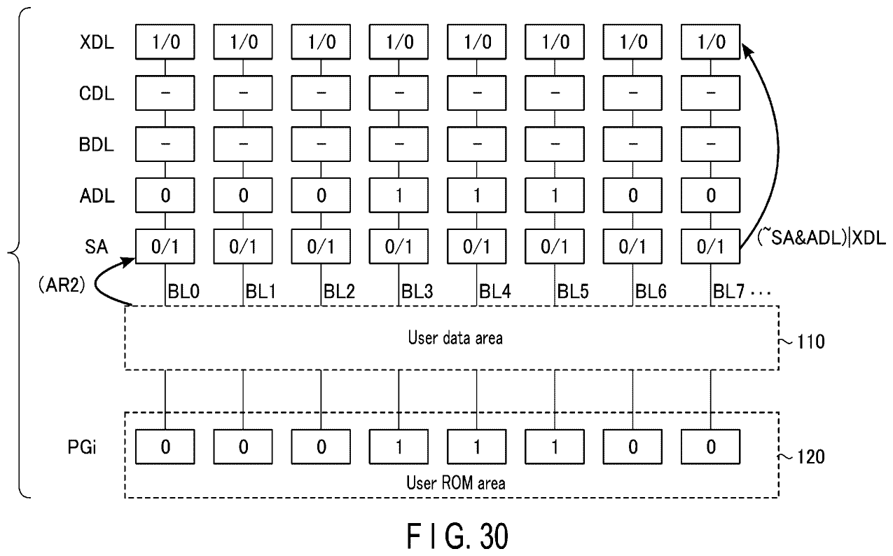

As illustrated in FIG. 30, next, the read operation AR2 of the A state of the second BL group is executed. In other words, the read operation AR2 using the read voltage (VA+Δa2) is executed. The sense circuit SA stores the data (0/1) read by the read operation AR2. The operation unit OP executes the operation of Expression (2) using the read data of the sense circuit SA, the group data of the latch circuit ADL, and the data of the latch circuit XDL, and transfers the result to the latch circuit XDL.

XDL=(~SA&ADL)|XDL (2)

As a result, the inverted data (1/0) of the sense circuit SA is stored in the latch circuits XDL corresponding to the bit lines BL3, BL4, and BL5. In other words, the inverted data (1/0) of the sense circuit SA is stored in the latch circuit XDL corresponding to the second BL group (ADL=1). As a result, the result of the read operation AR of the A state is stored in each latch circuit XDL.

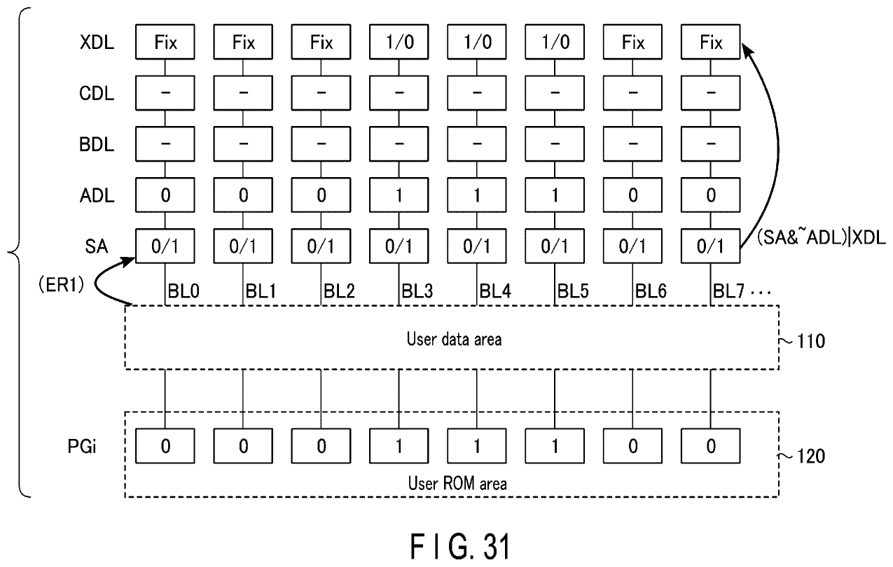

As illustrated in FIG. 31, next, the read operation ER1 of the E state of the first BL group is executed. In other words, the read operation ER1 using the read voltage (VE+Δe1) is executed. The sense circuit SA stores the data (0/1) read by the read operation ER1. The operation unit OP executes the operation of Expression (3) using the read data of the sense circuit SA, the group data of the latch circuit ADL, and the data of the latch circuit XDL, and transfers the result to the latch circuit XDL.

XDL=(SA&~ADL)|XDL (3)

As a result, the read result (Fix) of the Lower page data is stored in the latch circuits XDL corresponding to the bit lines BL0, BL1, BL2, BL6, and BL7. In other words, the read result (Fix) of the Lower page data is stored in the latch circuit XDL corresponding to the first BL group (ADL=0). As a result, the Lower page data of the first BL group is determined.

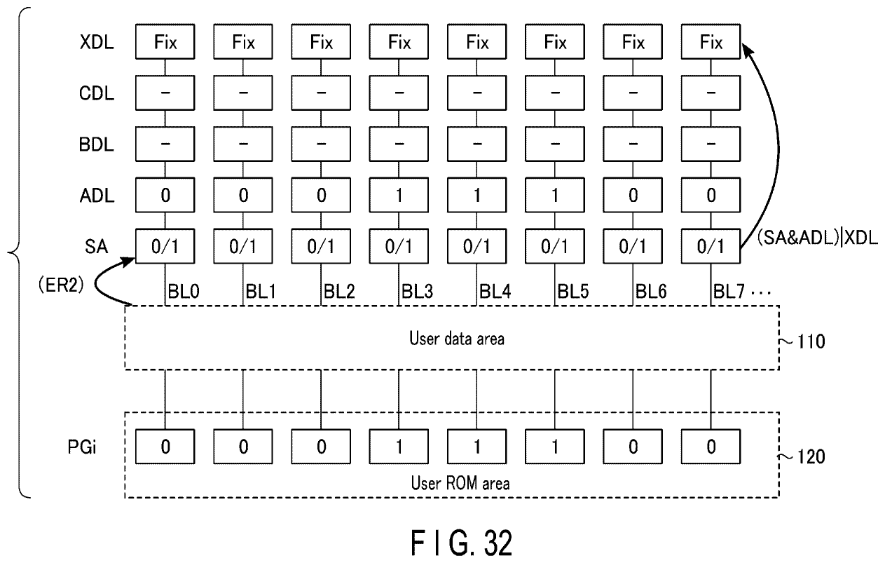

As illustrated in FIG. 32, next, the read operation ER2 of the E state of the second BL group is executed. In other words, the read operation ER2 using the read voltage (VE+Δe2) is executed. The sense circuit SA stores the data (0/1) read by the read operation ER2. The operation unit OP executes the operation of Expression (4) using the read data of the sense circuit SA, the group data of the latch circuit ADL, and the data of the latch circuit XDL, and transfers the result to the latch circuit XDL.

XDL=(SA&ADL)|XDL (4)

As a result, the read result (Fix) of the Lower page data is stored in the latch circuits XDL corresponding to the bit lines BL3, BL4, and BL5. In other words, the read result (Fix) of the Lower page data is stored in the latch circuit XDL corresponding to the second BL group (ADL=1). As a result, the Lower page data of the second BL group is determined. Therefore, the read result of the Lower page data is stored in each latch circuit XDL.

### 1.7 Effects According to Present Embodiment

With the configuration according to the present embodiment, it is possible to provide a memory system capable of improving reliability. Hereinafter, the present effect will be described in detail.

For example, in a case where the sizes (gate length, gate width, etc.) of the plurality of memory cell transistors MC included in one cell unit CU are different for each layer L, the threshold voltage distribution may be different depending on the size. In a case where the read operation is executed on the memory cell transistors MC having different threshold voltage distributions for each layer L under the same condition, there is a high possibility that erroneous reading occurs. In a case where the number of fail bits increases, error correction cannot be performed by the ECC process, and data reliability decreases.

On the other hand, with the configuration according to the present embodiment, the bit lines BL can be grouped for each layer L, and shift values of different read voltages can be set for each BL group. That is, different read voltages can be set for each layer L. Since the read voltage can be optimized for each layer L, an increase in the number of fail bits can be suppressed. That is, erroneous reading can be suppressed. Therefore, the reliability of the memory system can be improved.

Furthermore, with the configuration according to the present embodiment, the grouping of the BL group can be changed by changing the group mode (group data). Therefore, for example, even in a case where the characteristics of the memory cell transistor MC fluctuate due to an increase in the number of WE cycles or the like, an optimum shift value of the read voltage can be set for each layer L.

### 1.8 Modifications of First Embodiment

Next, five modifications of the first embodiment will be described. Hereinafter, differences from the first embodiment will be mainly described.

### 1.8.1 First Modification

First, the first modification of the first embodiment will be described. In the first embodiment, the case where the shift value of the first BL group is smaller than the shift value of the second BL group is described. In the present modification, a case where the magnitude relationship between the shift value of the first BL group and the shift value of the second BL group is not limited will be described.

### 1.8.1.1 Voltage of Selected Word Line at Time of Lower Page Data Read Operation

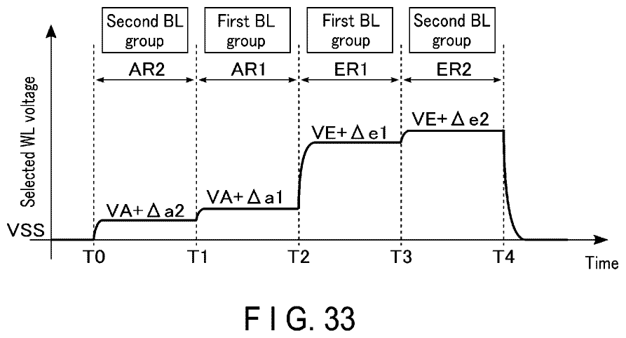

First, an example of the voltage of the selected word line WL at the time of the Lower page data read operation will be described with reference to FIG. 33. FIG. 33 is a timing chart illustrating an example of the voltage of the selected word line WL in the shift read of the Lower page data in a case where the number of groups of the BL groups is two.

For example, as in the description using FIG. 22 of the first embodiment, the memory controller 200 sequentially transmits a shift value Δa1 corresponding to the first BL group of the read operation AR, a shift value Δa2 corresponding to the second BL group of the read operation AR, a shift value Δe1 corresponding to the first BL group of the read operation ER, and a shift value Δe2 corresponding to the second BL group of the read operation ER to the memory device 100. However, in the present modification, the magnitude relationship between the shift values Δa1 and Δa2 and the magnitude relationship between the shift values Δe1 and Δe2 are not limited.

As illustrated in FIG. 33, for example, the shift values Δa1 and Δa2 have a relationship of Δa1>Δa2, and the shift values Δe1 and Δe2 have a relationship of Δe1<Δe2. Even in such a case, in each state, the read voltage is applied to the selected word line WL in ascending order.

During the period from the time T0 to the time T1, the read voltage (VA+Δa2) corresponding to the read operation AR2 of the A state of the second BL group is applied to the selected word line WL.

During the period from the time T1 to the time T2, the read voltage (VA+Δa1) corresponding to the read operation AR1 of the A state of the first BL group is applied to the selected word line WL.

During the period from the time T2 to the time T3, the read voltage (VE+Δe1) corresponding to the read operation ER1 of the E state of the first BL group is applied to the selected word line WL.

During the period from the time T3 to the time T4, the read voltage (VE+Δe2) corresponding to the read operation ER2 of the E state of the second BL group is applied to the selected word line WL.

### 1.8.1.2 Flow of Shift Read for Each BL Group

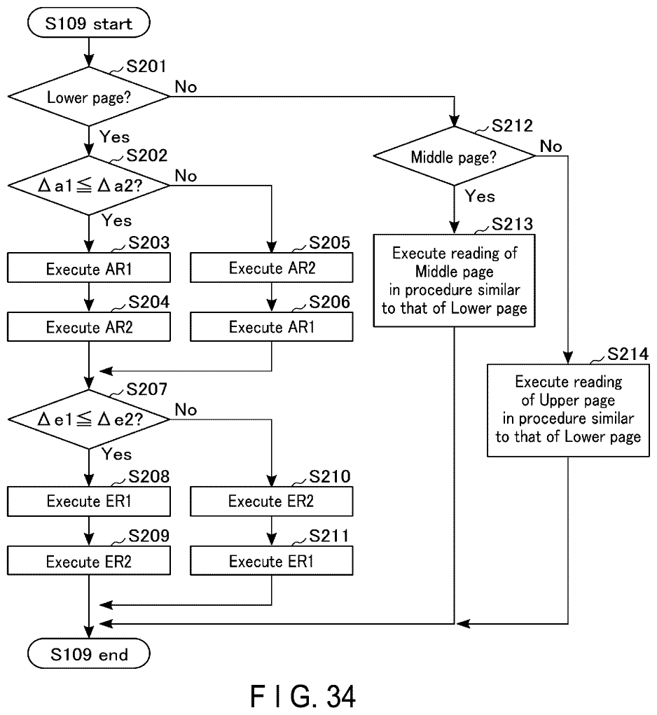

Next, an example of a flow of the shift read for each BL group will be described with reference to FIG. 34. FIG. 34 is a flowchart illustrating an example of a flow of the shift read for each BL group. FIG. 34 corresponds to step S109 of FIG. 19. In the example illustrated in FIG. 34, in order to simplify the description, details of the read operation of the Middle page data and the Upper page data are omitted.

As illustrated in FIG. 34, the sequencer 15 first checks whether the target of the read operation is the Lower page data.

In a case where the target of the read operation is the Lower page data (S201_Yes), the sequencer 15 compares the shift value Δa1 of the first BL group of the A state with the shift value Δa2 of the second BL group.

In a case where the shift value Δa1 of the first BL group is equal to or less than the shift value Δa2 of the second BL group (S202_Yes), that is, in a case where Δa1≤Δa2, the sequencer 15 first executes the read operation AR1 of the A state of the first BL group (S203). The operation unit OP executes the operation of Expression (1) and stores inverted data (1/0) of the sense circuit SA in the latch circuit XDL corresponding to the first BL group (ADL=0).

Next, the sequencer 15 executes the read operation AR2 of the A state of the second BL group. The operation unit OP executes the operation of Expression (2) and stores the inverted data (1/0) of the sense circuit SA in the latch circuit XDL corresponding to the second BL group (ADL=1).

On the other hand, in a case where the shift value Δa1 of the first BL group is larger than the shift value Δa2 of the second BL group (S202 No), that is, in a case where Δa1>Δa2, the sequencer 15 first executes the read operation AR2 of the A state of the second BL group as in step S204 (S205). The operation unit OP executes the operation of Expression (5) and stores the inverted data (1/0) of the sense circuit SA in the latch circuit XDL corresponding to the second BL group (ADL=1).

XDL=~SA&ADL (5)

Next, the sequencer 15 executes the read operation AR1 of the A state of the first BL group (S206). The operation unit OP executes the operation of Expression (6) and stores inverted data (1/0) of the sense circuit SA in the latch circuit XDL corresponding to the first BL group (ADL=0).

XDL=(~SA&~ADL)|XDL (6)

Next, in a case where the read operations AR1 and AR2 of the A state are ended, the sequencer 15 compares the shift value Δe1 of the E state of the first BL group with the shift value Δe2 of the second BL group.

In a case where the shift value Δe1 of the first BL group is equal to or less than the shift value Δe2 of the second BL group (S207_Yes), that is, in a case where Δe1≤Δe2, the sequencer 15 first executes the read operation ER1 of the E state of the first BL group (S208). The operation unit OP executes the operation of Expression (3) and stores the read result of the Lower page data in the latch circuit XDL corresponding to the first BL group (ADL=0). As a result, the Lower page data of the first BL group is determined.

Next, the sequencer 15 executes the read operation ER2 of the E state of the second BL group (S209). The operation unit OP executes the operation of Expression (4) and stores the read result of the Lower page data in the latch circuit XDL corresponding to the second BL group (ADL=1). As a result, the Lower page data of the first and second BL groups is determined.

On the other hand, in a case where the shift value Δe1 of the first BL group is larger than the shift value Δe2 of the second BL group (S207 No), that is, in a case where Δe1>Δe2, the sequencer 15 first executes the read operation ER2 of the E state of the second BL group as in step S209 (S210). The operation unit OP executes the operation of Expression (4) and stores the read result of the Lower page data in the latch circuit XDL corresponding to the second BL group (ADL=1). As a result, the Lower page data of the second BL group is determined.

Next, the sequencer 15 executes the read operation ER1 of the E state of the first BL group (S211). The operation unit OP executes the operation of Expression (3) and stores the read result of the Lower page data in the latch circuit XDL corresponding to the first BL group (ADL=0). As a result, the Lower page data of the first and second BL groups is determined.

In addition, in step S201, in a case where the target of the read operation is not the Lower page data (S201_No), the sequencer 15 checks whether the target of the read operation is the Middle page data.

In a case where the target of the read operation is the Middle page data (S212_Yes), the sequencer 15 executes the read operation of the Middle page data in the similar procedure as the read operation of the Lower page data (S213). For example, the sequencer 15 executes the read operation of the B, D, and F states as in the A and E states.

On the other hand, in a case where the target of the read operation is not the Middle page data (S212_No), the sequencer 15 executes the read operation of the Upper page data in the similar procedure as the read operation of the Lower page data (S214). For example, the sequencer 15 executes the read operation of the C and G states as in the A and E states.

### 1.8.1.3 Effects According to Present Modification

With the configuration according to the present modification, effects similar to those of the first embodiment can be obtained.

Furthermore, in the configuration according to the present modification, the magnitude relationship of the shift values of the BL group is not limited. Therefore, the optimum shift value can be set for each BL group without being restricted by the magnitude relationship with the shift values of other BL groups.

### 1.8.2 Second Modification

Next, the second modification of the first embodiment will be described. In the present modification, a case where the shift value of the first BL group is larger than the shift value of the second BL group will be described.

### 1.8.2.1 Command Sequence of Lower Page Data Read Operation

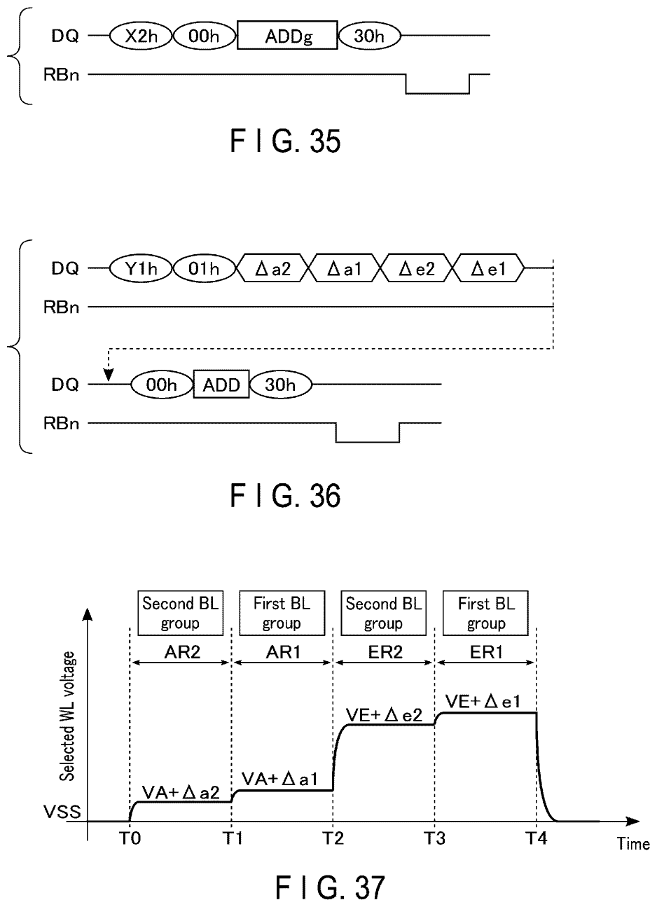

Next, an example of a command sequence of the read operation of the Lower page data will be described with reference to FIGS. 35 and 36. FIG. 35 is a diagram illustrating an example of a command set of group data read in a case where the number of groups of the BL group is two. FIG. 36 is a diagram illustrating an example of a command set of shift read of the Lower page data in a case where the number of groups of the BL group is two.

First, a command set of group data read will be described.

As illustrated in FIG. 35, in the present modification, first, the memory controller 200 transmits a command “X2h” to the memory device 100. The command “X2h” is a prefix command indicating reading the SLC data and that the read destination is the latch circuit ADL. In the case of the command “X2h”, inverted data of the group data is stored in the latch circuit ADL.

Next, the memory controller 200 transmits a command “00h”, an address” ADDg”, and a command “30h” to the memory device 100, as in the description of the first embodiment using FIG. 21.

Next, a command set corresponding to shift read for each BL group will be described.

As illustrated in FIG. 36, first, the memory controller 200 transmits commands “Y1h” and “01h” to the memory device 100, as in the description of the first embodiment using FIG. 22.

In the present modification, the shift values Δa1 and Δa2 have a relationship of Δa1>Δa2. The shift values Δe1 and Δe2 have a relationship of Δe1>Δe2. The memory controller 200 sequentially transmits the shift value Δa2 corresponding to the second BL group of the read operation AR, the shift value Δa1 corresponding to the first BL group of the read operation AR, the shift value Δe2 corresponding to the second BL group of the read operation ER, and the shift value Δe1 corresponding to the first BL group of the read operation ER to the memory device 100.

Next, the memory controller 200 transmits a command “00h”, an address “ADD”, and a command “30h” to the memory device 100, as in the description of the first embodiment using FIG. 22.

### 1.8.2.2 Voltage of Selected Word Line at Time of Lower Page Data Read Operation

Next, an example of the voltage of the selected word line WL at the time of the Lower page data read operation will be described with reference to FIG. 37. FIG. 37 is a timing chart illustrating an example of the voltage of the selected word line WL in the shift read of the Lower page data in a case where the number of groups of the BL groups is two.

As illustrated in FIG. 37, in each state, the read voltage is applied to the selected word line WL in ascending order.

During the period from the time T0 to the time T1, the read voltage (VA+Δa2) corresponding to the read operation AR2 of the A state of the second BL group is applied to the selected word line WL.

During the period from the time T1 to the time T2, the read voltage (VA+Δa1) corresponding to the read operation AR1 of the A state of the first BL group is applied to the selected word line WL.

During the period from the time T2 to the time T3, the read voltage (VE+Δe2) corresponding to the read operation ER2 of the E state of the second BL group is applied to the selected word line WL.

During the period from the time T3 to the time T4, the read voltage (VE+Δe1) corresponding to the read operation ER1 of the E state of the first BL group is applied to the selected word line WL.

### 1.8.2.3 Specific Example of Group Data Read

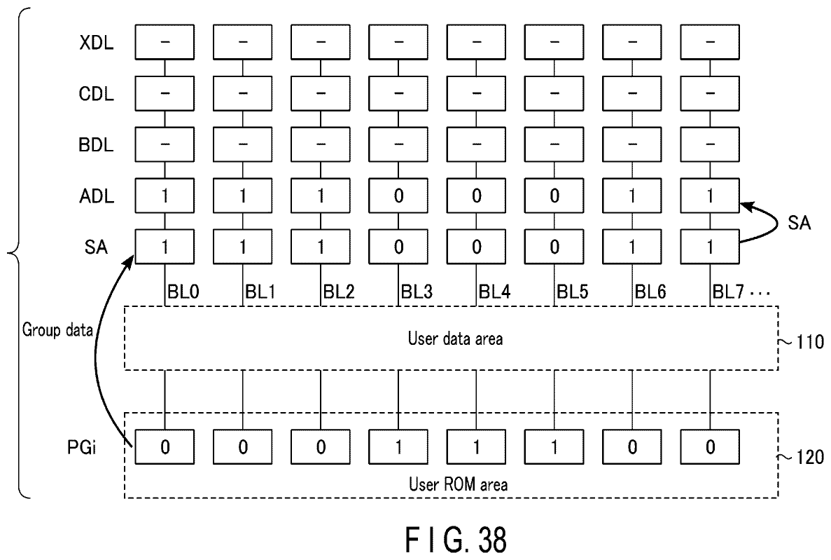

Next, a specific example of the group data read will be described with reference to FIG. 38. FIG. 38 is a diagram illustrating an example of the states of the latch circuits in the group data read. In the example illustrated in FIG. 38, the operation unit OP is omitted.

As illustrated in FIG. 38, the group data is stored in a page PGi of the user ROM area 120. For example, the data “0” indicates a first BL group, and the data “1” indicates a second BL group. The bit lines BL0, BL1, BL2, BL6, and BL7 belong to the first BL group, and the bit lines BL3, BL4, and BL5 belong to the second BL group.

The group data read of the page PGi is executed based on the command set of group data read described with reference to FIG. 35. First, the inverted data of the group data stored in the page PGi is read to the sense circuit SA. The operation unit OP transfers the data stored in the sense circuit SA to the latch circuit ADL. As a result, inverted data of the group data is stored in the latch circuit ADL. More specifically, “1” data is stored in the latch circuits ADL corresponding to the bit lines BL0, BL1, BL2, BL6, and BL7. “0” data is stored in the latch circuits ADL corresponding to the bit lines BL3, BL4, and BL5. In other words, “1” data is stored in the latch circuit ADL corresponding to the first BL group, and “0” data is stored in the latch circuit ADL corresponding to the second BL group.

In the shift read of the Lower page, first, the read operation AR2 of the A state of the second BL group is executed. At this time, the operation unit OP executes the operation of Expression (1) and transfers the result to the latch circuit XDL.

Next, the read operation AR1 of the A state of the first BL group is executed. At this time, the operation unit OP executes the operation of Expression (2) and transfers the result to the latch circuit XDL.

Next, the read operation ER2 of the E state of the second BL group is executed. At this time, the operation unit OP executes the operation of Expression (3) and transfers the result to the latch circuit XDL.

Next, the read operation ER1 of the E state of the first BL group is executed. At this time, the operation unit OP executes the operation of Expression (4) and transfers the result to the latch circuit XDL.

### 1.8.2.4 Effects According to Present Modification

With the configuration according to the present modification, effects similar to those of the first embodiment can be obtained.

### 1.8.3 Third Modification

Next, the third modification of the first embodiment will be described. For example, there is a case where a plurality of read operations is continuously executed. At this time, in a case where the group mode of the read operation to be executed next is the same as the group mode of the read operation executed last time, the group data read may be omitted in the read operation to be executed next time. In the present modification, such a case will be described.

### 1.8.3.1 Flow of Read Operation Using History Value

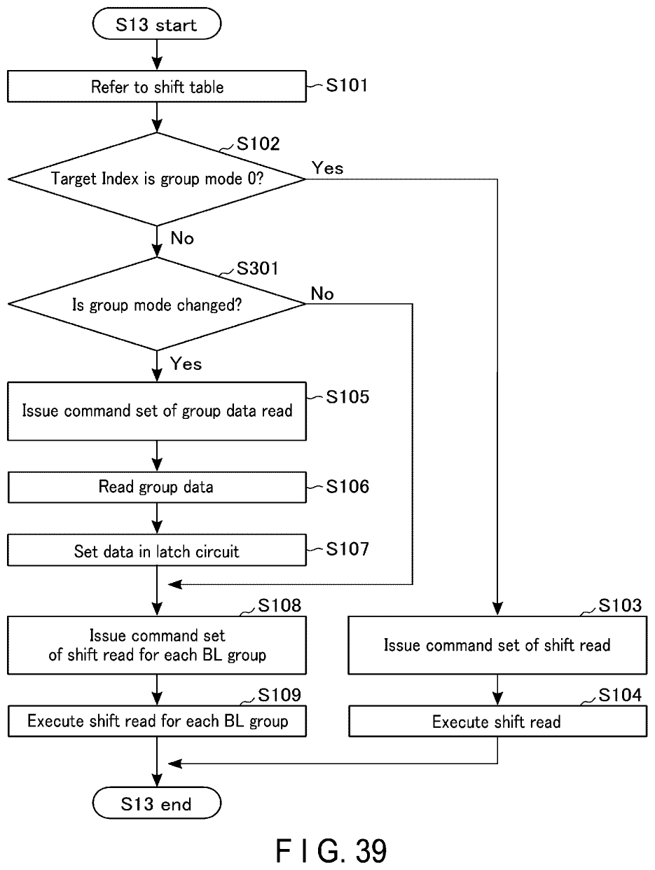

First, an example of a flow of a read operation using a history value will be described with reference to FIG. 39. FIG. 39 is a flowchart illustrating an example of a flow of the read operation using the history value. Note that FIG. 39 corresponds to step S13 in FIG. 16.

As illustrated in FIG. 39, the CPU 230 refers to the shift table 221 and checks the information about the target index corresponding to the history value of the selected word line WL acquired in step S12 of FIG. 16 (S101).

In a case where the group mode of the target index is 0 (S102_Yes), the CPU 230 executes steps S103 and S104 as in the description of the first embodiment with reference to FIG. 19.

On the other hand, in a case where the group mode of the target index is not 0 (S102_No), the CPU 230 checks whether the set group mode has been changed from the group mode of the read operation executed last time. That is, the CPU 230 checks whether the group data of the target index has been changed from the group data stored in the latch circuits.

In a case where the group mode is changed (S301_Yes), the CPU 230 sequentially executes steps S105 to S109 as in the description of the first embodiment with reference to FIG. 19. That is, the CPU 230 executes the group data read and the shift read for each BL group. In a case where the write operation is executed last time, the write data is stored in the latch circuits, and no group data remains. In this case, the CPU 230 advances the process to step S105 in order to read the group data.

On the other hand, in a case where there is no change in the group mode (S301_No), the CPU 230 omits steps S105 to S107 and sequentially executes steps S108 and S109. That is, the CPU 230 omits the group data read and executes the shift read for each BL group.

### 1.8.3.2 Effects According to Present Modification

With the configuration according to the present modification, effects similar to those of the first embodiment can be obtained.

Furthermore, with the configuration according to the present modification, in a case where the group mode is not changed in a case where the read operation is repeatedly executed, the group data read can be omitted. As a result, it is possible to suppress an increase in the processing time of the read operation by the group data read.

### 1.8.4 Fourth Modification

Next, the fourth modification of the first embodiment will be described. In the present modification, a case where the sense time of the node SEN in the sense circuit SA is changed instead of changing the read voltage for each BL group will be described.

### 1.8.4.1 Relationship Between Voltage of Node SEN and Sense Time in Read Operation

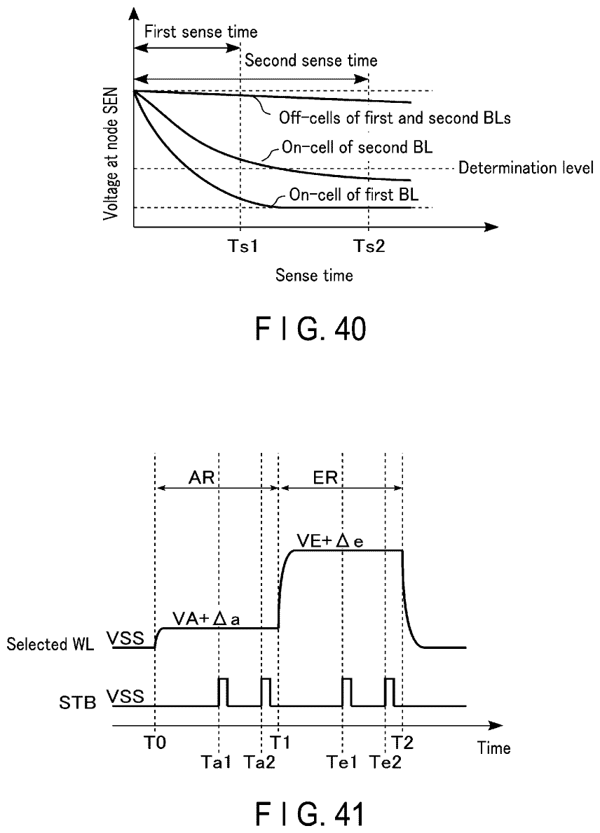

First, the relationship between the voltage of the node SEN and the sense time in the read operation will be described with reference to FIG. 40. FIG. 40 is a graph illustrating a relationship between the voltage of the node SEN and the sense time in the read operation. The example shown in FIG. 40 shows a case where the threshold voltage of the memory cell transistor MC of the first BL group is lower than the threshold voltage of the memory cell transistor MC of the second BL group.

As illustrated in FIG. 40, for example, in the read operation, in the node SEN corresponding to the ON-cell, the precharged charge is discharged via the bit line BL during the period (hereinafter, referred to as a “sense time”) in which the transistor T3 is turned on. The rate at which the voltage of the node SEN decreases differs depending on the threshold voltage of the memory cell transistor MC. For example, the ON-cell of the first BL group having a low threshold voltage is set to the ON state stronger than the ON-cell of the second BL group having a high threshold voltage. Therefore, the voltage of the node SEN corresponding to the ON-cell of the first BL group decreases more rapidly than the voltage of the node SEN corresponding to the ON-cell of the second BL group. In the case of the Off-cell, the voltage of the node SEN hardly decreases regardless of the first and second BL groups.

Based on this relationship, a time during which it can be determined whether the memory cell transistor MC of the first BL group is the ON-cell or the Off-cell is set as a first sense time Ts1. A time during which it can be determined whether the memory cell transistor MC of the second BL group is the ON-cell or the Off-cell is set as a second sense time Ts2. The first sense time Ts1 and the second sense time Ts2 have a relationship of Ts1<Ts2. By executing the strobe operation corresponding to the sense time Ts1 and the strobe operation corresponding to the sense time Ts2, the read operation of the first BL group and the read operation corresponding to the second BL group can be executed using the same read voltage.

### 1.8.4.2 Voltages of Selected Word Line and Control Signal STB in Lower Page Data Read Operation

Next, the voltages of the selected word line WL and the control signal STB in the Lower page data read operation will be described with reference to FIG. 41. FIG. 41 is a timing chart illustrating the voltages of the selected word line WL and the control signal STB in the Lower page data read operation.

As illustrated in FIG. 41, during the period from the time T0 to the time T1, the read operation AR of the A state is executed. More specifically, during the period from the time T0 to the time T1, the read voltage (VA+Δa) is applied to the selected word line WL. In this state, at the time Ta1, the control signal STB is set to the “H” level. At this time, a strobe operation (read operation AR1) corresponding to the first BL group (first sense time Ts1) is executed. Next, at the time Ta2, the control signal STB is set to the “H” level. At this time, a strobe operation (read operation AR2) corresponding to the second BL group (second sense time Ts2) is executed.

During the period from the time T1 to the time T2, the read operation ER of the E state is executed. More specifically, during the period from the time T1 to the time T2, the read voltage (VE+Δe) is applied to the selected word line WL. In this state, at the time Te1, the control signal STB is set to the “H” level. At this time, a strobe operation (read operation ER1) corresponding to the first BL group (first sense time Ts1) is executed. Next, at the time Te2, the control signal STB is set to the “H” level. At this time, a strobe operation (read operation ER2) corresponding to the second BL group (second sense time Ts2) is executed.

### 1.8.4.3 Effects According to Present Modification

With the configuration according to the present modification, effects similar to those of the first embodiment can be obtained.

Furthermore, with the configuration according to the present modification, shift read for each BL group can be executed by applying one read voltage to one state. As a result, it is possible to suppress an increase in the processing time due to the voltage application to the selected word line WL in the shift read for each BL group.

### 1.8.5 Fifth Modification

Next, the fifth modification of the first embodiment will be described. In the present modification, a configuration of a memory system 1 different from that of the first embodiment will be described.

### 1.8.5.1 Configuration of Memory Controller

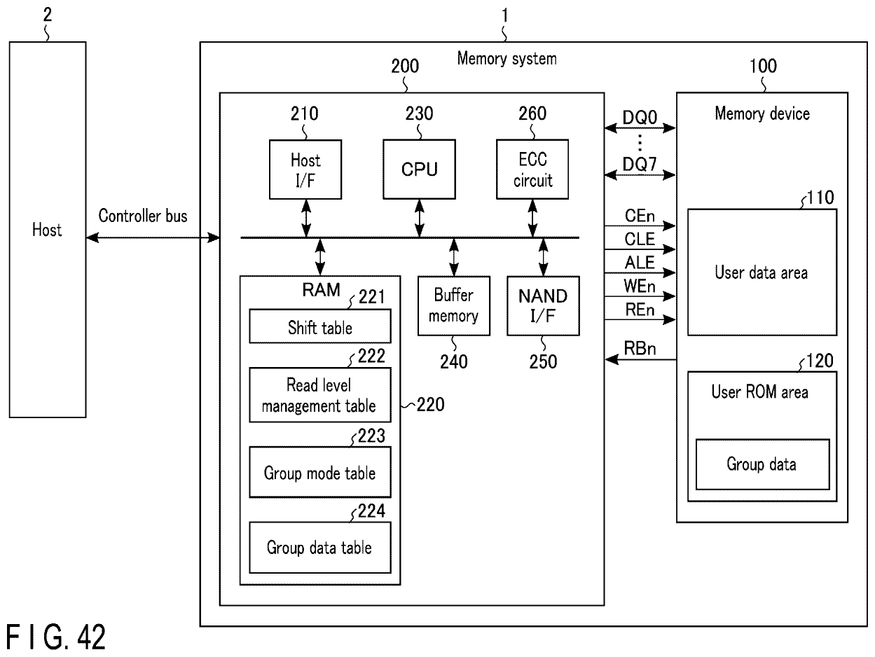

First, an example of a configuration of the memory controller 200 will be described with reference to FIG. 42. FIG. 42 is a block diagram illustrating an example of a configuration of an information processing system including the memory system 1.

As shown in FIG. 42, the configurations of the host interface circuit 210, the CPU 230, the buffer memory 240, and the NAND interface circuit 250 of the memory controller 200, and the ECC circuit 260 is similar to those of the first embodiment in FIG. 1.

In the present embodiment, the RAM 220 further includes a group data table 224. The group data table 224 is a table for temporarily storing at least part of the group data read from the user ROM area 120 of the memory device 100. For example, the group data table 224 stores group data having a high use frequency or group data used most recently.

### 1.8.5.2 Flow of Read Operation Using History Value

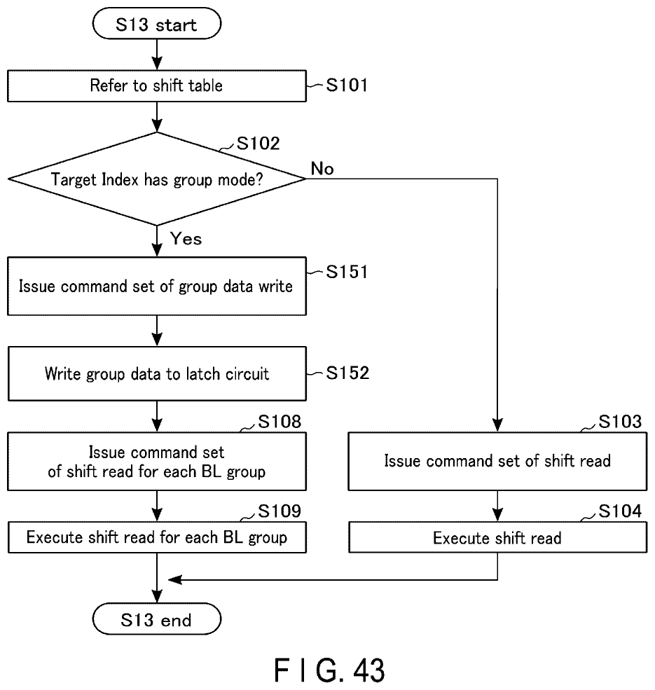

Next, an example of a flow of the read operation using the history value will be described with reference to FIG. 43. FIG. 43 is a flowchart illustrating an example of a flow of the read operation using the history value. Note that FIG. 43 corresponds to step S13 in FIG. 16.

As illustrated in FIG. 43, the CPU 230 refers to the shift table 221 and checks the information about the target index corresponding to the history value of the selected word line WL (S101).

In a case where the group mode is not set for the target index (S102_No), the CPU 230 executes steps S103 and S104 as in the description of the first embodiment with reference to FIG. 19.

On the other hand, in a case where the group mode is set for the target index (S102_Yes), the CPU 230 writes the target group data stored in the group data table 224 of the RAM 220 to the latch circuit of the sense amplifier module 21. Therefore, the CPU 230 issues a command set of group data write (S151). The command set of group data write includes a command CMD instructing execution of a write operation of the group data and a write destination, and the group data. The CPU 230 transmits the command set of group data write to the memory device 100.

Upon receiving the command set of group data write, the sequencer 15 writes the group data in the latch circuit (for example, the latch circuit ADL) designated as the write destination (S152).

Next, the CPU 230 sequentially executes steps S108 and S109. That is, the CPU 230 executes shift read for each BL group.

### 1.8.5.3 Effects According to Present Modification

With the configuration according to the present modification, effects similar to those of the first embodiment can be obtained.

Furthermore, with the configuration according to the present modification, since the memory controller 200 has the group data, the group data read in the memory device 100 can be omitted. Therefore, an increase in the read time in the memory device 100 can be suppressed.

### 2. SECOND EMBODIMENT

Next, a second embodiment will be described. In the second embodiment, a case where grouping of BL groups is different for each state will be described. Hereinafter, differences from the first embodiment will be mainly described.

### 2.1 Specific Example of Grouping of BL Groups

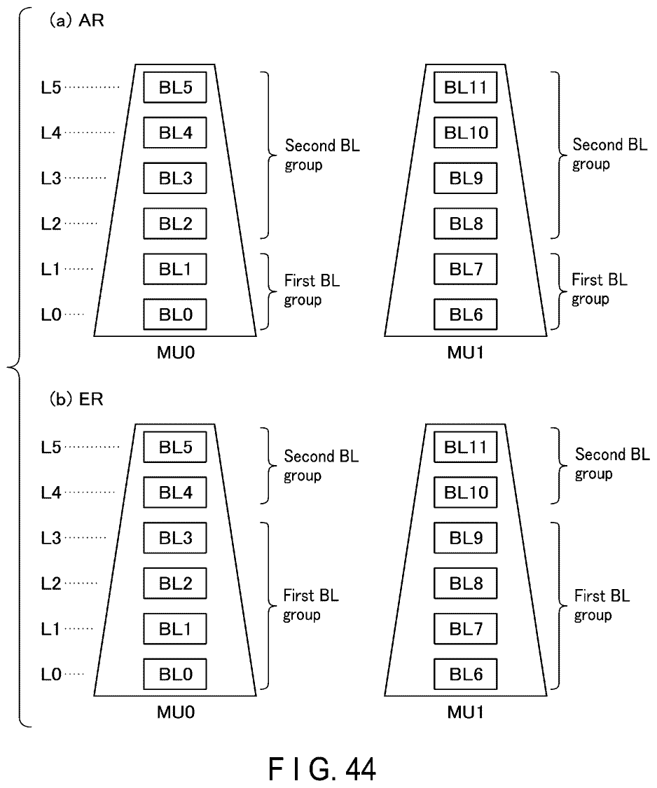

First, a specific example of grouping of the bit lines BL will be described with reference to FIG. 44. FIG. 44 is a diagram schematically illustrating an example of grouping of the bit lines BL corresponding to the read operations AR and ER.

As illustrated in (a) of FIG. 44, in the present specific example, in the read operation AR, the bit lines BL0, BL1, BL6, and BL7 corresponding to the layers L0 and L1 belong to the first BL group, and the bit lines BL2 to BL5 and BL8 to BL11 corresponding to the layers L2 to L5 belong to the second BL group.

As illustrated in (b) of FIG. 44, in the read operation ER, the bit lines BL0 to BL3 and BL6 to BL9 corresponding to the layers L0 to L3 belong to the first BL group, and the bit lines BL4, BL5, BL10, and BL11 corresponding to the layers L4 and L5 belong to the second BL group. As described above, the grouping of the BL group is different between the A state and the E state.

### 2.2 Command Sequence of Lower Page Data Read Operation

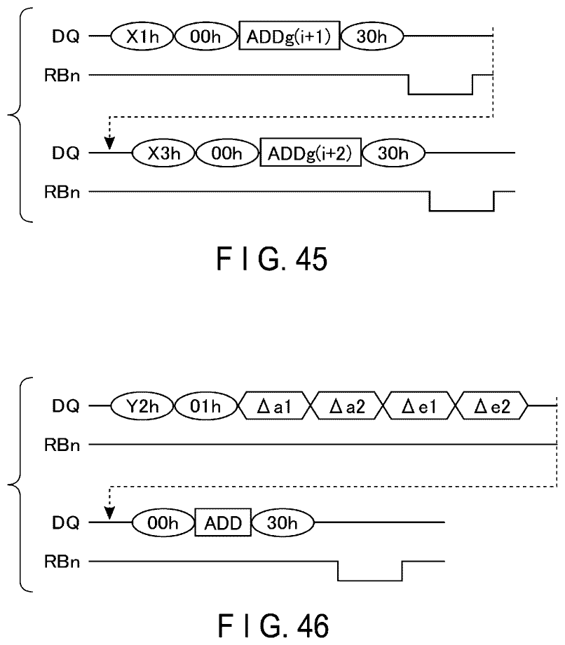

Next, an example of a command sequence of the read operation of the Lower page data will be described with reference to FIGS. 45 and 46. FIG. 45 is a diagram illustrating an example of a command set of group data read. FIG. 46 is a diagram illustrating an example of a command set of shift read of the Lower page data.

First, a command set of group data read will be described.

As illustrated in FIG. 45, first, the memory controller 200 issues a command set of group data read corresponding to the read operation AR. The memory controller 200 transmits a command “X1h”, a command “00h”, an address “ADDg(1+1)”, and a command “30h” to the memory device 100. The address “ADDg(i+1)” is an address designating the page PG(i+1).

Upon receiving the command “30h”, the sequencer 15 sets the ready/busy signal RBn to the “L” level. Then, based on the command “X1h”, the sequencer 15 executes the SLC read operation. In a case where the group data of the page PG(i+1) is transferred to the latch circuit ADL, the sequencer 15 sets the ready/busy signal RBn to the “H” level.

Next, the memory controller 200 issues a command set of group data read corresponding to the read operation ER. The memory controller 200 transmits a command “X3h”, a command “00h”, an address “ADDg(i+2)”, and a command “30h” to the memory device 100. The command “X3h” is a prefix command indicating reading the SLC data and that the read destination is the latch circuit BDL. In the case of the command “X3h”, the group data is stored in the latch circuit BDL. The address “ADDg(i+2)” is an address designating the page PG(i+2).

Upon receiving the command “30h”, the sequencer 15 sets the ready/busy signal RBn to the “L” level. Then, the sequencer 15 executes the SLC read operation based on the command “X3h”. In a case where the group data of the page PG(i+2) is transferred to the latch circuit BDL, the sequencer 15 sets the ready/busy signal RBn to the “H” level.

Next, a command set corresponding to shift read for each BL group will be described.

As illustrated in FIG. 46, first, the memory controller 200 transmits a command “Y2 h” to the memory device 100. The command “Y2 h” is a prefix command indicating that the number of groups corresponding to each state is two and shift read for each BL group is executed using the latch circuits ADL and BDL. Next, the memory controller 200 transmits a command “01h” to the memory device 100. Next, the memory controller 200 sequentially transmits the shift values Δa1, Δa2, Δe1, and Δe2 to the memory device 100. The shift values Δa1 and Δa2 have a relationship of Δa1<Δa2. The shift values Δe1 and Δe2 have a relationship of Δe1<Δe2.

Next, the memory controller 200 transmits a command “00h”, an address “ADD”, and a command “30h” to the memory device 100.

Upon receiving the command “30h”, the sequencer 15 sets the ready/busy signal RBn to the “L” level. Then, based on the command “Y2 h”, the sequencer 15 executes shift read for each BL group in a case where the number of groups corresponding to each state is two and the latch circuits ADL and BDL are used. In a case where the shift read operation is ended, the sequencer 15 sets the ready/busy signal RBn to the “H” level.

### 2.3 Specific Example of Lower Page Data Read Operation In a Case where Grouping of BL Groups is Different for Each State

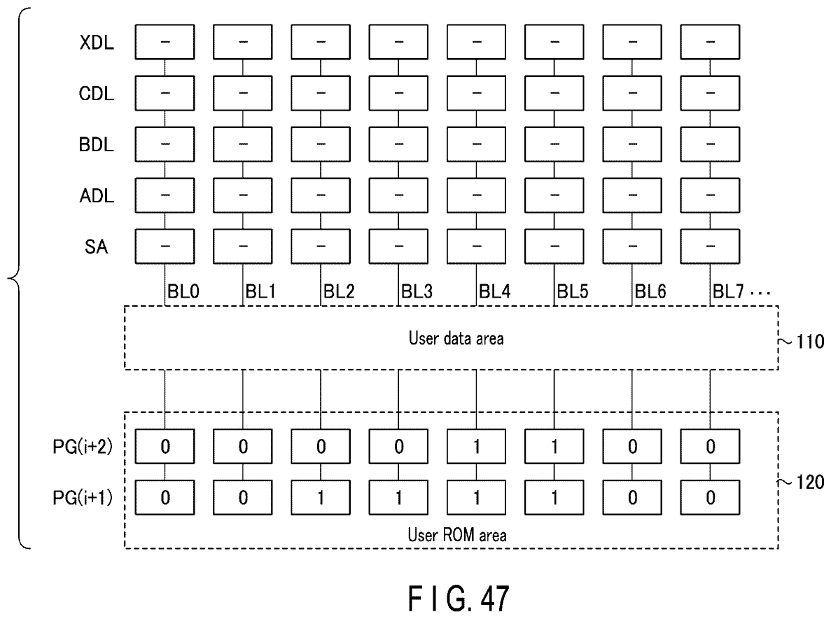

Next, a specific example of the read operation of the Lower page data in a case where the grouping of the BL group is different for each state will be described with reference to FIGS. 47 to 53. FIGS. 47 to 53 are diagrams illustrating an example of the states of the latch circuits at the time of the read operation of the Lower page data in a case where the grouping of the BL group is different for each state of threshold voltage distributions. In the examples illustrated in FIGS. 47 to 53, the operation unit OP is omitted.

As illustrated in FIG. 47, the group data corresponding to the read operation AR is stored in the page PG(i+1) of the user ROM area 120. For example, the bit lines BL0, BL1, BL6, and BL7 belong to the first BL group, and the bit lines BL2, BL3, BL4, and BL5 belong to the second BL group.

In addition, the group data corresponding to the read operation ER is stored in the page PG(i+2). For example, the bit lines BL0, BL1, BL2, BL3, BL6, and BL7 belong to the first BL group, and the bit lines BL4 and BL5 belong to the second BL group.

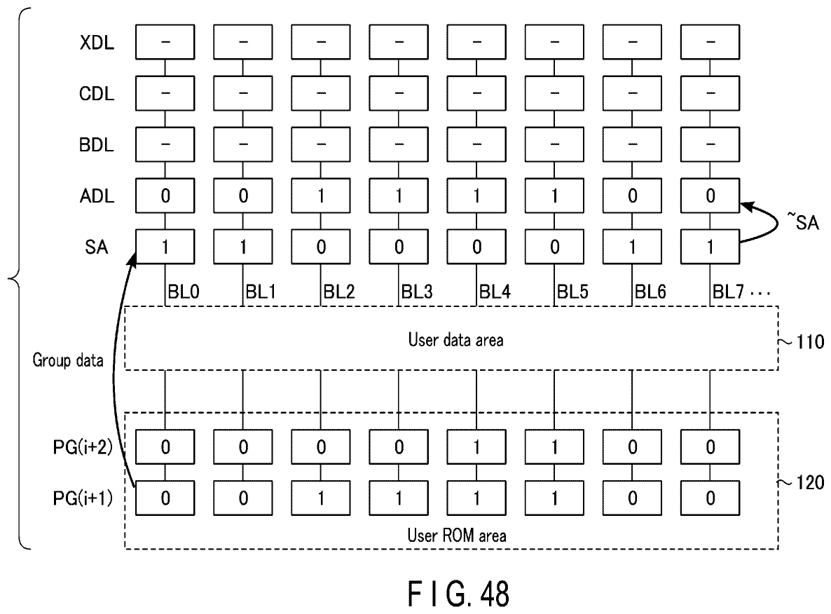

As illustrated in FIG. 48, first, the group data read of the page PG(i+1) is executed based on the command set of group data read corresponding to the read operation AR described with reference to FIG. 45. The sense circuit SA reads the group data stored in the page PG(i+1). At this time, the group data is inverted in the sense circuit SA. The operation unit OP transfers inverted data (~SA) of data stored in the sense circuit SA to the latch circuit ADL. As a result, the same data as the page PG(i+1) is stored in the latch circuit ADL. “0” data is stored in the latch circuit ADL corresponding to the first BL group, and “1” data is stored in the latch circuit ADL corresponding to the second BL group.

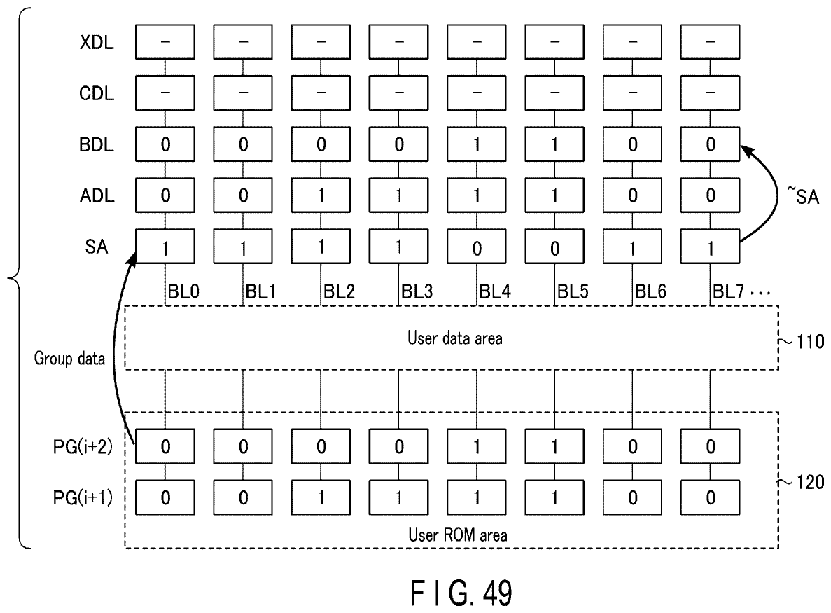

As illustrated in FIG. 49, next, the group data read of the page PG(i+2) is executed based on the command set of group data read corresponding to the read operation ER described with reference to FIG. 45. The sense circuit SA reads the group data stored in the page PG(i+2). At this time, the group data is inverted in the sense circuit SA. The operation unit OP transfers inverted data (~SA) of data stored in the sense circuit SA to the latch circuit BDL. As a result, the same data as the page PG(i+2) is stored in the latch circuit BDL. “0” data is stored in the latch circuit BDL corresponding to the first BL group, and “1” data is stored in the latch circuit BDL corresponding to the second BL group.

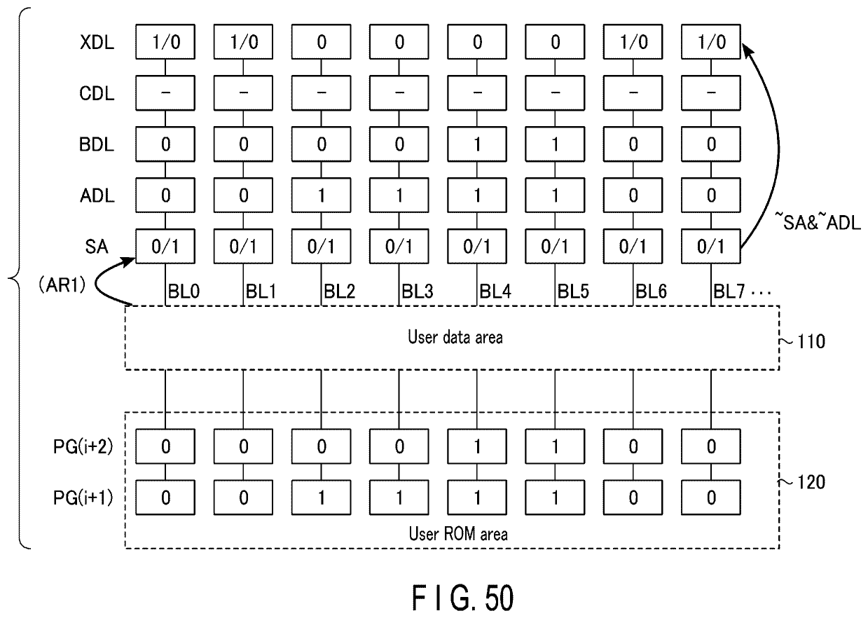

As illustrated in FIG. 50, the shift read of the Lower page is executed based on the command set of shift read for each BL group described with reference to FIG. 46. First, the read operation AR1 of the A state of the first BL group is executed. The sense circuit SA stores the data (0/1) read by the read operation AR1. The operation unit OP executes the operation of Expression (1) using the read data of the sense circuit SA and the group data of the latch circuit ADL, and transfers the result to the latch circuit XDL.

As a result, the inverted data (1/0) of the sense circuit SA is stored in the latch circuits XDL corresponding to the bit lines BL0, BL1, BL6, and BL7. “0” data is stored in the latch circuits XDL corresponding to the bit lines BL2, BL3, BL4, and BL5. In other words, inverted data (1/0) of the sense circuit SA is stored in the latch circuit XDL corresponding to the first BL group (ADL=0), and “O” data is stored in the latch circuit XDL corresponding to the second BL group (ADL=1).

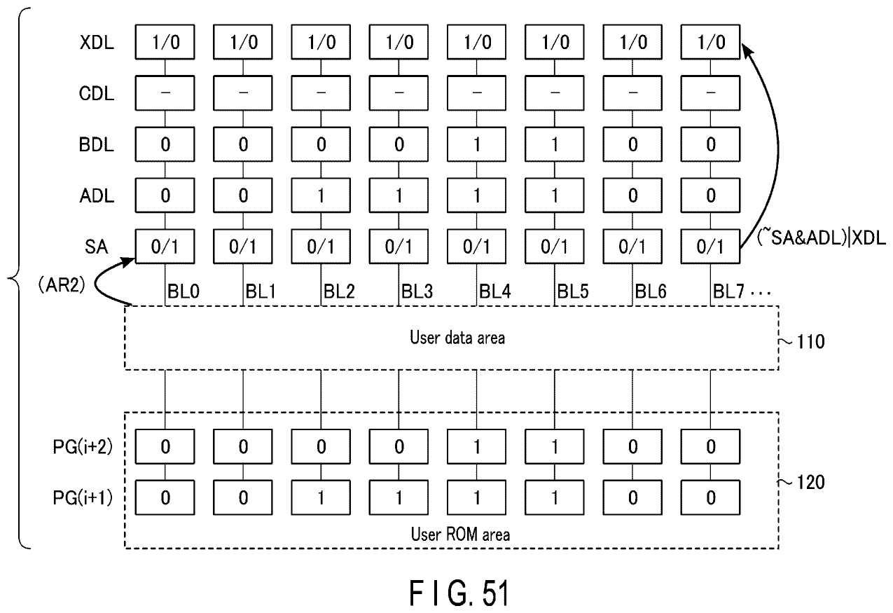

As illustrated in FIG. 51, next, the read operation AR2 of the A state of the second BL group is executed. The sense circuit SA stores the data (0/1) read by the read operation AR2. The operation unit OP executes the operation of Expression (2) using the read data of the sense circuit SA, the group data of the latch circuit ADL, and the data of the latch circuit XDL, and transfers the result to the latch circuit XDL.

As a result, the inverted data (1/0) of the sense circuit SA is stored in the latch circuits XDL corresponding to the bit lines BL2, BL3, BL4, and BL5. In other words, the inverted data (1/0) of the sense circuit SA is stored in the latch circuit XDL corresponding to the second BL group (ADL=1). As a result, the result of the read operation AR of the A state is stored in each latch circuit XDL.

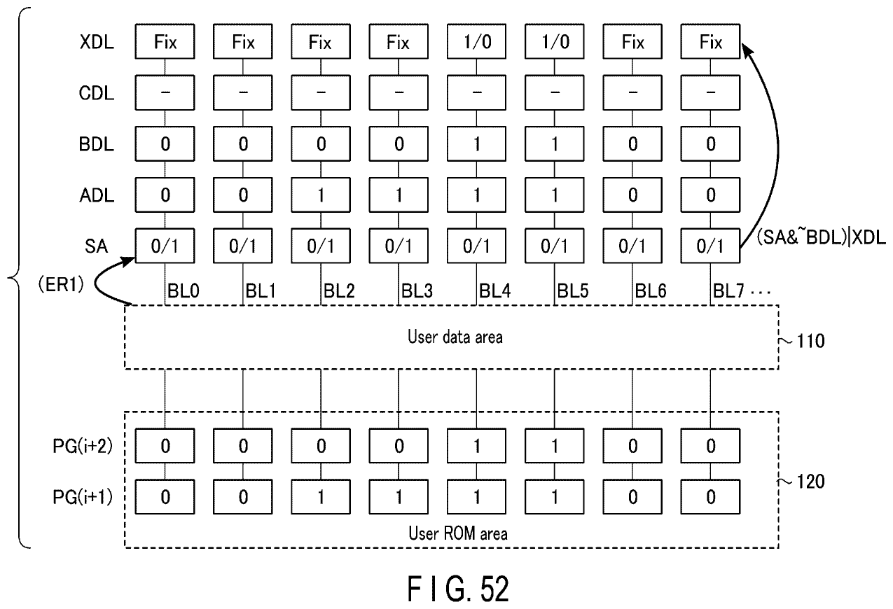

As illustrated in FIG. 52, next, the read operation ER1 of the E state of the first BL group is executed. The sense circuit SA stores the data (0/1) read by the read operation ER1. The operation unit OP executes the operation of Expression (7) using the read data of the sense circuit SA, the group data of the latch circuit BDL, and the data of the latch circuit XDL, and transfers the result to the latch circuit XDL.

XDL=(SA&~BDL)|XDL (7)

As a result, the read result (Fix) of the Lower page data is stored in the latch circuits XDL corresponding to the bit lines BL0, BL1, BL2, BL3, BL6, and BL7. In other words, the read result (Fix) of the Lower page data is stored in the latch circuit XDL corresponding to the first BL group (BDL=0). As a result, the Lower page data of the first BL group is determined.

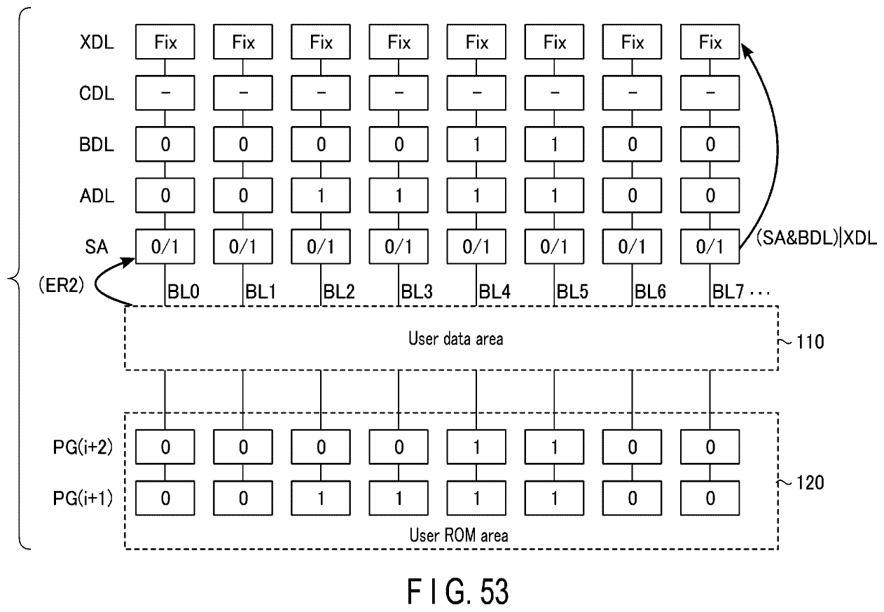

As illustrated in FIG. 53, next, the read operation ER2 of the E state of the second BL group is executed. The sense circuit SA stores the data (0/1) read by the read operation ER2. The operation unit OP executes the operation of Expression (8) using the read data of the sense circuit SA, the group data of the latch circuit BDL, and the data of the latch circuit XDL, and transfers the result to the latch circuit XDL.

XDL=(SA&BDL)|XDL (8)

As a result, the read result (Fix) of the Lower page data is stored in the latch circuits XDL corresponding to the bit lines BL2, BL3, BL4, and BL5. In other words, the read result (Fix) of the Lower page data is stored in the latch circuit XDL corresponding to the second BL group (BDL=1). As a result, the Lower page data of the second BL group is determined. Each latch circuit XDL stores a read result of the Lower page data.

### 2.4 Effects According to Present Embodiment

With the configuration according to the present embodiment, effects similar to those of the first embodiment can be obtained.

Furthermore, with the configuration according to the present embodiment, shift read for each BL group can be executed in a case where grouping of BL groups is different for each state.

Note that the first to fifth modifications of the first embodiment can be applied to the second embodiment.

### 3. THIRD EMBODIMENT

Next, a third embodiment will be described. In the third embodiment, a case where the number of groups is four will be described. Hereinafter, differences from the first and second embodiments will be mainly described.

### 3.1 Specific Example of Grouping of BL Groups

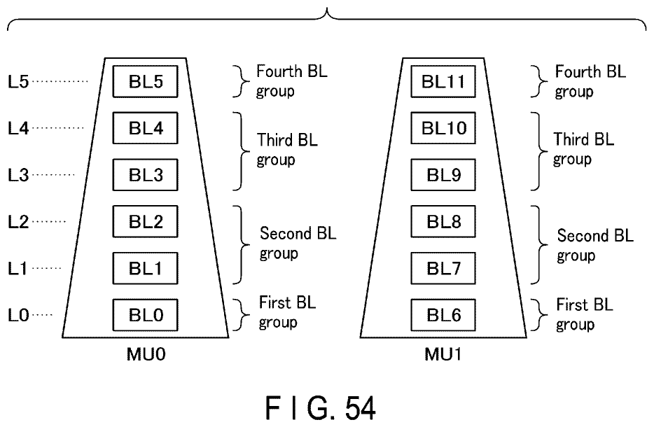

First, a specific example of grouping of the bit lines BL will be described with reference to FIG. 54. FIG. 54 is a diagram schematically illustrating an example of grouping of the bit lines BL.

As illustrated in FIG. 54, in the specific example, the bit lines BL0 and BL6 corresponding to the layer L0 belong to the first BL group. The bit lines BL1, BL2, BL7, and BL8 corresponding to the layers L1 and L2 belong to the second BL group. The bit lines BL3, BL4, BL9, and BL10 corresponding to the layers L3 and L4 belong to the third BL group. The bit lines BL5 and BL11 corresponding to the layer L5 belong to the fourth BL group.

### 3.2 Command Sequence of Lower Page Data Read Operation

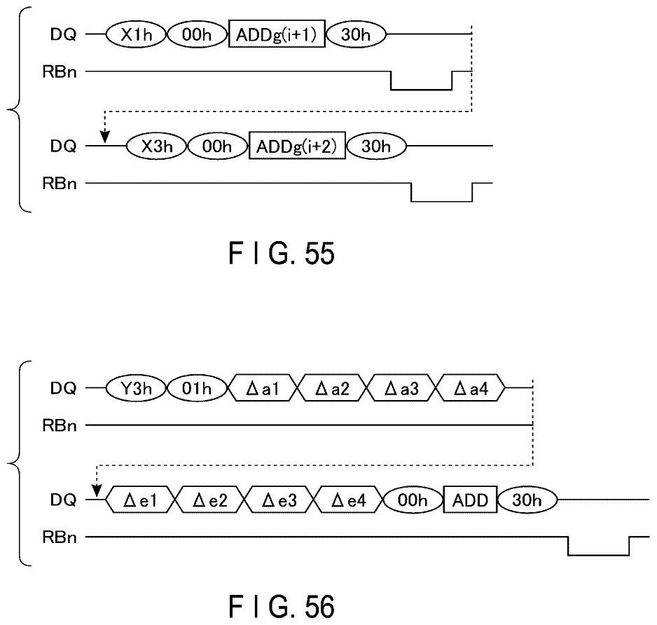

Next, an example of a command sequence of the read operation of the Lower page data will be described with reference to FIGS. 55 and 56. FIG. 55 is a diagram illustrating an example of a command set of group data read. FIG. 56 is a diagram illustrating an example of a command set of shift read of the Lower page data.

First, a command set of group data read will be described.

As illustrated in FIG. 55, first, the memory controller 200 issues a command set of group data read for reading the group data to the latch circuit ADL. The memory controller 200 transmits a command “X1h”, a command “00h”, an address “ADDg(i+1)”, and a command “30h” to the memory device 100.

Upon receiving the command “30h”, the sequencer 15 sets the ready/busy signal RBn to the “L” level. Then, based on the command “X1h”, the sequencer 15 executes the SLC read operation. In a case where the group data of the page PG(i+1) is transferred to the latch circuit ADL, the sequencer 15 sets the ready/busy signal RBn to the “H” level.

Next, the memory controller 200 issues a command set of group data read for reading the group data to the latch circuit BDL. The memory controller 200 transmits a command “X3h”, a command “00h”, an address “ADDg(i+2)”, and a command “30h” to the memory device 100.

Upon receiving the command “30h”, the sequencer 15 sets the ready/busy signal RBn to the “L” level. Then, the sequencer 15 executes the SLC read operation based on the command “X3h”. In a case where the group data of the page PG(i+2) is transferred to the latch circuit BDL, the sequencer 15 sets the ready/busy signal RBn to the “H” level.

Next, a command set corresponding to shift read for each BL group will be described.

As illustrated in FIG. 56, first, the memory controller 200 transmits a command “Y3 h” to the memory device 100. The command “Y3 h” is a prefix command indicating shift read for each BL group in a case where the number of groups is four. Next, the memory controller 200 transmits a command “01h” to the memory device 100. Next, the memory controller 200 sequentially transmits the shift values Δa1, Δa2, Δa3, Δa4, Δe1, Δe2, Δe3, and Δe4 to the memory device 100. The shift values Δa1 to Δa4 correspond to the first to fourth BL groups of the read operation AR, respectively. The shift values Δe1 to Δe4 correspond to the first to fourth BL groups of the read operation ER, respectively. The shift values Δa1, Δa2, Δa3, and Δa4 have a relationship of Δa1<Δa2<Δa3<Δa4. The shift values Δe1, Δe2, Δe3, and Δe4 have a relationship of Δe1<Δe2<Δe3<Δe4.

Next, the memory controller 200 transmits a command “00h”, an address “ADD”, and a command “30h” to the memory device 100.

Upon receiving the command “30h”, the sequencer 15 sets the ready/busy signal RBn to the “L” level. Then, the sequencer 15 executes the shift read for each BL group in a case where the number of groups is four based on the command “Y3 h”. In a case where the shift read operation is ended, the sequencer 15 sets the ready/busy signal RBn to the “H” level.

### 3.3 Voltage of Selected Word Line at Time of Read Operation of Lower Page Data

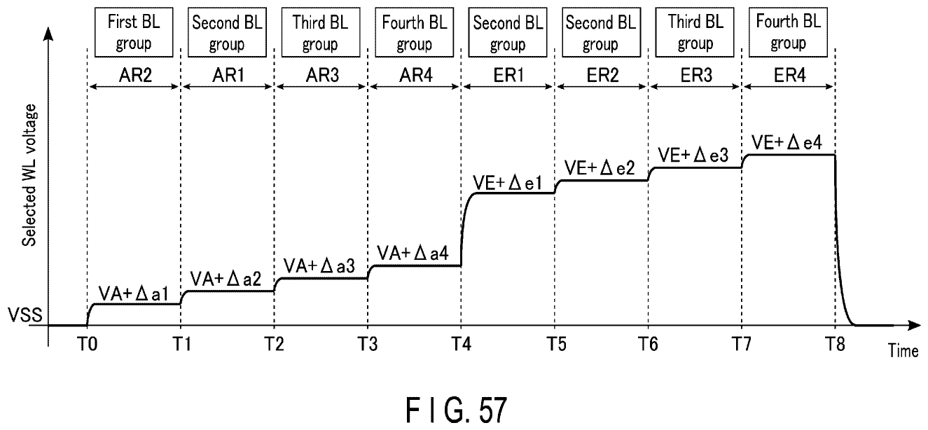

Next, an example of the voltage of the selected word line WL at the time of the Lower page data read operation will be described with reference to FIG. 57. FIG. 57 is a timing chart illustrating an example of the voltage of the selected word line WL in the shift read of the Lower page data in a case where the number of groups of the BL groups is four.

As illustrated in FIG. 57, in each state, the read voltage is applied to the selected word line WL in ascending order.

During the period from the time T0 to the time T1, first, the read voltage (VA+Δa1) corresponding to the read operation AR1 of the A state of the first BL group is applied to the selected word line WL.

During the period from the time T1 to the time T2, the read voltage (VA+Δa2) corresponding to the read operation AR2 of the A state of the second BL group is applied to the selected word line WL.

During the period from the time T2 to the time T3, the read voltage (VA+Δa3) corresponding to the read operation AR3 of the A state of the third BL group is applied to the selected word line WL.

During the period from the time T3 to the time T4, the read voltage (VA+Δa4) corresponding to the read operation AR4 of the A state of the fourth BL group is applied to the selected word line WL.

During the period from the time T4 to the time T5, the read voltage (VE+Δe1) corresponding to the read operation ER1 of the E state of the first BL group is applied to the selected word line WL.

During the period from the time T5 to the time T6, the read voltage (VE+Δe2) corresponding to the read operation ER2 of the E state of the second BL group is applied to the selected word line WL.

During the period from the time T6 to the time T7, the read voltage (VE+Δe3) corresponding to the read operation ER3 of the E state of the third BL group is applied to the selected word line WL.

During the period from the time T7 to the time T8, the read voltage (VE+Δe4) corresponding to the read operation ER4 of the E state of the fourth BL group is applied to the selected word line WL.

### 3.4 Specific Example of Lower Page Data Read Operation In a Case where the Number of Groups is Four

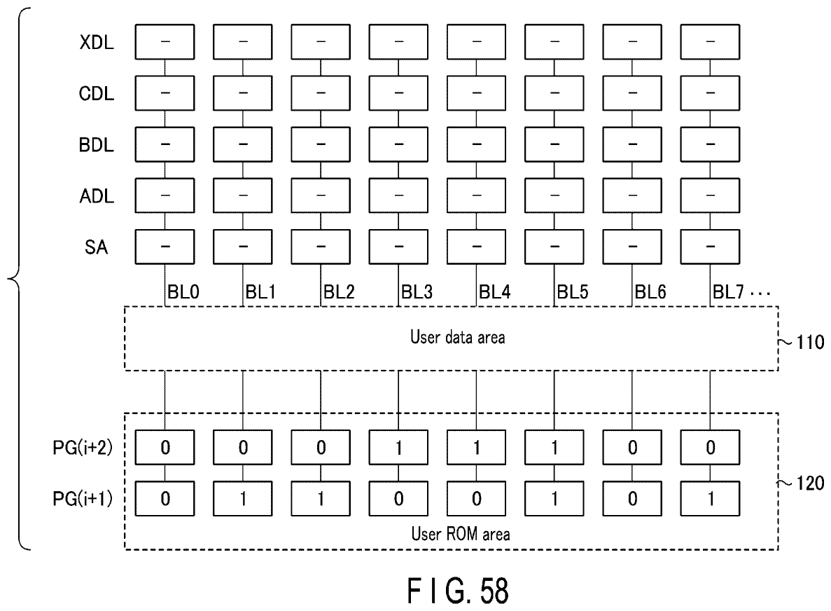

Next, a specific example of the read operation of the Lower page data in a case where the number of groups is 4 will be described with reference to FIGS. 58 to 67. FIGS. 58 to 67 are diagrams illustrating an example of the states of the latch circuits at the time of the Lower page data read operation. In the examples illustrated in FIGS. 58 to 67, the operation unit OP is omitted.

As illustrated in FIG. 58, the group data in a case where the number of groups is four is stored in pages PG(i+1) and PG(i+2) of the user ROM area 120. For example, lower page data is stored in the page PG(i+1), and upper page data is stored in the page PG(i+1). In this case, 2-bit data is allocated to the first to fourth BL groups as shown below.
First BL group: “00” data
Second BL group: “01” data
Third BL group: “10” data
Fourth BL group: “11” data

In the example illustrated in FIG. 58, the bit lines BL0 and BL6 belong to the first BL group. The bit lines BL1, BL2, and BL7 belong to the second BL group. The bit lines BL3 and BL4 belong to the third BL group. The bit line BL5 belongs to the fourth BL group.

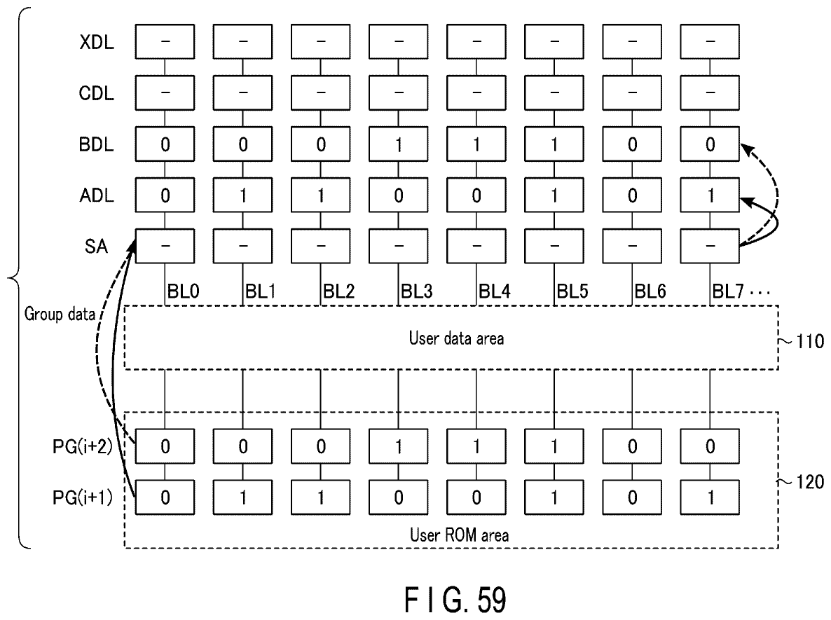

As illustrated in FIG. 59, the group data read of the pages PG(i+1) and PG(i+2) is sequentially executed based on the command set of group data read described with reference to FIG. 55. First, the sense circuit SA reads the group data stored in the page PG(i+1). The operation unit OP transfers inverted data (~SA) of data stored in the sense circuit SA to the latch circuit ADL. As a result, the group data of the page PG(i+1) is stored in the latch circuit ADL. Next, the sense circuit SA reads the group data stored in the page PG(i+2). The operation unit OP transfers inverted data (~SA) of data stored in the sense circuit SA to the latch circuit BDL. As a result, the group data of the page PG(i+2) is stored in the latch circuit BDL.

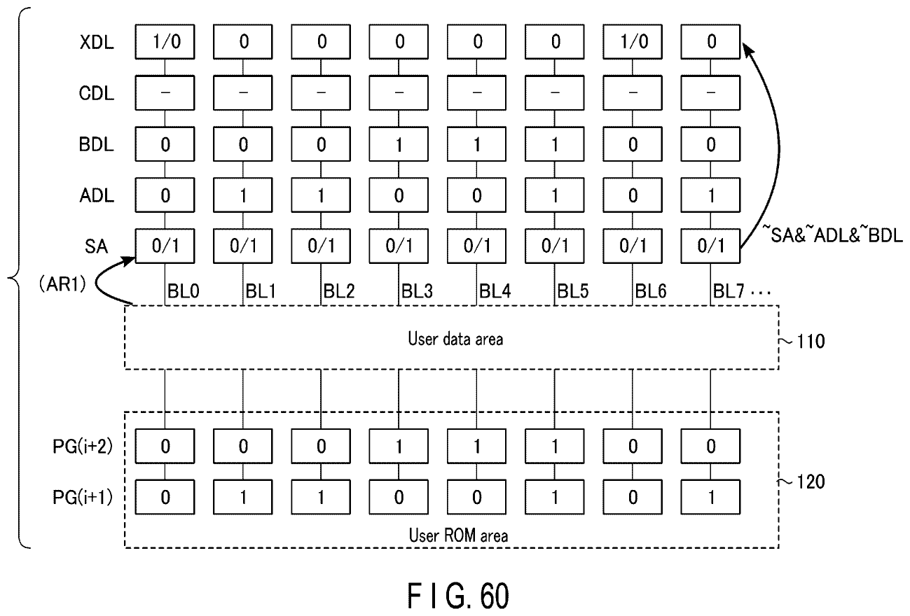

As illustrated in FIG. 60, the shift read of the Lower page is executed based on the command set of shift read for each BL group described with reference to FIG. 56. First, the read operation AR1 of the A state of the first BL group is executed. The sense circuit SA stores the data (0/1) read by the read operation AR1. The operation unit OP executes the operation of Expression (9) using the read data of the sense circuit SA and the group data of the latch circuits ADL and BDL, and transfers the result to the latch circuit XDL.

XDL=~SA&~ADL&~BDL (9)

As a result, the inverted data (1/0) of the sense circuit SA is stored in the latch circuits XDL corresponding to the bit lines BL0 and BL6. “0” data is stored in the latch circuits XDL corresponding to the bit lines BL1 to BL5 and BL7. In other words, inverted data (1/0) of the sense circuits SA is stored in the latch circuits XDL corresponding to the first BL group (ADL=0, BDL=0), and “0” data is stored in the latch circuits XDL corresponding to the second to fourth BL groups.

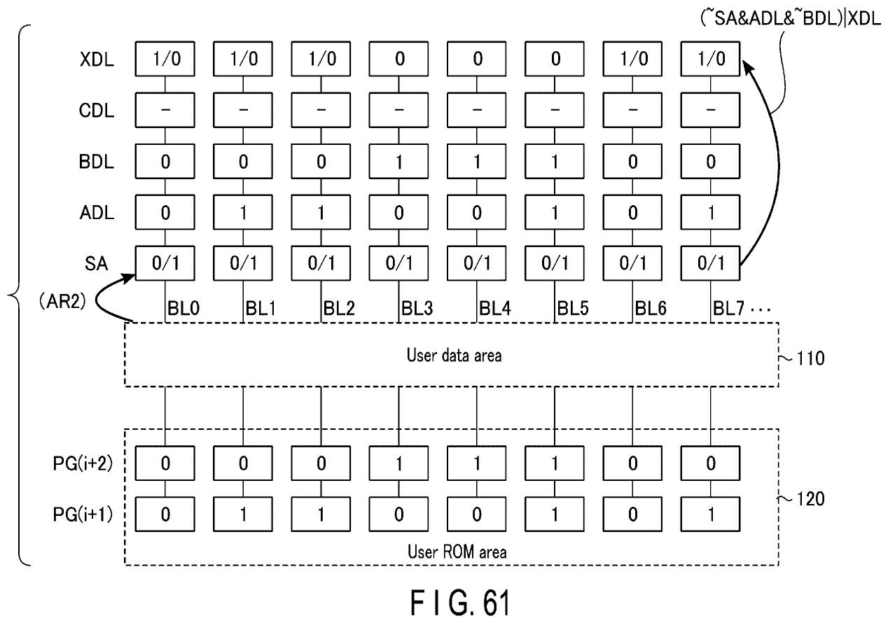

As illustrated in FIG. 61, next, the read operation AR2 of the A state of the second BL group is executed. The sense circuit SA stores the data (0/1) read by the read operation AR2. The operation unit OP executes the operation of Expression (10) using the read data of the sense circuit SA, the group data of the latch circuits ADL and BDL, and the data of the latch circuit XDL, and transfers the result to the latch circuit XDL.

XDL=(~SA&ADL&~BDL)|XDL (10)

As a result, the inverted data (1/0) of the sense circuit SA is stored in the latch circuits XDL corresponding to the bit lines BL1, BL2, and BL7. In other words, the inverted data (1/0) of the sense circuit SA is stored in the latch circuit XDL corresponding to the second BL group (ADL=1, BDL=0).

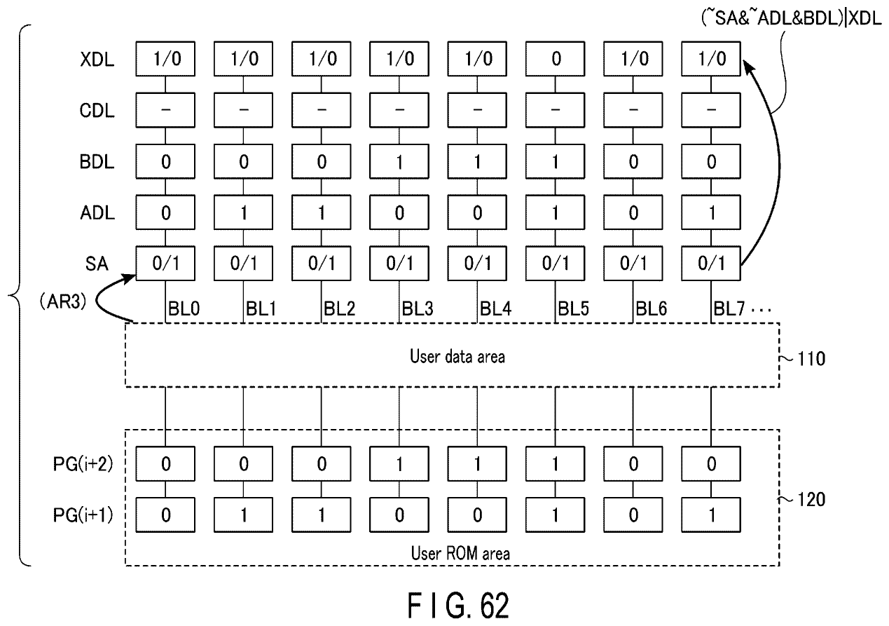

As illustrated in FIG. 62, next, the read operation AR3 of the A state of the third BL group is executed. The sense circuit SA stores the data (0/1) read by the read operation AR3. The operation unit OP executes the operation of Expression (11) using the read data of the sense circuit SA, the group data of the latch circuits ADL and BDL, and the data of the latch circuit XDL, and transfers the result to the latch circuit XDL.

XDL=(~SA&~ADL&BDL)|XDL (11)

As a result, the inverted data (1/0) of the sense circuit SA is stored in the latch circuit XDL corresponding to the bit lines BL3 and BL4. In other words, the inverted data (1/0) of the sense circuit SA is stored in the latch circuit XDL corresponding to the third BL group (ADL=0, BDL=1).

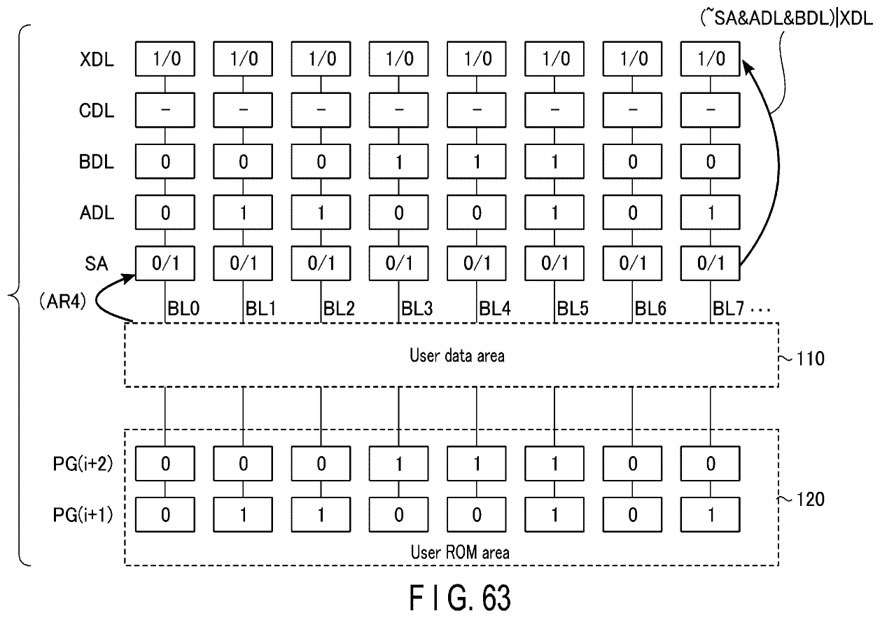

As illustrated in FIG. 63, next, the read operation AR4 of the A state of the fourth BL group is executed. The sense circuit SA stores the data (0/1) read by the read operation AR4. The operation unit OP executes the operation of Expression (12) using the read data of the sense circuit SA, the group data of the latch circuits ADL and BDL, and the data of the latch circuit XDL, and transfers the result to the latch circuit XDL.

XDL=(~SA&ADL&BDL)|XDL (12)

As a result, the inverted data (1/0) of the sense circuit SA is stored in the latch circuit XDL corresponding to the bit line BL5. In other words, the inverted data (1/0) of the sense circuit SA is stored in the latch circuit XDL corresponding to the fourth BL group (ADL=1, BDL=1). As a result, the result of the read operation AR of the A state is stored in each latch circuit XDL.

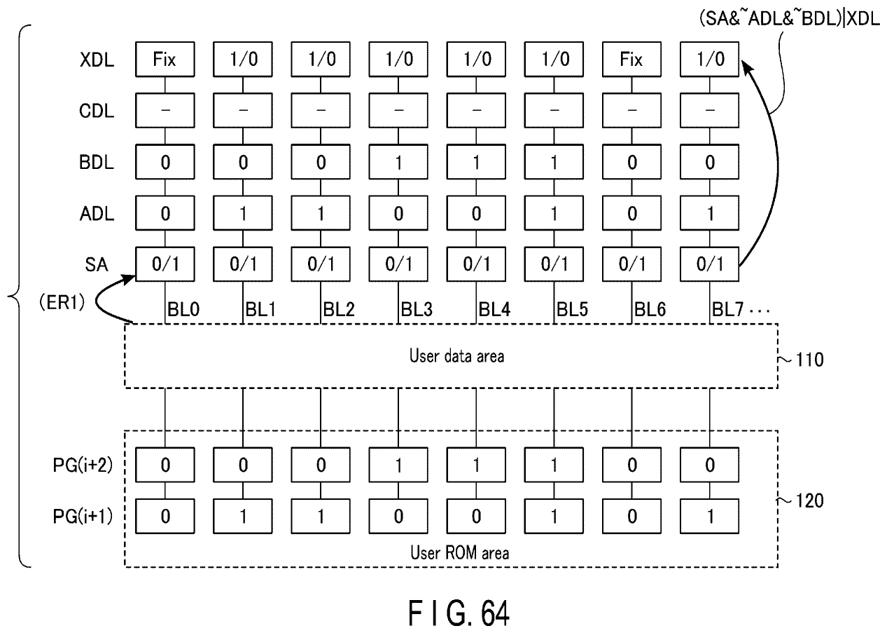

As illustrated in FIG. 64, next, the read operation ER1 of the E state of the first BL group is executed. The sense circuit SA stores the data (0/1) read by the read operation ER1. The operation unit OP executes the operation of Expression (13) using the read data of the sense circuit SA, the group data of the latch circuits ADL and BDL, and the data of the latch circuit XDL, and transfers the result to the latch circuit XDL.

XDL=(SA&~ADL&~BDL)|XDL (13)

As a result, the read result (Fix) of the Lower page data is stored in the latch circuits XDL corresponding to the bit lines BL0 and BL6. In other words, the read result (Fix) of the Lower page data is stored in the latch circuit XDL corresponding to the first BL group (ADL=0, BDL=0). As a result, the Lower page data of the first BL group is determined.

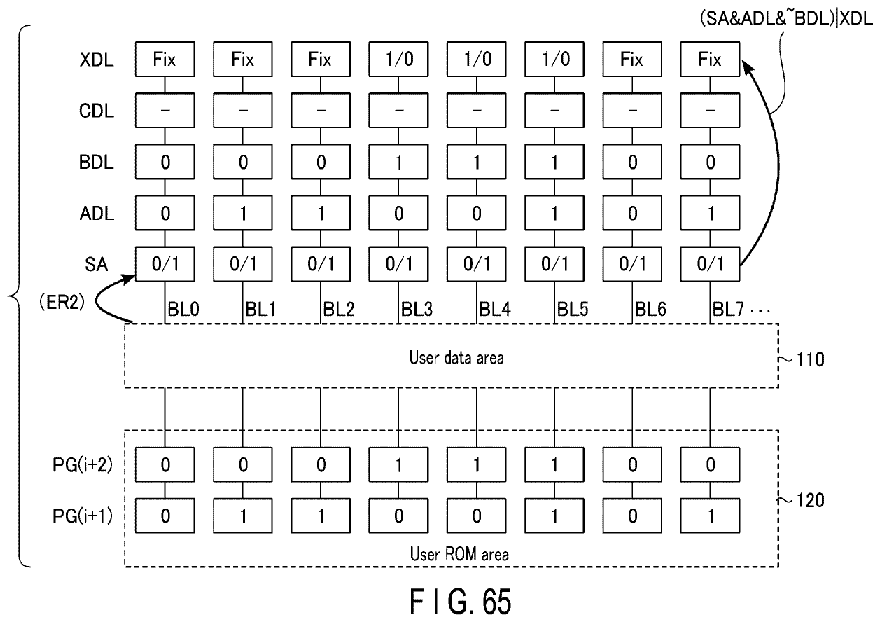

As illustrated in FIG. 65, next, the read operation ER2 of the E state of the second BL group is executed. The sense circuit SA stores the data (0/1) read by the read operation ER2. The operation unit OP executes the operation of Expression (14) using the read data of the sense circuit SA, the group data of the latch circuits ADL and BDL, and the data of the latch circuit XDL, and transfers the result to the latch circuit XDL.

XDL=(SA&ADL&~BDL)|XDL (14)

As a result, the read result (Fix) of the Lower page data is stored in the latch circuits XDL corresponding to the bit lines BL1, BL2, and BL7. In other words, the read result (Fix) of the Lower page data is stored in the latch circuit XDL corresponding to the second BL group (ADL=1, BDL=0). As a result, the Lower page data of the second BL group is determined.

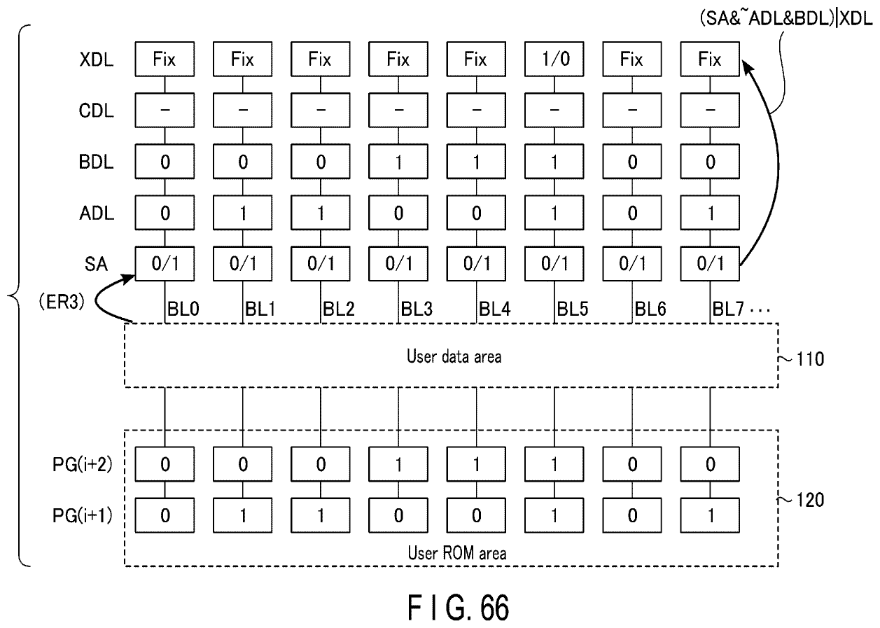

As illustrated in FIG. 66, next, the read operation ER3 of the E state of the third BL group is executed. The sense circuit SA stores the data (0/1) read by the read operation ER3. The operation unit OP executes the operation of Expression (15) using the read data of the sense circuit SA, the group data of the latch circuits ADL and BDL, and the data of the latch circuit XDL, and transfers the result to the latch circuit XDL.

XDL=(SA&~ADL&BDL)|XDL (15)

As a result, the read result (Fix) of the Lower page data is stored in the latch circuits XDL corresponding to the bit lines BL3 and BL4. In other words, the read result (Fix) of the Lower page data is stored in the latch circuit XDL corresponding to the third BL group (ADL=0, BDL=1). As a result, the Lower page data of the third BL group is determined.

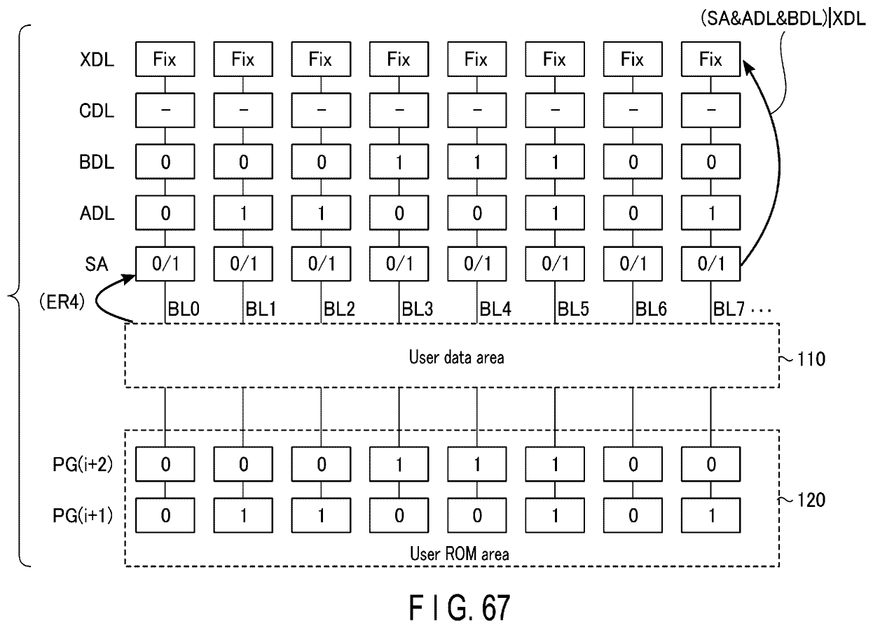

As illustrated in FIG. 67, next, the read operation ER4 of the E state of the fourth BL group is executed. The sense circuit SA stores the data (0/1) read by the read operation ER4. The operation unit OP executes the operation of Expression (16) using the read data of the sense circuit SA, the group data of the latch circuits ADL and BDL, and the data of the latch circuit XDL, and transfers the result to the latch circuit XDL.

XDL=(SA&ADL&BDL)|XDL (16)

As a result, the read result (Fix) of the Lower page data is stored in the latch circuit XDL corresponding to the bit line BL5. In other words, the read result (Fix) of the Lower page data is stored in the latch circuit XDL corresponding to the fourth BL group (ADL=1, BDL=1). As a result, the Lower page data of the fourth BL group is determined. Each latch circuit XDL stores a read result of the Lower page data.

### 3.5 Effects According to Present Embodiment

With the configuration according to the present embodiment, effects similar to those of the first embodiment can be obtained.

Furthermore, in a case where BL groups are grouped into four, the present embodiment can be applied.

The first to fifth modifications of the first embodiment can be applied to the third embodiment.

### 4. FOURTH EMBODIMENT

Next, a fourth embodiment will be described. In the fourth embodiment, a case where shift read for each BL group of nine or more groups is executed using three latch circuits ADL, BDL, and CDL will be described. Hereinafter, differences from the first to third embodiments will be mainly described.

### 4.1 Flow of Read Operation Using History Value

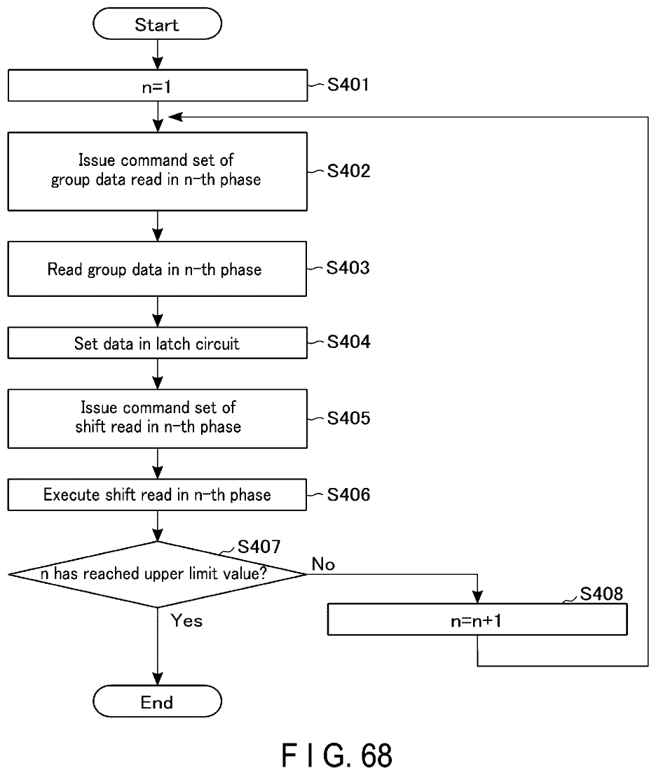

First, an example of a flow of a read operation using a history value will be described with reference to FIG. 68. FIG. 68 is a flowchart illustrating an example of a flow of the read operation using the history value. Note that FIG. 68 illustrates a case where the number of groups of BL groups is larger than powers of the number of bits representing group data.

For example, in the sense amplifier unit SAU, in a case where the group data can be stored in the three latch circuits ADL, BDL, and CDL, each BL group can be represented by 3-bit data. In this case, the maximum number of groups that can be supported by one read operation is eight. In the present embodiment, in a case where the number of groups of the BL group is nine or more, the BL group is divided into a plurality of phases and the read operation is executed.

As illustrated in FIG. 68, the CPU 230 first sets a variable n=1 (S401). The variable n is an integer of one or more indicating a phase number.

The CPU 230 issues a command set of group data read in n-th phase in order to read group data in n-th phase (S402). The CPU 230 transmits the command set of group data read to the memory device 100.

Upon receiving the command set of group data read, the sequencer 15 reads group data in the n-th phase (S403).

The group data in the n-th phase is set in the latch circuit of the sense amplifier module 21 designated as the read destination (S404).

The CPU 230 issues a command set corresponding to the n-th phase shift read (S405). The CPU 230 transmits the issued command set to the memory device 100.

Upon receiving the command set, the sequencer 15 executes n-th phase shift read (S406).

The CPU 230 checks whether the variable n has reached the upper limit value. In a case where the variable n does not reach the upper limit value (S407 No), the CPU 230 counts up the variable n (S408), and then advances the process to S402.

On the other hand, in a case where the variable n reaches the upper limit value (S407 Yes), the CPU 230 ends the read operation.

### 4.2 Specific Example of Group Data Allocation for Each BL Group in Shift Read in First Phase and Second Phase

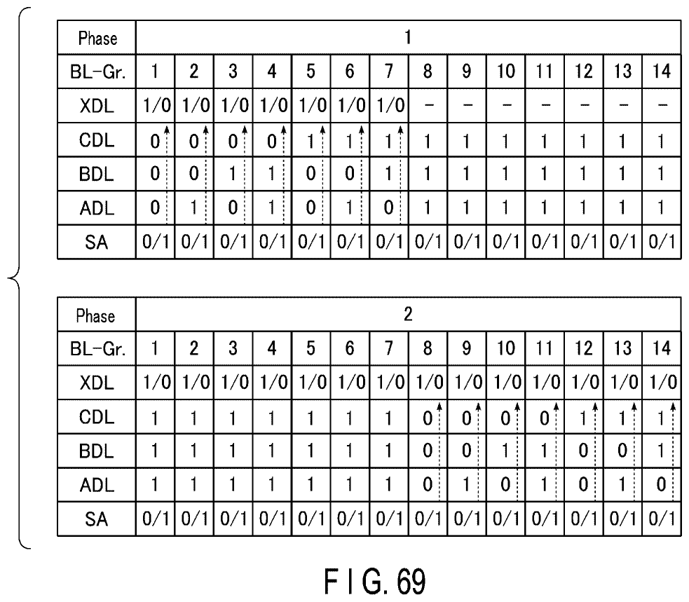

Next, a specific example of the allocation of the group data for each BL group in the shift read in a first phase and a second phase will be described with reference to FIG. 69. FIG. 69 is a diagram illustrating an example of the allocation of the group data for each BL group in the shift read in the first phase and the second phase. Note that the example illustrated in FIG. 69 illustrates a case where the number of groups of the BL group is 14.

As illustrated in FIG. 69, in a case where the number of groups is 14, the shift read of first to seventh BL groups is executed in the first phase, and the shift read of eighth to fourteenth BL groups is executed in the second phase.

For example, lower bit data is stored in the latch circuit ADL, middle bit data is stored in the latch circuit BDL, and upper bit data is stored in the latch circuit CDL. In this case, for example, in the first phase, the following 3-bit data (CDL/BDL/ADL) is allocated to each BL group.
First BL group: “000”
Second BL group: “001”
Third BL group: “010”
Fourth BL group: “011”
Fifth BL group: “100”
Sixth BL group: “101”
Seventh BL group: “110”
Eighth to fourteenth BL groups: “111”

In the first phase, the operation is executed so that the read data is not transferred to the latch circuit XDL corresponding to the “111” data.

Arithmetic expressions corresponding to the read operations AR1 to AR7 of the A state of the first to seventh BL groups will be specifically described.

In the read operation AR1 of the A state of the first BL group, the operation unit OP executes the operation of Expression (17) and transfers the result to the latch circuit XDL.

XDL=~SA&~ADL&~BDL&~CDL (17)

In the read operation AR2 of the A state of the second BL group, the operation unit OP executes the operation of Expression (18) and transfers the result to the latch circuit XDL.

XDL=(~SA&ADL&~BDL&~CDL)|XDL (18)

In the read operation AR3 of the A state of the third BL group, the operation unit OP executes the operation of Expression (19) and transfers the result to the latch circuit XDL.

XDL=(~SA&~ADL&BDL&~CDL)|XDL (19)

In the read operation AR4 of the A state of the fourth BL group, the operation unit OP executes the operation of Expression (20) and transfers the result to the latch circuit XDL.

XDL=(~SA&ADL&BDL&~CDL)|XDL (20)

In the read operation AR5 of the A state of the fifth BL group, the operation unit OP executes the operation of Expression (21) and transfers the result to the latch circuit XDL.

XDL=(~SA&~ADL&~BDL&CDL)|XDL (21)

In the read operation AR6 of the A state of the sixth BL group, the operation unit OP executes the operation of Expression (22) and transfers the result to the latch circuit XDL.

XDL=(~SA&ADL&~BDL&CDL)|XDL (22)

In the read operation AR7 of the A state of the seventh BL group, the operation unit OP executes the operation of Expression (23) and transfers the result to the latch circuit XDL.

XDL=(~SA&~ADL&BDL&CDL)|XDL (23)

Next, arithmetic expressions corresponding to the read operations ER1 to ER7 of the E state of the first to seventh BL groups will be specifically described.

In the read operation ER1 of the E state of the first BL group, the operation unit OP executes the operation of Expression (24) and transfers the result to the latch circuit XDL.

XDL=(SA&~ADL&~BDL&~CDL)|XDL (24)

In the read operation ER2 of the E state of the second BL group, the operation unit OP executes the operation of Expression (25) and transfers the result to the latch circuit XDL.

XDL=(SA&ADL&~BDL&~CDL)|XDL (25)

In the read operation ER3 of the E state of the third BL group, the operation unit OP executes the operation of Expression (26) and transfers the result to the latch circuit XDL.

XDL=(SA&~ADL&BDL&~CDL)|XDL (26)

In the read operation ER4 of the E state of the fourth BL group, the operation unit OP executes the operation of Expression (27) and transfers the result to the latch circuit XDL.

XDL=(SA&ADL&BDL&~CDL)|XDL (27)

In the read operation ER5 of the E state of the fifth BL group, the operation unit OP executes the operation of Expression (28) and transfers the result to the latch circuit XDL.

XDL=(SA&~ADL&~BDL&CDL)|XDL (28)

In the read operation ER6 of the E state of the sixth BL group, the operation unit OP executes the operation of Expression (29) and transfers the result to the latch circuit XDL.

XDL=(SA&ADL&~BDL&CDL)|XDL (29)

In the read operation ER7 of the E state of the seventh BL group, the operation unit OP executes the operation of Expression (30) and transfers the result to the latch circuit XDL.

XDL=(SA&~ADL&BDL&CDL)|XDL (30)

As a result, the Lower page data is stored in the latch circuits XDL corresponding to the first to seventh BL groups.

For example, in the second phase, the following 3-bit data (CDL/BDL/ADL) is allocated to each BL group.
First to seventh BL groups: “111”
Eighth BL group: “000”
Ninth BL group: “001”
Tenth BL group: “010”
Eleventh BL group: “011”
Twelfth BL group: “100”
Thirteenth BL group: “101”
Fourteenth BL group: “110”

In the second phase, as in the first phase, the operation is executed so that the read data is not transferred to the latch circuit XDL corresponding to the “111” data.

First, arithmetic expressions corresponding to the read operations AR8 to AR14 of the A state of the eighth to fourteenth BL groups will be specifically described.

In the read operation AR8 of the A state of the eighth BL group, the operation unit OP executes the operation of Expression (31) and transfers the result to the latch circuit XDL.

XDL=(~SA&~ADL&~BDL&~CDL)|XDL (31)

In the read operations AR9 to AR14 of the A states of the ninth to fourteenth BL groups, the operation unit OP executes the operations of Expressions (18) to (23), and transfers the results to the latch circuit XDL.

Next, arithmetic expressions corresponding to the read operations ER8 to ER14 of the E states of the eighth to fourteenth BL groups will be specifically described.

In the read operations ER8 to ER14 of the E state of the eighth to fourteenth BL groups, the operation unit OP executes the operations of Expressions (24) to (30), and transfers the results to the latch circuit XDL.

As a result, the read data is stored in the latch circuits XDL corresponding to the eighth to fourteenth BL groups.

In a case where the number of groups of the BL group is 15 or more, shift read corresponding to a plurality of groups can be executed by setting three or more phases.

### 4.3 Command Sequence of Lower Page Data Read Operation

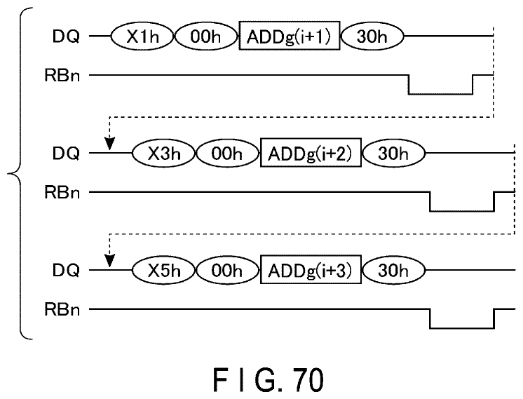

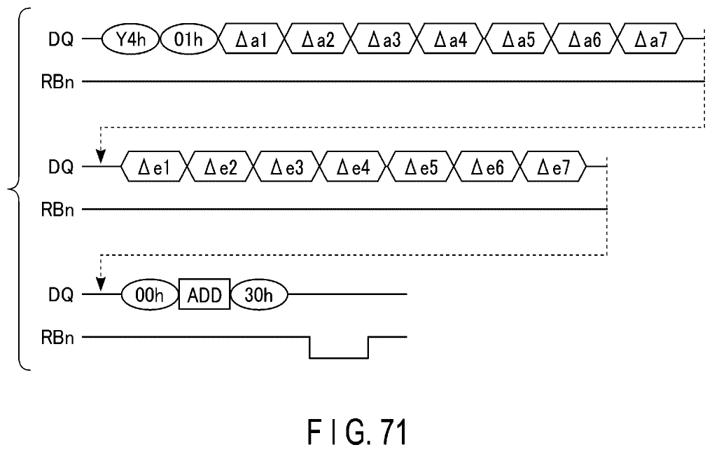

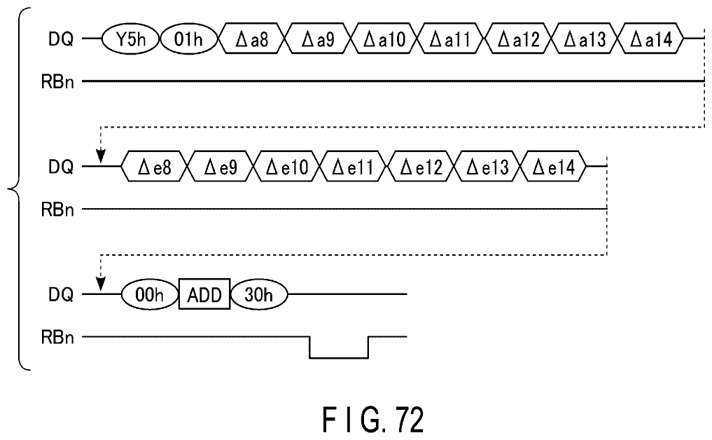

Next, an example of a command sequence of the read operation of the Lower page data will be described with reference to FIGS. 70 to 72. FIG. 70 is a diagram illustrating an example of a command set of group data read. FIG. 71 is a diagram illustrating an example of a command set of shift read in the first phase of the Lower page data. FIG. 72 is a diagram illustrating an example of a command set of shift read in the second phase of the Lower page data.

First, a command set of group data read will be described. In the present embodiment, in each phase, before the shift read is executed, a command set of group data read corresponding to the phase is issued.

As illustrated in FIG. 70, first, the memory controller 200 issues a command set of group data read for reading the group data to the latch circuit ADL. The memory controller 200 transmits a command “X1h”, a command “00h”, an address “ADDg(i+1)”, and a command “30h” to the memory device 100.

Upon receiving the command “30h”, the sequencer 15 sets the ready/busy signal RBn to the “L” level. Then, based on the command “X1h”, the sequencer 15 executes the SLC read operation. In a case where the group data of the page PG(i+1) is transferred to the latch circuit ADL, the sequencer 15 sets the ready/busy signal RBn to the “H” level.

Next, the memory controller 200 issues a command set of group data read for reading the group data to the latch circuit BDL. The memory controller 200 transmits a command “X3h”, a command “00h”, an address “ADDg(i+2)”, and a command “30h” to the memory device 100.

Upon receiving the command “30h”, the sequencer 15 sets the ready/busy signal RBn to the “L” level. Then, the sequencer 15 executes the SLC read operation based on the command “X3h”. In a case where the group data of the page PG(i+2) is transferred to the latch circuit BDL, the sequencer 15 sets the ready/busy signal RBn to the “H” level.

Next, the memory controller 200 issues a command set of group data read for reading the group data to the latch circuit CDL. The memory controller 200 transmits a command “X5h”, a command “00h”, an address “ADDg(1+3)”, and a command “30h” to the memory device 100. The command “X5h” is a prefix command indicating reading the SLC data and that read destination is the latch circuit CDL. In the case of the command “X5h”, the group data is stored in the latch circuit CDL.

Upon receiving the command “30h”, the sequencer 15 sets the ready/busy signal RBn to the “L” level. Then, the sequencer 15 executes the SLC read operation based on the command “X5h”. In a case where the group data of the page PG(i+3) is transferred to the latch circuit CDL, the sequencer 15 sets the ready/busy signal RBn to the “H” level.

Next, a command set corresponding to shift read for each BL group corresponding to the first phase will be described.

As illustrated in FIG. 71, first, the memory controller 200 transmits a command “Y4h” to the memory device 100. The command “Y4h” is a prefix command indicating shift read for each BL group in the first phase. Next, the memory controller 200 transmits a command “01h” to the memory device 100. Next, the memory controller 200 sequentially transmits shift values Δa1, Δa2, Δa3, Δa4, Δa5, Δa6, and Δa7 corresponding to the first to seventh BL groups of the A state and shift values Δe1, Δe2, Δe3, Δe4, Δe5, Δe6, and Δe7 corresponding to the first to seventh BL groups of the E state to the memory device 100. The shift values Δa1, Δa2, Δa3, Δa4, Δa5, Δa6, and Δa7 have a relationship of Δa1<Δa2<Δa3<Δa4<Δa5<Δa6<Δa7. The shift values Δe1, Δe2, Δe3, Δe4, Δe5, Δe6, and Δe7 have a relationship of Δe1<Δe2<Δe3<Δe4<Δe5<Δe6<Δe7.

Next, the memory controller 200 transmits a command “00h”, an address “ADD”, and a command “30h” to the memory device 100.

Upon receiving the command “30h”, the sequencer 15 sets the ready/busy signal RBn to the “L” level. Then, the sequencer 15 executes the shift read of the first to seventh BL groups based on the command “Y4h”. In a case where the shift read operation is ended, the sequencer 15 sets the ready/busy signal RBn to the “H” level.

Next, a command set corresponding to shift read for each BL group corresponding to the second phase will be described.

As illustrated in FIG. 72, first, the memory controller 200 transmits a command “Y5 h” to the memory device 100. The command “Y5 h” is a prefix command indicating shift read for each BL group in the second phase. Next, the memory controller 200 transmits a command “01h” to the memory device 100. Next, the memory controller 200 sequentially transmits shift values Δa8, Δa9, Δa10, Δa11, Δa12, Δa13, and Δa14 corresponding to the eighth to fourteenth BL groups of the A state and shift values Δe8, Δe9, Δe10, Δe11, Δe12, Δe13, and Δe14 corresponding to the eighth to fourteenth BL groups of the E state to the memory device 100. The shift values Δa8, Δa9, Δa10, Δa11, Δa12, Δa13, and Δa14 have a relationship of Δa8<Δa9<Δa10<Δa11<Δa12<Δa13<Δa14. The shift values Δe8, Δe9, Δe10, Δe11, Δe12, Δe13, and Δe14 have a relationship of Δe8<Δe9<Δe10<Δe11<Δe12<Δe13<Δe14.

Next, the memory controller 200 transmits a command “00h”, an address “ADD”, and a command “30h” to the memory device 100.

Upon receiving the command “30h”, the sequencer 15 sets the ready/busy signal RBn to the “L” level. Then, the sequencer 15 executes the shift read of the eighth to fourteenth BL groups based on the command “Y5 h”. In a case where the shift read operation is ended, the sequencer 15 sets the ready/busy signal RBn to the “H” level.

### 4.4 Voltage of Selected Word Line at Time of Read Operation of Lower Page Data

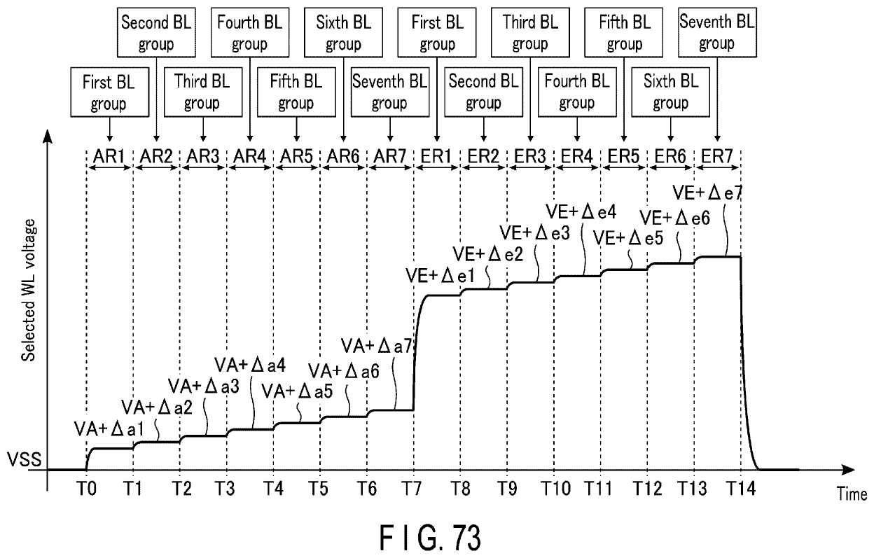

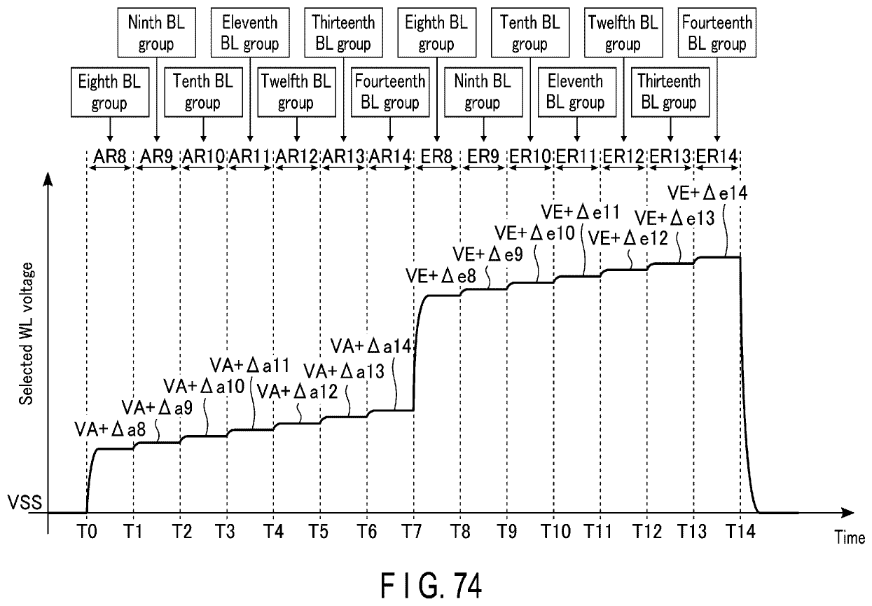

Next, an example of the voltage of the selected word line WL at the time of the Lower page data read operation will be described with reference to FIGS. 73 and 74. FIG. 73 is a timing chart illustrating an example of the voltage of the selected word line WL in the shift read in the first phase of the Lower page data. FIG. 74 is a timing chart illustrating an example of the voltage of the selected word line WL in the shift read in the second phase of the Lower page data.

As illustrated in FIG. 73, in each state, the read voltage is applied to the selected word line WL in ascending order.

During the period from the time T0 to the time T1, first, the read voltage (VA+Δa1) corresponding to the read operation AR1 of the A state of the first BL group is applied to the selected word line WL.

During the period from the time T1 to the time T2, the read voltage (VA+Δa2) corresponding to the read operation AR2 of the A state of the second BL group is applied to the selected word line WL.

During the period from the time T2 to the time T3, the read voltage (VA+Δa3) corresponding to the read operation AR3 of the A state of the third BL group is applied to the selected word line WL.

During the period from the time T3 to the time T4, the read voltage (VA+Δa4) corresponding to the read operation AR4 of the A state of the fourth BL group is applied to the selected word line WL.

During the period from the time T4 to the time T5, the read voltage (VA+Δa5) corresponding to the read operation AR5 of the A state of the fifth BL group is applied to the selected word line WL.

During the period from the time T5 to the time T6, the read voltage (VA+Δa6) corresponding to the read operation AR6 of the A state of the sixth BL group is applied to the selected word line WL.

During the period from the time T6 to the time T7, the read voltage (VA+Δa7) corresponding to the read operation AR7 of the A state of the seventh BL group is applied to the selected word line WL.

During the period from time T7 to time T8, the read voltage (VE+Δe1) corresponding to the read operation ER1 of the E state of the first BL group is applied to the selected word line WL.

During the period from time T8 to time T9, the read voltage (VE+Δe2) corresponding to the read operation ER2 of the E state of the second BL group is applied to the selected word line WL.

During the period from time T0 to time T10, the read voltage (VE+Δe3) corresponding to the read operation ER3 of the E state of the third BL group is applied to the selected word line WL.

During the period from time T10 to time T11, the read voltage (VE+Δe4) corresponding to the read operation ER4 of the E state of the fourth BL group is applied to the selected word line WL.

During the period from time T11 to time T12, a read voltage (VE+Δe5) corresponding to the read operation ER5 of the E state of the fifth BL group is applied to the selected word line WL.

During the period from time T12 to time T13, the read voltage (VE+Δe6) corresponding to the read operation ER6 of the E state of the sixth BL group is applied to the selected word line WL.

During the period from time T13 to time T14, the read voltage (VE+Δe7) corresponding to the read operation ER7 of the E state of the seventh BL group is applied to the selected word line WL.

As illustrated in FIG. 74, in each state, the read voltage is applied to the selected word line WL in ascending order.

During the period from the time T0 to the time T1, first, the read voltage (VA+Δa8) corresponding to the read operation AR8 of the A state of the eighth BL group is applied to the selected word line WL.

During the period from the time T1 to the time T2, the read voltage (VA+Δa9) corresponding to the read operation AR9 of the A state of the ninth BL group is applied to the selected word line WL.

During the period from the time T2 to the time T3, the read voltage (VA+Δa10) corresponding to the read operation AR10 of the A state of the tenth BL group is applied to the selected word line WL.

During the period from the time T3 to the time T4, the read voltage (VA+Δa11) corresponding to the read operation AR11 of the A state of the eleventh BL group is applied to the selected word line WL.

During the period from the time T4 to the time T5, the read voltage (VA+Δa12) corresponding to the read operation AR12 of the A state of the twelfth BL group is applied to the selected word line WL.

During the period from time T5 to time T6, a read voltage (VA+Δa13) corresponding to the read operation AR13 of the A state of the thirteenth BL group is applied to the selected word line WL.

During the period from time T6 to time T7, a read voltage (VA+Δa14) corresponding to the read operation AR14 of the A state of the fourteenth BL group is applied to the selected word line WL.

During the period from time T7 to time T8, the read voltage (VE+Δe8) corresponding to the read operation ER8 of the E state of the eighth BL group is applied to the selected word line WL.

During the period from time T8 to time T9, the read voltage (VE+Δe9) corresponding to the read operation ER9 of the E state of the ninth BL group is applied to the selected word line WL.

During the period from time T9 to time T10, a read voltage (VE+Δe10) corresponding to the read operation ER10 of the E state of the tenth BL group is applied to the selected word line WL.

During the period from time T10 to time T11, a read voltage (VE+Δe11) corresponding to the read operation ER11 of the E state of the eleventh BL group is applied to the selected word line WL.

During the period from time T11 to time T12, a read voltage (VE+Δe12) corresponding to the read operation ER12 of the E state of the twelfth BL group is applied to the selected word line WL.

During the period from time T12 to time T13, a read voltage (VE+Δe13) corresponding to the read operation ER13 of the E state of the thirteenth BL group is applied to the selected word line WL.

During the period from time T13 to time T14, a read voltage (VE+Δe14) corresponding to the read operation ER14 of the E state of the fourteenth BL group is applied to the selected word line WL.

### 4.5 Effects According to Present Embodiment

With the configuration according to the present embodiment, effects similar to those of the first embodiment can be obtained.

Furthermore, with the configuration according to the present embodiment, the shift read for each BL group can be executed by dividing into a plurality of phases. As a result, the number of groups of BL groups can be set without being limited to the number of latch circuits of the sense amplifier unit SAU.

The first to fifth modifications of the first embodiment can be applied to the fourth embodiment.

### 5. FIFTH EMBODIMENT

Next, a fifth embodiment will be described. In the fifth embodiment, a case where the Vth tracking operation is executed for each BL group will be described. Hereinafter, differences from the first to fourth embodiments will be mainly described.

### 5.1 Flow of Vth Tracking Operation

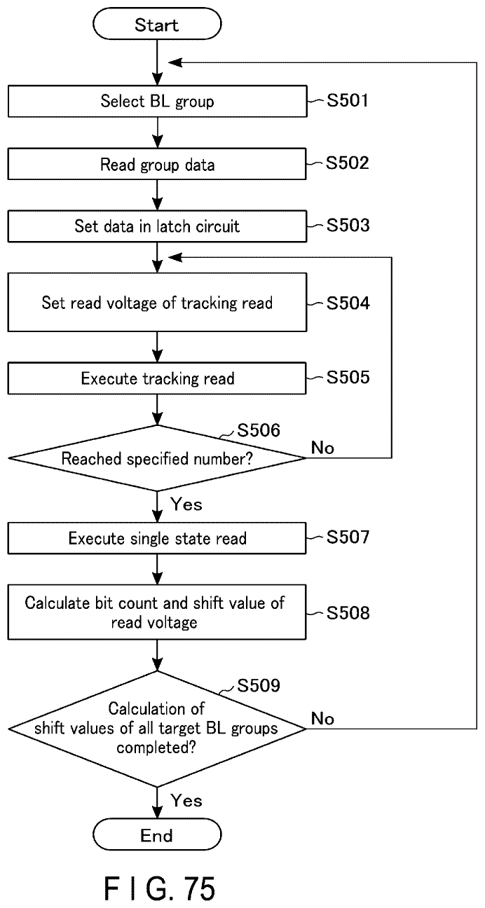

First, an example of a flow of the Vth tracking operation will be described with reference to FIG. 75. FIG. 75 is a flowchart illustrating an example of a flow of the Vth tracking operation.

As illustrated in FIG. 75, the CPU 230 first selects the BL group for which the tracking read is executed (S501). The CPU 230 issues a command set of tracking read corresponding to the selected BL group. The CPU 230 transmits a command set of tracking read to the memory device 100.

Upon receiving the command set of tracking read, the sequencer 15 first reads the group data (S502).

The group data is set in the latch circuit of the sense amplifier module 21 designated as the read destination (S503).

The sequencer 15 sets the read voltage of the tracking read (S504). The read voltage of the tracking read is stepped up every time the tracking read is repeated.

The sequencer 15 executes the tracking read (S505). After executing the tracking read, the sequencer 15 transmits the read data (hereinafter, referred to as “tracking data”) of the tracking read to the memory controller 200.

The sequencer 15 checks whether the number of tracking reads has reached a specified number of times.

In a case where the number of tracking reads has not reached the specified number of times (S506_No), the sequencer 15 advances the process to S504 and sets the read voltage of the next tracking read.

On the other hand, in a case where the number of times of tracking read has reached the specified number of times (S506_Yes), the sequencer 15 executes single state read (S507). Note that the single state read may be executed before the tracking read is executed. The single state read is, for example, a read operation of single-state data (hereinafter, referred to as “single data”) used for a state separation process in a case where page data includes information of a plurality of states. For example, in the case of state separation of the Lower page data, the voltage VC is selected as the single-state read voltage. After executing the single state read, the sequencer 15 transmits the read data of the single state read to the memory controller 200.

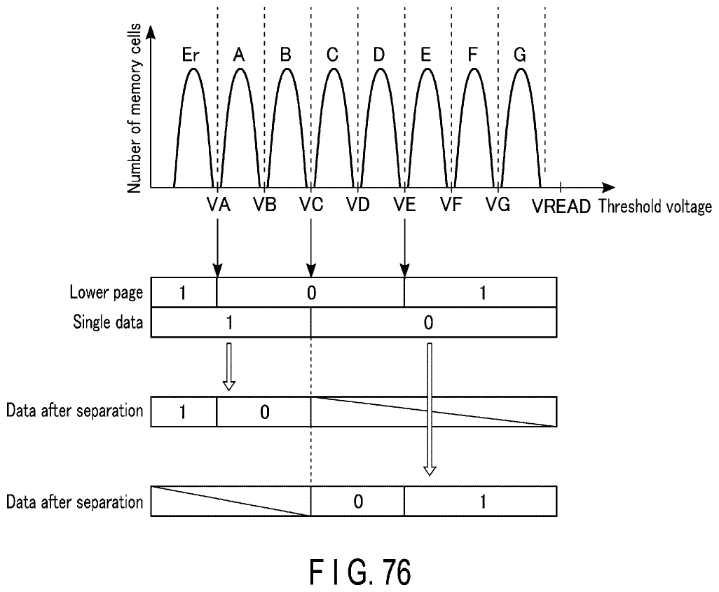

The state separation will be briefly described with reference to FIG. 76. FIG. 76 is a diagram illustrating an example of state separation of Lower page data.

As illustrated in FIG. 76, in the Lower page data, in a case where the threshold voltage of the memory cell transistor MC is less than the read voltage VA or equal to or more than the read voltage VE, the bit data is “1”. In this case, the memory cell transistor MC is considered to belong to either the Er state or the E to G states. In addition, in a case where the threshold voltage of the memory cell transistor MC is equal to or more than the read voltage VA and less than the read voltage VE, the bit data is “0”. In this case, the memory cell transistor MC is considered to belong to any of the A to D states.

In the read data (hereinafter, referred to as “single data”) of the single state read, the bit data is “1” in a case where the threshold voltage of the memory cell transistor MC is less than the read voltage VC. In this case, the memory cell transistor MC is considered to belong to any of the Er to B states. In a case where the threshold voltage of the memory cell transistor MC is equal to or higher than the read voltage VC, the bit data is “0”. In this case, the memory cell transistor MC is considered to belong to any of the C to G states.

For example, the CPU 230 executes state separation of the Lower page data based on the single data. Specifically, the CPU 230 separates the Lower page data into data corresponding to single data of “1” bits and data corresponding to single data of “0” bits.

For example, the CPU 230 counts the number of “1” bits in the tracking data after the state separation. Then, the CPU 230 calculates the shift value of the corresponding read voltage from the differential minimum point of the change amount of the bit count number of the plurality of tracking data for each separated state (S508).

The CPU 230 checks whether the calculation of the shift values of the read voltages of all the target BL groups has been completed.

In a case where the calculation of the shift values of the read voltages of all the target BL groups is not completed (S509_No), the CPU 230 advances the process to S501 and selects the next BL group.

In a case where the calculation of the shift values of the read voltages of all the target BL groups is completed (S509_Yes), the CPU 230 ends the Vth tracking operation. For example, the CPU 230 executes shift read for each BL group using the calculated shift value of the read voltage. In addition, the CPU 230 updates the history value of the read level management table 222 based on the calculated shift value.

### 5.2 Command Sequence of Tracking Read of Lower Page Data

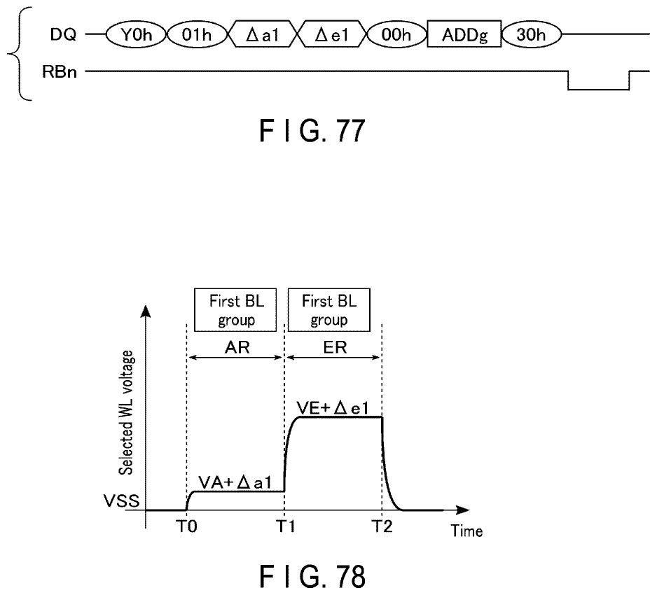

Next, an example of a command sequence of the tracking read of the Lower page data will be described with reference to FIG. 77. FIG. 77 is a diagram illustrating an example of a command set of tracking read of the Lower page data.

As illustrated in FIG. 77, first, the memory controller 200 transmits a command “Y0h” to the memory device 100. The command “Y0h” is a prefix command indicating tracking read for each BL group using group data of one page. Next, the memory controller 200 transmits a command “01h” to the memory device 100.

Next, the memory controller 200 sequentially transmits the shift value Δa1 of the A state and the shift value Δe1 of the E state to the memory device 100. Next, the memory controller 200 transmits a command “00h”, an address “ADDg” of the group data, and a command “30h” to the memory device 100.

Upon receiving the command “30h”, the sequencer 15 sets the ready/busy signal RBn to the “L” level. Then, the sequencer 15 executes tracking read based on the command “Y0h”. In a case where the tracking read is completed the specified number of times, the sequencer 15 sets the ready/busy signal RBn to the “H” level. 5.3 voltage of selected word line in tracking read of Lower page data

Next, an example of the voltage of the selected word line WL in the tracking read of the Lower page data will be described with reference to FIG. 78. FIG. 78 is a timing chart illustrating an example of the voltage of the selected word line WL in the tracking read of the Lower page data. The example illustrated in FIG. 78 illustrates a case where the first BL group is selected as the target BL group.

As illustrated in FIG. 78, during the period from the time T0 to the time T1, the read voltage (VA+Δa1) corresponding to the read operation AR of the A state of the first BL group is applied to the selected word line WL.

During the period from the time T1 to the time T2, the read voltage (VE+Δe1) corresponding to the read operation ER of the E state of the first BL group is applied to the selected word line WL.

### 5.4 Specific Example of Tracking Read of Lower Page Data

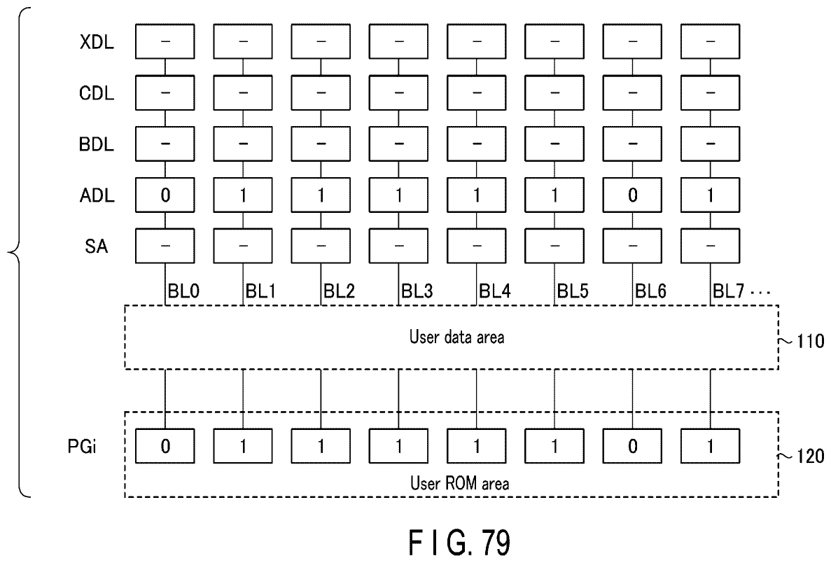

Next, a specific example of the tracking read of the Lower page data will be described with reference to FIGS. 79 to 81. FIGS. 79 to 81 are diagrams illustrating an example of the state of the latch circuit in the tracking read of the Lower page data. In the examples illustrated in FIGS. 79 to 81, the operation unit OP is omitted.

As illustrated in FIG. 79, first, the group data read of the page PGi is executed. As a result, the same data as the page PGi is stored in the latch circuits ADL. More specifically, “O” data is stored in the latch circuits ADL corresponding to the bit lines BL0 and BL6. “1” data is stored in the latch circuits ADL corresponding to the bit lines BL1 to BL5 and BL7. In other words, “0” data is stored in the latch circuits ADL corresponding to the first BL group, and “1” data is stored in the latch circuits ADL corresponding to the BL group other than the first BL group.

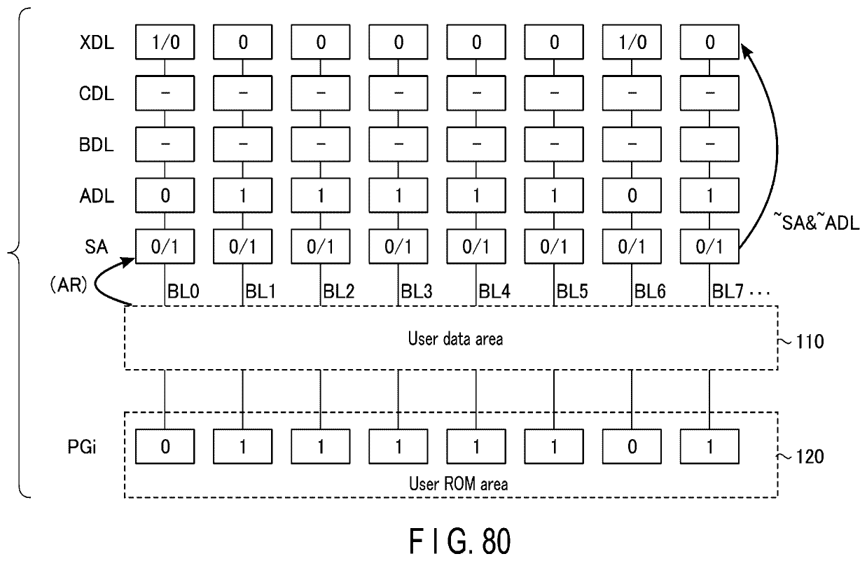

As illustrated in FIG. 80, first, the read operation AR of the A state of the first BL group is executed. The sense circuit SA stores data (0/1) read by the read operation AR. The operation unit OP executes the operation of Expression (1) and transfers the result to the latch circuit XDL.

As a result, the inverted data (1/0) of the sense circuit SA is stored in the latch circuits XDL corresponding to the bit lines BL0 and BL6. “0” data is stored in the latch circuits XDL corresponding to the bit lines BL1 to BL5 and BL7. In other words, the inverted data (1/0) of the sense circuit SA is stored in the latch circuit XDL corresponding to the first BL group (ADL=0), and the “0” data is stored in the latch circuit XDL corresponding to the BL group (ADL=1) other than the first BL group.

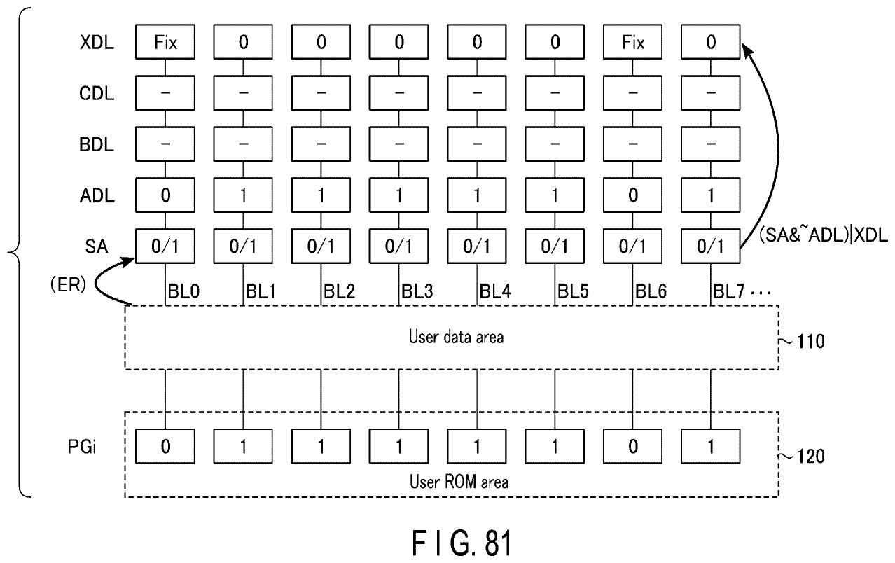

As illustrated in FIG. 81, next, the read operation ER of the E state of the first BL group is executed. The sense circuit SA stores the data (0/1) read by the read operation ER. The operation unit OP executes the operation of Expression (3) and transfers the result to the latch circuit XDL.

As a result, the read result (Fix) of the Lower page data is stored in the latch circuits XDL corresponding to the bit lines BL0 and BL6. In other words, the read result (Fix) of the Lower page data is stored in the latch circuit XDL corresponding to the first BL group (ADL=0). As a result, the Lower page data of the first BL group is determined.

### 5.5 Configuration According to Present Embodiment

With the configuration according to the present embodiment, the tracking read can be executed for each bit line BL group. That is, the shift value of the read voltage different for each layer L can be calculated. As a result, since the shift value of the read voltage can be optimized for each layer L, an increase in the number of fail bits can be suppressed. That is, erroneous reading can be suppressed. Therefore, the reliability of the memory system can be improved.

### 5.6 Modification of Fifth Embodiment

Next, a modification of the fifth embodiment will be described. In the present modification, a flow of a Vth tracking operation different from that of the fifth embodiment will be described. Hereinafter, differences from the fifth embodiment will be mainly described.

### 5.6.1 Flow of Vth Tracking Operation

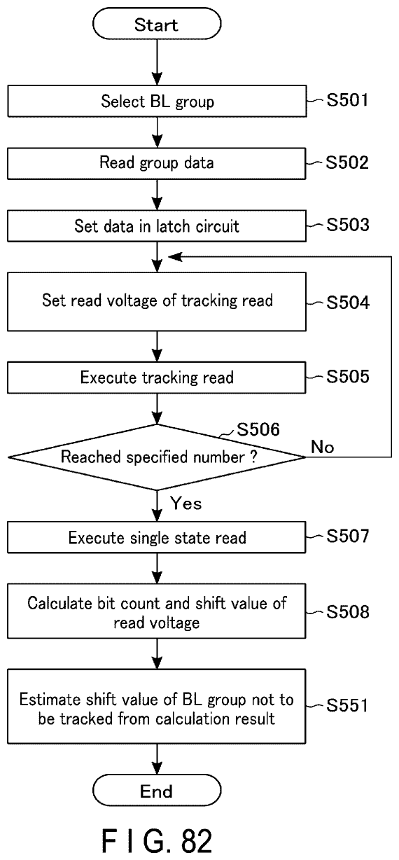

An example of a flow of the Vth tracking operation will be described with reference to FIG. 82. FIG. 82 is a flowchart illustrating an example of a flow of the Vth tracking operation.

As illustrated in FIG. 82, the operation in steps S501 to S508 is similar to that in the description using FIG. 75.

The CPU 230 estimates the shift value of the read voltage of another BL group based on the calculation result of the shift value of the read voltage of the BL group in which the tracking read is completed (S551). More specifically, for example, in a case where the calculation of the shift value of the read voltage of the first BL group is completed, the CPU 230 estimates the shift value of the read voltage of another BL group based on the calculation result.

In a case where the estimation of the shift value of the read voltage is completed, the CPU 230 ends the Vth tracking operation. For example, the CPU 230 executes shift read using the calculated shift value of the read voltage.

### 5.6.2 Effects According to Present Modification

With the configuration according to the present modification, effects similar to those of the fifth embodiment can be obtained.

Furthermore, with the configuration according to the present modification, the shift values of another BL group can be estimated from the result of tracking read of some BL groups. Therefore, it is possible to suppress an increase in processing time of the Vth tracking operation.

### 6. MODIFICATIONS AND THE LIKE

The memory system according to the above embodiments includes a memory device (100) and a memory controller (200). The memory device includes a memory cell array (18) including a first memory cell (MC) and a second memory cell (MC) stacked apart from each other above a substrate, a word line (WL) coupled to a gate of the first memory cell and a gate of the second memory cell, a first bit line (BL0) coupled to the first memory cell, a second bit line (BL3) coupled to the second memory cell, a sense amplifier module (21) including a first sense circuit (SA) to which the first bit line is coupled, a second sense circuit (SA) to which the second bit line is coupled, a first latch circuit (ADL) coupled to the first sense circuit, and a second latch circuit (ADL) coupled to the second sense circuit, and a data register (22) coupled to the sense amplifier module. The memory controller configured to control a read operation in the memory device. In a first read operation of the first memory cell and the second memory cell, the first latch circuit is configured to store first data (0) corresponding to a first group (first BL group) to which the first bit line belongs, the second latch circuit is configured to store second data (1) corresponding to a second group (second BL group) to which the second bit line belongs, and the data register is configured to store data of the first memory cell read by the first sense circuit under a first read condition based on an operation result using the first data, and stores data of the second memory cell read by the second sense circuit under a second read condition based on an operation result using the second data.

With the configuration according to the above embodiments, data reliability can be improved.

Note that the present invention is not limited to the above-described embodiments, and various modifications can be applied.

Furthermore, the “coupling” in the above embodiments includes a state in which the coupling is indirectly made with some unit, for example, a transistor or a resistor, interposed therebetween.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory device including:
a memory cell array including a first memory cell and a second memory cell stacked apart from each other above a substrate;
a word line coupled to a gate of the first memory cell and a gate of the second memory cell;
a first bit line coupled to the first memory cell;
a second bit line coupled to the second memory cell;
a sense amplifier module including a first sense circuit to which the first bit line is coupled, a second sense circuit to which the second bit line is coupled, a first latch circuit coupled to the first sense circuit, and a second latch circuit coupled to the second sense circuit; and
a data register coupled to the sense amplifier module; and
a memory controller configured to control a read operation in the memory device, wherein
in a first read operation of the first memory cell and the second memory cell,
the first latch circuit is configured to store first data corresponding to a first group to which the first bit line belongs,
the second latch circuit is configured to store second data corresponding to a second group to which the second bit line belongs, and
the data register is configured to store data of the first memory cell read by the first sense circuit under a first read condition based on an operation result using the first data, and store data of the second memory cell read by the second sense circuit under a second read condition based on an operation result using the second data.

2. The memory system according to claim 1, wherein
the memory controller is configured to manage the first read condition and the second read condition using a table.

3. The memory system according to claim 1, wherein
the memory controller is configured to manage a history of a read condition applied to the word line using a table.

4. The memory system according to claim 1, wherein
the memory cell array further includes a first block and a second block,
the first block includes the first memory cell and the second memory cell, and
the second block stores at least the first data and the second data.

5. The memory system according to claim 4, wherein
the memory controller is further configured to:
issue a command set including a command and an address of the second block storing the first data and the second data, the command instructing reading of the first data and the second data and a read destination of the first data and the second data; and
transmit the command set to the memory device.

6. The memory system according to claim 1, wherein
the memory controller is configured to manage a table including the first data and the second data.

7. The memory system according to claim 6, wherein
the memory controller is further configured to:
issue a command set including the first data, the second data, and a command instructing writing of the first data and the second data and a write destination of the first data and the second data; and
transmit the command set to the memory device.

8. The memory system according to claim 1, wherein
a size of the first memory cell is different from a size of the second memory cell.

9. The memory system according to claim 1, wherein
a first shift value of a first read voltage in the first read condition is different from a second shift value of a second read voltage in the second read condition.

10. The memory system according to claim 9, wherein
the memory controller is configured to manage the first shift value and the second shift value using a table.

11. The memory system according to claim 9, wherein
the memory controller is further configured to:
issue a command set including a first command indicating the number of groups including the first group and the second group, data related to the first shift value and the second shift value, a second command of the first read operation, and an address of the first memory cell and the second memory cell; and
transmit the command set to the memory device.

12. The memory system according to claim 9, wherein
in a case where the first shift value of the first read condition is equal to or less than the second shift value of the second read condition, the first read voltage based on the first shift value of the first read condition and the second read voltage based on the second shift value of the second read condition are sequentially applied to the word line, and
in a case where the first shift value of the first read condition is larger than the second shift value of the second read condition, the second read voltage based on the second shift value of the second read condition and the first read voltage based on the first shift value of the first read condition are sequentially applied to the word line.

13. The memory system according to claim 1, wherein
the first read condition and the second read condition have a same read voltage and different timings at which data is read.

14. The memory system according to claim 1, further comprising:
a third memory cell and a fourth memory cell stacked apart from the first memory cell and the second memory cell, each of the third memory cell and the fourth memory cell having a gate coupled to the word line, wherein
the sense amplifier module further includes a third sense circuit coupled to the third memory cell via a third bit line, a fourth sense circuit coupled to the fourth memory cell via a fourth bit line, a third latch circuit coupled to the first sense circuit, a fourth latch circuit coupled to the second sense circuit, a fifth latch circuit and a sixth latch circuit coupled to the third sense circuit, and a seventh latch circuit and an eighth latch circuit coupled to the fourth sense circuit, and
in a second read operation of the first memory cell, the second memory cell, the third memory cell, and the fourth memory cell,
the first latch circuit and the third latch circuit are configured to store third data corresponding to the first group,
the second latch circuit and the fourth latch circuit are configured to store fourth data corresponding to the second group,
the fifth latch circuit and the sixth latch circuit are configured to store fifth data corresponding to a third group to which the third bit line belongs,
the seventh latch circuit and the eighth latch circuit are configured to store sixth data corresponding to a fourth group to which the fourth bit line belongs, and
the data register is configured to store data of the first memory cell read by the first sense circuit under a third read condition based on an operation result using the third data, store data of the second memory cell read by the second sense circuit under a fourth read condition based on an operation result using the fourth data, store data of the third memory cell read by the third sense circuit under a fifth read condition based on an operation result using the fifth data, and store data of the fourth memory cell read by the third sense circuit under a sixth read condition based on an operation result using the sixth data.

15. The memory system according to claim 14, wherein
a third shift value of a third read voltage in the third read condition, a fourth shift value of a fourth read voltage in the fourth read condition, a fifth shift value of a fifth read voltage in the fifth read condition, and a sixth shift value of a sixth read voltage in the sixth read condition are different from each other.

16. The memory system according to claim 15, wherein
in a case where the third shift value of the third read condition is smaller than the fourth shift value of the fourth read condition, the fourth shift value of the fourth read condition is smaller than the fifth shift value of the fifth read condition, and the fifth shift value of the fifth read condition is smaller than the sixth shift value of the sixth read condition, the third read voltage based on the third shift value of the third read condition, the fourth read voltage based on the fourth shift value of the fourth read condition, the fifth read voltage based on the fifth shift value of the fifth read condition, and the sixth read voltage based on the sixth shift value of the sixth read condition are sequentially applied to the word line.

17. The memory system according to claim 1, further comprising a third memory cell and a fourth memory cell stacked apart from the first memory cell and the second memory cell, each of the third memory cell and the fourth memory cell having a gate coupled to the word lines, wherein
a third read operation of the first memory cell, the second memory cell, the third memory cell, and the fourth memory cell includes a first phase read operation of reading data of the first memory cell and the second memory cell and a second phase read operation of reading data of the third memory cell and the fourth memory cell.

18. The memory system according to claim 17, wherein
in the first phase read operation,
seventh data is allocated to the first group,
eighth data is allocated to the second group, and
ninth data is allocated to a third group to which a third bit line coupled to a gate of the third memory cell belongs and a fourth group to which a fourth bit line coupled to a gate of the fourth memory cell belongs, and wherein
in the second phase read operation,
the ninth data is allocated to the first group and the second group,
the seventh data is allocated to the third group, and
the eighth data is allocated to the fourth group.

19. The memory system according to claim 1, wherein
the memory controller is further configured to calculate a first shift value of a first read voltage corresponding to the first group based on the first data, and calculate a second shift value of a second read voltage corresponding to the second group based on the second data.

20. The memory system according to claim 1, wherein
the memory controller is configured to calculate a first shift value of a first read voltage corresponding to the first group based on the first data, and estimate a second shift value of a second read voltage corresponding to the second group based on the first shift value.
